(19) United States
(12) Patent Application Publication
(10) Pub. No.: US 2026/0096465 A1
(43) Pub. Date: Apr. 2, 2026

(54) PASSIVATION LAYER STACK FOR STRESS REDUCTION ON A SEMICONDUCTOR DIE AND METHODS FOR MAKING THE SAME

(71) Applicant: Taiwan Semiconductor Manufacturing Company Limited, Hsinchu (TW)

(72) Inventors: Cheng-Nan Lin, Hsinchu City (TW); Yu-Tse Su, Chiayi City (TW); Ching-Wen Hsiao, Hsinchu City (TW); Tai-Shen Yang, Taipei City (TW); Wei-Hsiang Tu, Hsinchu City (TW)

(21) Appl. No.: 18/904,368

(22) Filed: Oct. 2, 2024

(51) Int. Cl. H01L 21/56; H01L 23/00; H01L 23/29; H01L 23/31

(52) U.S. Cl. CPC H10W 74/014; H10W 74/137; H10W 74/47; H10W 72/07236; H10W 74/15; H10W 74/40; H10W 90/724; H10W 90/734

(57) ABSTRACT

A device structure may be provided by: forming semiconductor devices and metal interconnect structures formed within dielectric material layers over a semiconductor substrate; forming metal pads in a topmost layer of the dielectric material layers; forming a passivation layer stack including a first dielectric diffusion barrier layer, a silicate glass layer, a second dielectric diffusion barrier layer, and a polymer layer; forming openings through the passivation layer stack over the metal pads; forming die bump structures on the metal pads; and dicing a wafer including the passivation layer stack, the dielectric material layers, and the semiconductor substrate along dicing channels into a plurality of semiconductor dies.

### BACKGROUND

Edge portions of passivation layers on a semiconductor die may delaminate due to mechanical stress during packaging, which reduces the reliability of a semiconductor package. A scheme to reduce the stress on edge portions of passivation layers on a semiconductor die is desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top-down view of a wafer after formation of metal interconnect structures formed within dielectric material layers.

FIG. 1B is a vertical cross-sectional view of a region of the wafer along the vertical plane B-B′ of FIG. 1A.

FIG. 1C is a magnified view of region C of FIG. 1A.

FIG. 2A-2I are sequential vertical cross-sectional views of a first semiconductor die during fabrication and dicing according to an embodiment of the present disclosure.

FIG. 2J is a top-down view of the first semiconductor die of FIG. 2H.

FIG. 2K is a vertical cross-sectional view of an alternative configuration of the first semiconductor die.

FIG. 3A-3D are sequential vertical cross-sectional views of a second semiconductor die during fabrication and dicing according to an embodiment of the present disclosure.

FIG. 3E is a top-down view of the second semiconductor die of FIG. 3D.

FIG. 3F is a vertical cross-sectional view of an alternative configuration of the second semiconductor die.

FIG. 4A-4H are sequential vertical cross-sectional views of a third semiconductor die during fabrication and dicing according to an embodiment of the present disclosure.

FIG. 4I is a top-down view of the third semiconductor die of FIG. 4H.

FIG. 4J is a vertical cross-sectional view of an alternative configuration of the third semiconductor die.

FIG. 5A-5D are sequential vertical cross-sectional views of a fourth semiconductor die during fabrication and dicing according to an embodiment of the present disclosure.

FIG. 5E is a top-down view of the fourth semiconductor die of FIG. 5D.

FIG. 5F is a vertical cross-sectional view of an alternative configuration of the fourth semiconductor die.

FIG. 6A-6E are sequential vertical cross-sectional views of a fifth semiconductor die during fabrication and dicing according to an embodiment of the present disclosure.

FIG. 6F is a top-down view of the fifth semiconductor die of FIG. 6E.

FIG. 7A-7D are sequential vertical cross-sectional views of a sixth semiconductor die during fabrication and dicing according to an embodiment of the present disclosure.

FIG. 7E is a top-down view of the sixth semiconductor die of FIG. 7D.

FIG. 8A-8E are sequential vertical cross-sectional views of a seventh semiconductor die during fabrication and dicing according to an embodiment of the present disclosure.

FIG. 9A-9D are sequential vertical cross-sectional views of an eighth semiconductor die during fabrication and dicing according to an embodiment of the present disclosure.

FIG. 10A-10C are sequential vertical cross-sectional views of an exemplary structure during assembly of a semiconductor die and a packaging structure according to an embodiment of the present disclosure.

FIG. 11A-11H are vertical cross-sectional views of various configurations of a first exemplary bonded assembly according to an embodiment of the present disclosure.

FIG. 12A-12H are vertical cross-sectional views of various configurations of a second exemplary bonded assembly according to an embodiment of the present disclosure.

FIG. 13 is a first flowchart illustrating steps for a manufacturing process according to an embodiment of the present disclosure.

FIG. 14 is a second flowchart illustrating steps for the manufacturing process according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples, and are not intended to be limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The present disclosure is directed to a passivation method for semiconductor dies, and more specifically to a method for improving the reliability and stress management of semiconductor passivation layers. Modern passivation technologies often face issues such as debris generation during dicing. In addition, modern passivation technologies often face stress concentrations at die corners during packaging. These issues may lead to delamination and reliability concerns in a bonded assembly including a semiconductor die. Prevention of delamination is desired for providing superior performance and reliability for the bonded assemblies including semiconductor dies.

In semiconductor manufacturing, a robust passivation layer is desired for protecting the die and ensuring long-term reliability. Related methods utilizing silicon oxide layers may result in a mismatch in the coefficient of thermal expansion (CTE) between different materials, leading to delamination and mechanical stress. According to an aspect of the present disclosure, a novel passivation technique is used to reduce mechanical stress at corner regions of a semiconductor die by forming stress-diffusing patterns. The stress-diffusing patterns reduce the risk of delamination and enhances the overall durability of a passivation layer stack, thereby improving the reliability and lifespan of semiconductor packages. The various aspects of the present disclosure are now described in detail with reference to the accompanying figures.

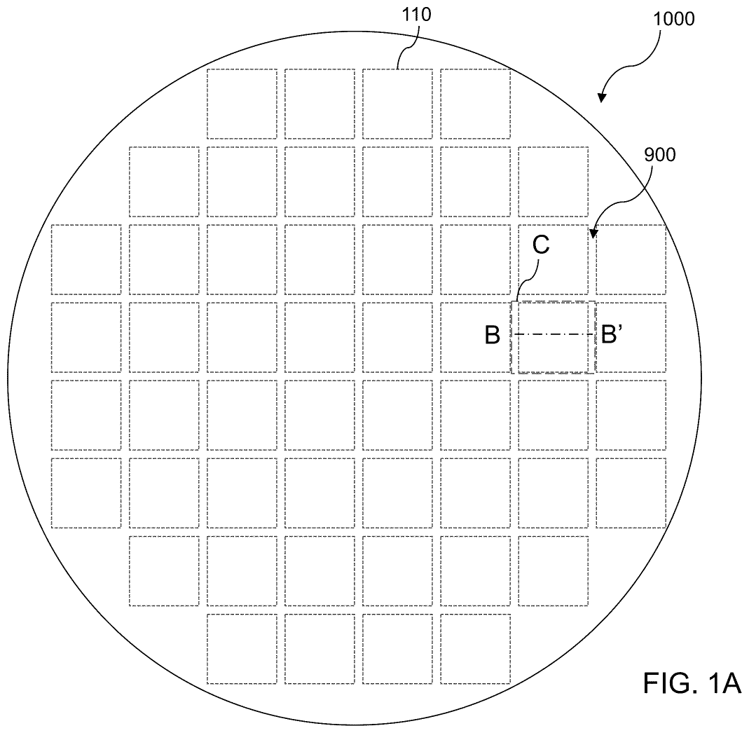

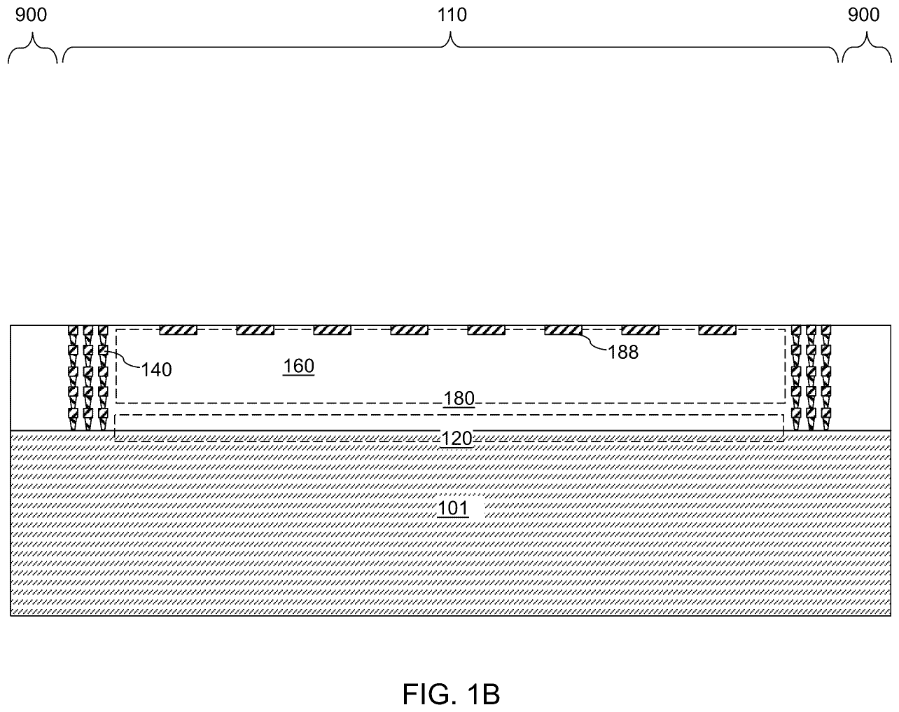

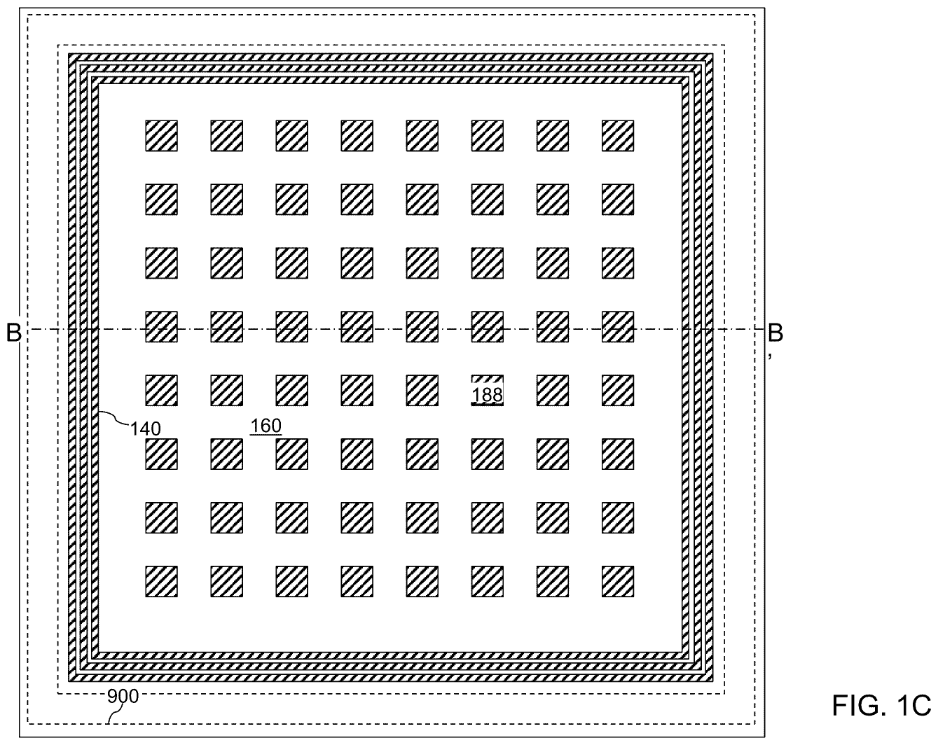

Referring to FIG. 1A, a top-down view of a wafer 1000 is illustrated after formation of semiconductor devices and metal interconnect structures formed within dielectric material layers over a semiconductor substrate. The wafer includes a two-dimensional array of semiconductor die regions 110 and dicing channel region 900. The semiconductor die regions 110 are rectangular portions of the wafer 1000 that become semiconductor dies upon dicing of the wafer 1000 in a subsequent processing step. The dicing channel regions 900 are grid-shaped portions of the wafer 1000 that are removed during the dicing of the wafer 1000.

FIG. 1B is a vertical cross-sectional view of a region of the wafer 1000 along the vertical plane B-B′ of FIG. 1A. FIG. 1C is a magnified view of region C of FIG. 1A. Referring to FIGS. 1B and 1C, the wafer 1000 comprises a semiconductor substrate 101, which may be a commercially available semiconductor wafer such as a single crystalline wafer. Semiconductor devices 120 may be formed on the semiconductor substrate 101 within each area of the semiconductor die regions 110. The semiconductor devices 120 may comprise any type of semiconductor devices known in the art such as field effect transistors, capacitors, resistors, inductors, diodes, etc.

Metal interconnect structures 180 may be formed within dielectric material layers 160 that are subsequently formed over the semiconductor devices 120, and provide electrical connections to and from the semiconductor devices 120 and die bump structures to be subsequently formed. The metal interconnect structures 180 may comprise various metal lines, metal via structures, etc. The metal interconnect structures 180 may comprise copper-based metal interconnect structures and/or aluminum-based metal interconnect structures. The dielectric material layers 160 may comprise, and/or may consist of, inorganic dielectric materials such as silicate glasses, silicon nitride, silicon carbide nitride, silicon oxynitride, dielectric metal oxides, etc. It is noted that organosilicate glass is primarily composed of inorganic silicon-oxygen bonds, and thus, despite presence of some C-H bonds, organosilicate glass is an inorganic material despite its name. In one embodiment, the dielectric material layers 160 may be free of polymer materials.

The metal interconnect structures 180 may comprise metal pads 188 that are formed at the topmost level of the dielectric material layers 160. In one embodiment, the metal pads 188 may be arranged in a pattern of a periodic array for subsequently forming a periodic array of die bump structures (such as copper pillar structures) thereupon. In one embodiment, the metal pads 188 may comprise a two-dimensional array of copper pads having a pitch in a range from 20 microns to 200 microns, although lesser and greater pitches may also be used.

A frame-shaped peripheral portion within each semiconductor die region 110 comprises an edge-seal region that contains an edge-seal structure 140. The frame-shaped peripheral portion is herein referred to as a seal ring region. The edge-seal structure 140 comprises at least one continuous set of metal interconnect structures that vertically extends from the top surface of the semiconductor substrate 101 to the topmost surface of the dielectric material layers 160. Each continuous set of metal interconnect structures may comprise a vertically alternating sequence of via-level wall structures and line-level wall structures, and thus, provides a continuous diffusion barrier structure against ingress of moisture and impurities.

The width of the seal ring region may be in a range from 2 microns to 10 microns, although lesser and greater widths may also be used. The lateral offset distance between the outermost sidewall of the edge-seal structure 140 and the most proximal portion of the dicing channel regions 900 may be in a range from 0.01 micron to 5 microns, such as from 0.2 micron to 3 microns, although lesser and greater lateral offset distances may also be used.

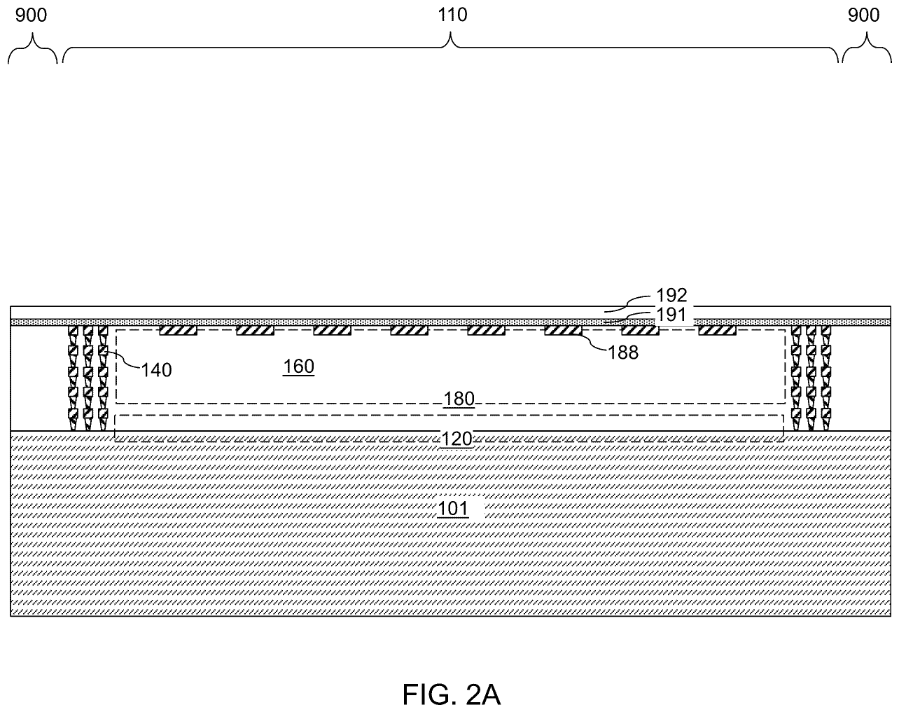

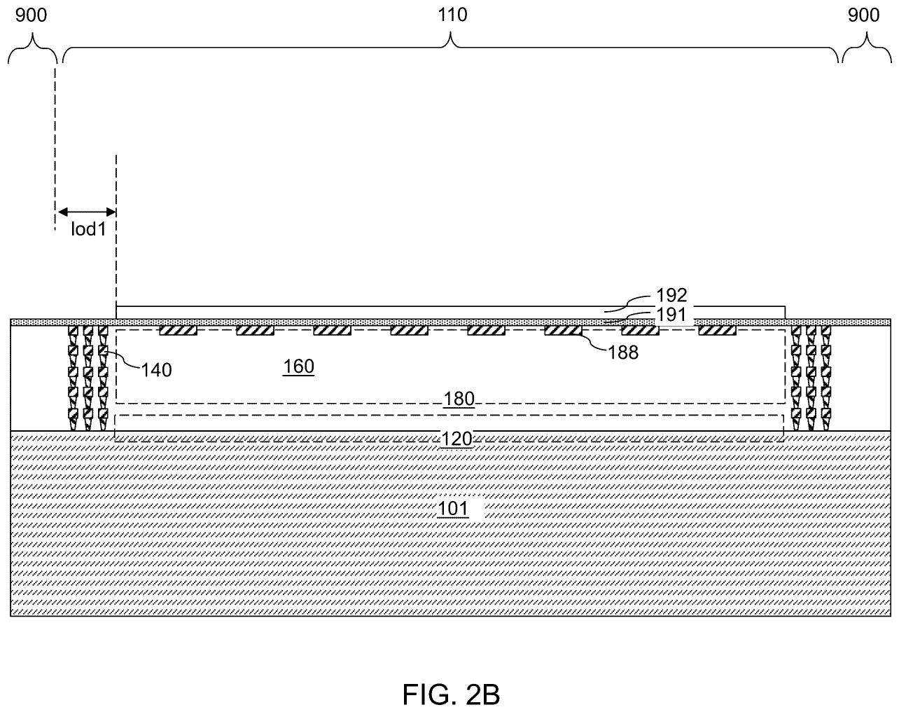

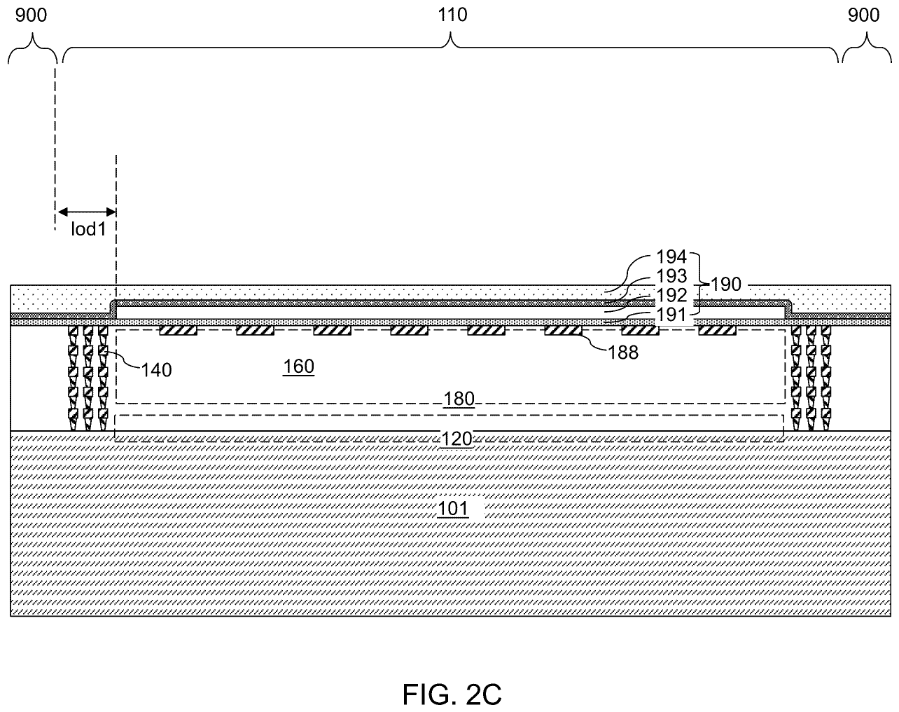

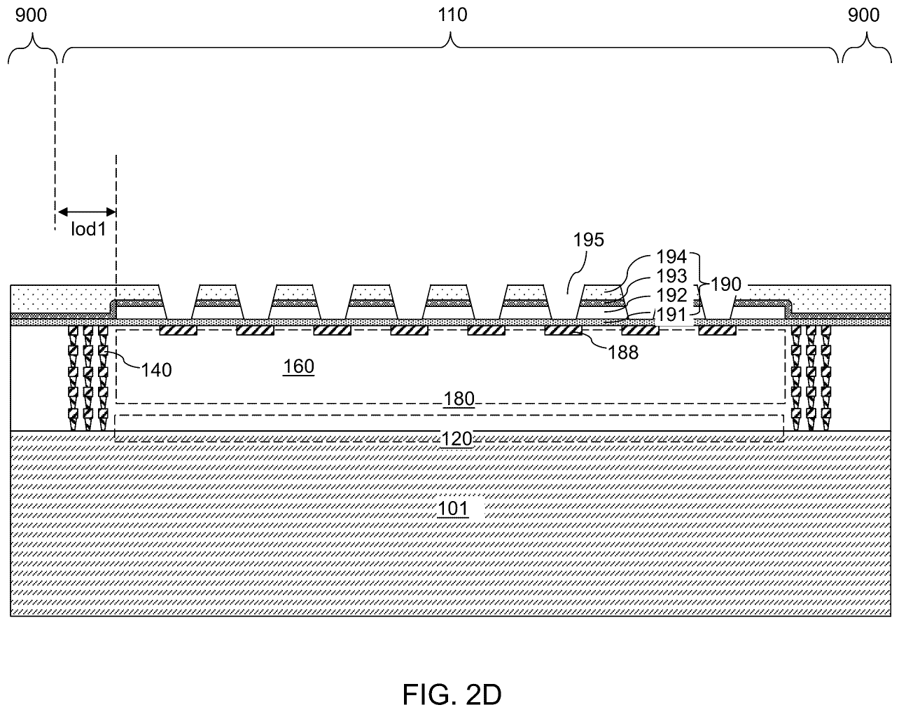

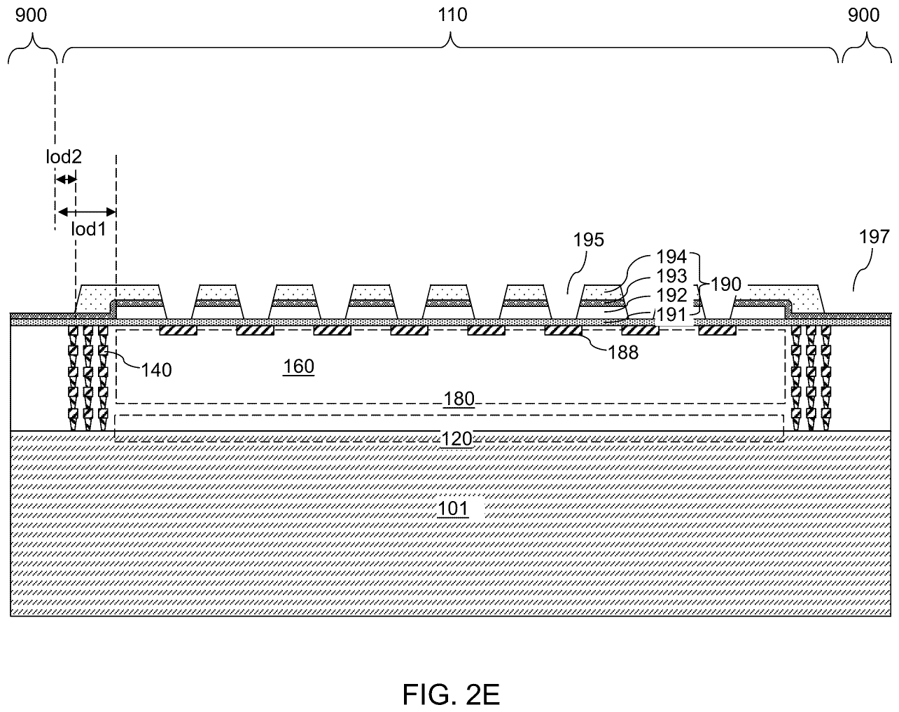

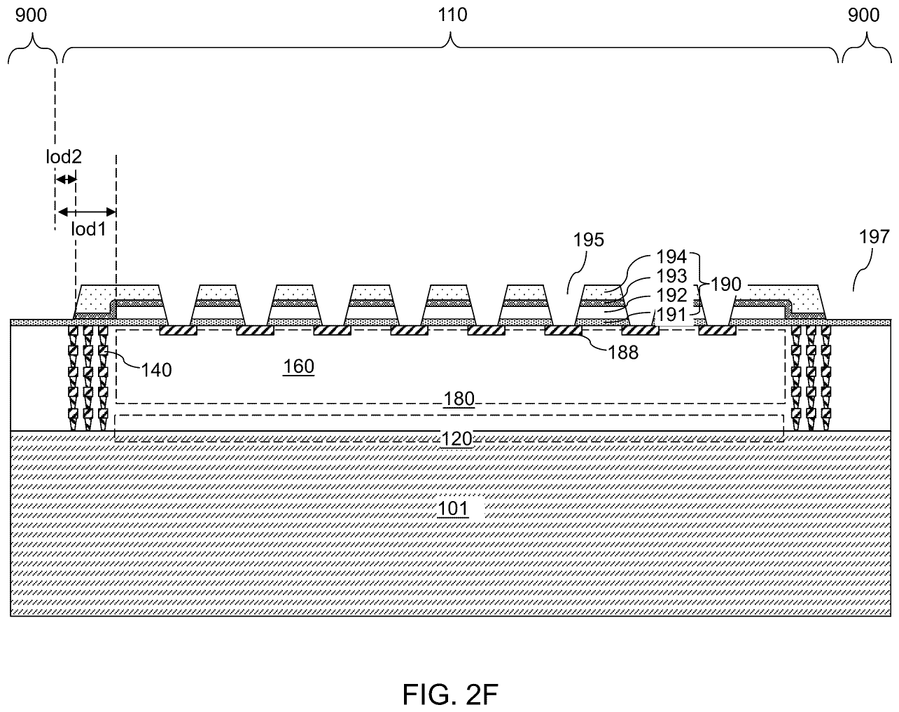

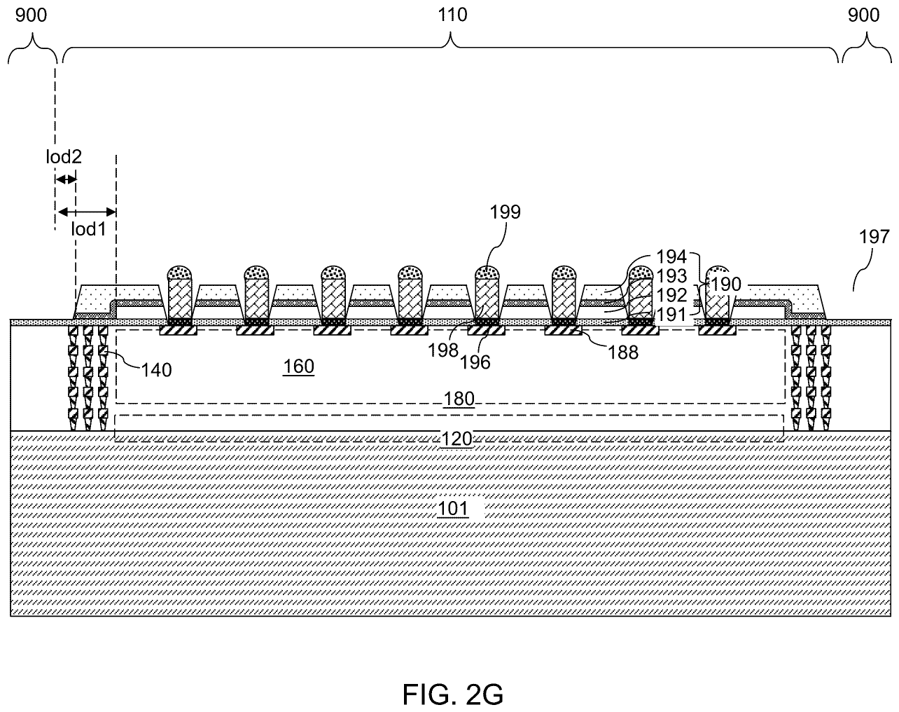

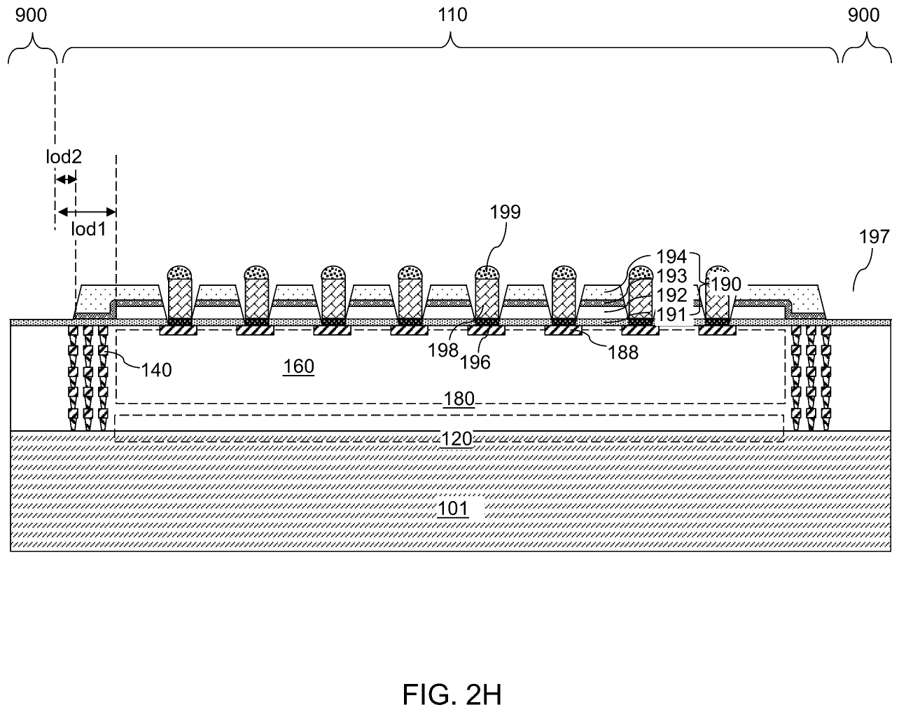

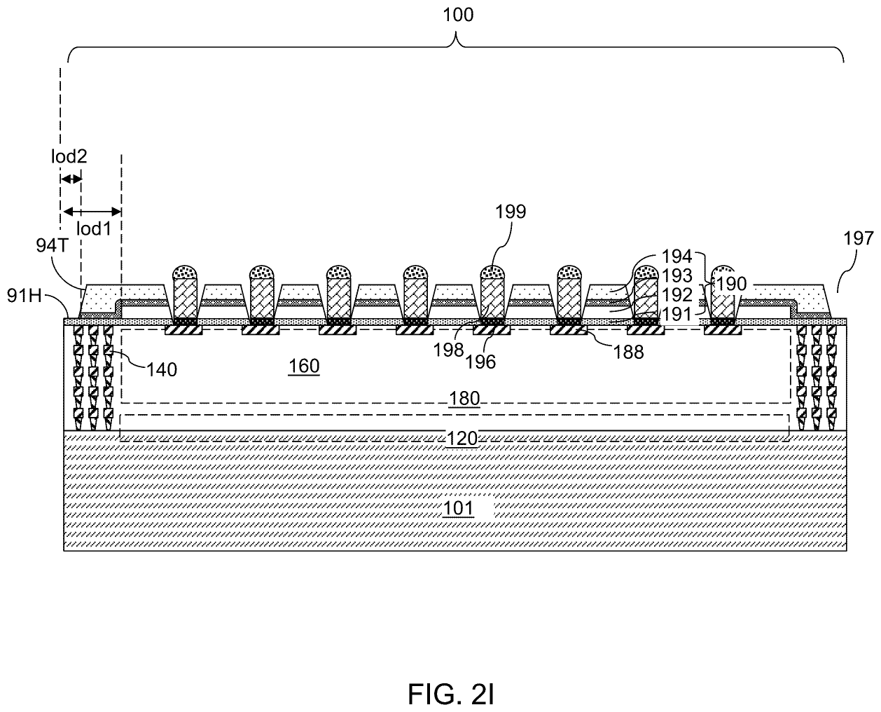

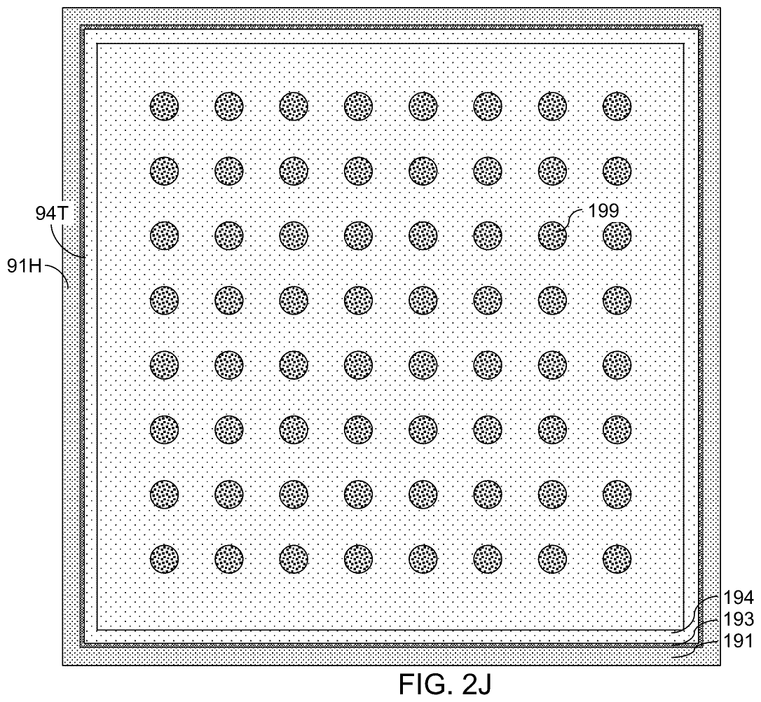

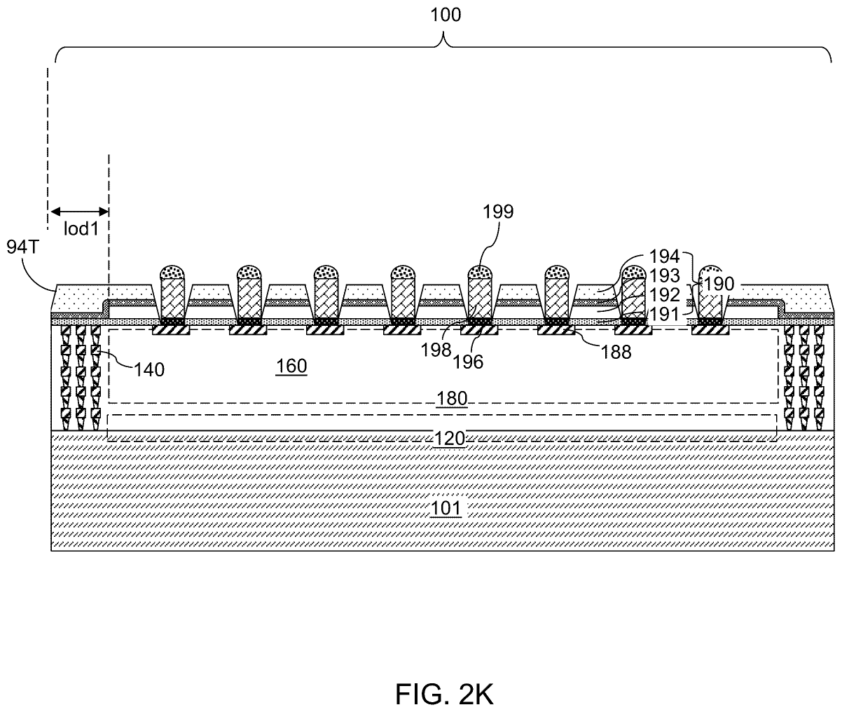

FIG. 2A-2I are sequential vertical cross-sectional views of a first semiconductor die 100 during fabrication and dicing according to an embodiment of the present disclosure.

Referring to FIG. 2A, a portion of the wafer 1000 in FIG. 1A is illustrated after formation of a first dielectric diffusion barrier layer 191 and a silicate glass layer 192 over the dielectric material layers 160 and the metal pads 188. The first dielectric diffusion barrier layer 191 comprises a first dielectric diffusion barrier material that may effectively block diffusion of hydrogen, moisture, and impurities. For example, the first dielectric diffusion barrier layer 191 may comprise, and/or may consist essentially of, silicon nitride and/or silicon carbide nitride. Other dielectric materials are within the contemplated scope of disclosure. The first dielectric diffusion barrier layer 191 may be deposited by chemical vapor deposition (CVD). The thickness of the first dielectric diffusion barrier layer 191 may be in a range from 100 nm to 3,000 nm, such as from 300 nm to 1,000 nm, although lesser and greater thicknesses may also be used.

The silicate glass layer 192 comprises a silicate glass material such as undoped silicate glass or a doped silicate glass (e.g., borophosphosilicate glass, phosphosilicate glass, borosilicate glass, etc.). The silicate glass layer 192 may have a Young's modulus of about 70 GPa, and thus, is more elastic than the material of the first dielectric diffusion barrier layer 191. In an illustrative example, a first dielectric diffusion barrier layer 191 comprising silicon nitride has Young's modulus of about 300 GPa, and first dielectric diffusion barrier layer 191 comprising silicon carbide nitride has Young's modulus between 150 GPa and 250 GPa depending on the carbon content. The increased elasticity of the silicate glass layer 192 relative to the material of the first dielectric diffusion barrier layer 191 provides the advantage of better absorbing mechanical stress during subsequent stress-generating events such as bonding of a semiconductor die and application of an underfill material. The silicate glass layer 192 may be deposited by chemical vapor deposition such as high density plasma chemical vapor deposition. The thickness of the silicate glass layer 192 may be in a range from 300 nm to 6,000 nm, such as from 600 nm to 2,000 nm, although lesser and greater thicknesses may also be used.

Referring to FIG. 2B, a photoresist layer (not shown) may be applied over the silicate glass layer 192, and may be lithographically patterned to cover areas of the semiconductor devices 120 without covering the areas of the edge-seal structures 140 or the dicing channel regions 900. An anisotropic etch process may be performed to etch unmasked portions of the silicate glass layer 192. The etch chemistry of the anisotropic etch process may be selective to the material of the first dielectric diffusion barrier layer 191. The photoresist layer may be subsequently removed, for example, by ashing. Each patterned portion of the silicate glass layer 192 may have a rectangular shape in a top-down view, and may have straight edges that are parallel to a most proximal boundary between the semiconductor die region 110 and the dicing channel region 900. The straight edges of the silicate glass layer 192 may be laterally offset relative to the most proximal edge of the dicing channel region 900 by a first lateral offset distance lod1. The first lateral offset distance lod1 is greater than the width of the edge-seal structure 140, i.e., the lateral distance between an outermost sidewall of the edge-seal structure 140 and the innermost sidewall of the edge-seal structure 140. Thus, the first lateral offset distance lod1 is greater than the width of the seal ring region. In an illustrative example, the first lateral offset distance lod1 may be in a range from 2.2 microns to 20 microns, such as from 3 microns to 10 microns, although lesser and greater values may also be used.

Referring to FIG. 2C, a second dielectric diffusion barrier layer 193 and a polymer layer 194 may be sequentially deposited. The second dielectric diffusion barrier layer 193 comprises a second dielectric diffusion barrier material that may effectively block diffusion of hydrogen, moisture, and impurities. For example, the second dielectric diffusion barrier layer 193 may comprise, and/or may consist essentially of, silicon nitride and/or silicon carbide nitride. The material of the second dielectric diffusion barrier layer 193 may be the same as, or may be different from, the material of the first dielectric diffusion barrier layer 191. The second dielectric diffusion barrier layer 193 may be conformally deposited by chemical vapor deposition, and thus, may have the same thickness throughout. The thickness of the second dielectric diffusion barrier layer 193 may be in a range from 100 nm to 3,000 nm, such as from 300 nm to 1,000 nm, although lesser and greater thicknesses may also be used.

The polymer layer 194 comprises a polymer material that may be applied using a self-planarizing deposition process such as spin coating. In one embodiment, the polymer layer 194 comprises a photosensitive polymer material that may be patterned using lithographic exposure and development. For example, the polymer layer 194 may comprise a polymer material such as polyimide, photosensitive polybenzoxazole (PBO), photosensitive epoxy resins, photosensitive polyarylene ether (PAE), acrylic-based photoresists, photosensitive benzocyclobutene (BCB), or photosensitive polyimide derivatives. In one embodiment, the polymer layer 194 comprises polyimide. The entirety of the top surface of the polymer layer 194 may be formed within a horizontal plane. The thickness of the polymer layer 194 within an area in which the silicate glass layer 192 is present may be in a range from 1 micron to 20 microns, such as from 1.5 microns to 10 microns, although lesser and greater thicknesses may also be used. The polymer layer 194 functions as an elastic material layer during a subsequent bonding process. For example, polyimide has Young's modulus in a range from 2.5 GPa to 4.0 GPa. The combination of the first dielectric diffusion barrier layer 191, the silicate glass layer 192, the second dielectric diffusion barrier layer 193, and the polymer layer 194 is herein referred to as a passivation layer stack 190.

Referring to FIG. 2D, the polymer layer 194 may be patterned by lithographic exposure and development. A pattern of a two-dimensional array of openings may be formed in the polymer layer 194 such that each opening is formed entirely within the area of an underlying metal pad 188. An anisotropic etch process may be performed to transfer the pattern of the openings in the polymer layer 194 through the second dielectric diffusion barrier layer 193 and the silicate glass layer 192. The etch chemistry of a terminal step of the anisotropic etch process may be selective to the material of the first dielectric diffusion barrier layer 191. Openings 195 may be formed through the polymer layer 194, the second dielectric diffusion barrier layer 193, and the silicate glass layer 192. The taper angle of the sidewalls of the openings 195 (as measured relative to the vertical direction) may be in a range from 1 degree to 20 degrees, such as from 2 degrees to 10 degrees, although lesser and greater taper angles may also be used.

Referring to FIG. 2E, a photoresist layer (not shown) may be applied over the passivation layer stack 190, and may be lithographically patterned to cover the area of the semiconductor devices 120 and an inner portion of the edge-seal region without covering an outer portion of the edge-seal region or the dicing channel region 900. An etch process (such as an anisotropic etch process) may be performed to remove unmasked portions of the polymer layer 194 selectively to the material of the second dielectric diffusion barrier layer 193. A grid-shaped cavity 197 may be formed along the dicing channel regions 900 such that the area of the grid-shaped cavity 197 includes the entire area of the dicing channel regions 900 and further includes frame-shaped peripheral areas of the semiconductor die regions 110.

A frame-shaped horizontal top surface of the second dielectric diffusion barrier layer 193 may be physically exposed within a peripheral portion of the semiconductor die region 110. The patterned sidewalls of the polymer layer 194 may have a taper angle (as measured relative to the vertical direction) in a range from 1 degree to 20 degrees, such as from 2 degrees to 10 degrees, although lesser and greater taper angles may also be used. The bottom edge of outermost tapered sidewalls of the polymer layer 194 within each semiconductor die region 110 may be laterally offset from a most proximal edge of the dicing channel regions 900 by about a second lateral offset distance lod2, which may be in a range from 300 nm to 10,000 nm, such as from 600 nm to 5,000 nm, although lesser and greater values may also be used for the second lateral offset distance lod2.

Referring to FIG. 2F, an anisotropic etch process may be performed to vertically extend the openings 195 and the grid-shaped cavity 197. The anisotropic etch process has an etch chemistry that etches the materials of the first dielectric diffusion barrier layer 191 and the second dielectric diffusion barrier layer 193 selectively to the material of the metal pads 188. The openings 195 through the polymer layer 194, the second dielectric diffusion barrier layer 193, and the silicate glass layer 192 are vertically extended through the first dielectric diffusion barrier layer 191 so that top surfaces of the metal pads 188 are physically exposed. The anisotropic etch process may vertically extend the grid-shaped cavity 197 through the second dielectric diffusion barrier layer 193 so that the top surface of the first dielectric diffusion barrier layer 191 is physically exposed at the bottom of the grid-shaped cavity 197.

The lateral dimension (i.e., the maximum lateral dimension) of each physically exposed surface of the metal pads 188 underneath the openings 195 through the passivation layer stack 190 may be selected to provide subsequent formation of die bump structures (such as copper pillar structures) thereupon. For example, the lateral dimension of each physically exposed surface of the metal pad 188 may be in a range from 5 microns to 50 microns, such as from 10 microns to 30 microns, although lesser and greater dimensions may also be used. The shape of each physically exposed surface of the metal pads 188 (as seen in a top-down view) may be a circle, a rectangle, a rounded rectangle, or any other suitable two-dimensional curvilinear shape having a closed boundary.

A frame-shaped horizontal top surface of the first dielectric diffusion barrier layer 191 may be physically exposed within a peripheral portion of the semiconductor die region 110. The bottom edge of outermost tapered sidewalls of the polymer layer 194 within each semiconductor die region 110 may be laterally offset from a most proximal edge of the dicing channel regions 900 by the second lateral offset distance lod2, which may be in a range from 300 nm to 10,000 nm, such as from 600 nm to 5,000 nm, although lesser and greater values may also be used for the second lateral offset distance lod2.

Referring to FIG. 2G, vertical stacks of a respective metallic adhesion plate 196 and a respective die bump structure 198 may be formed on the physically exposed surfaces of the metal pads 188. For example, a metallic adhesion material layer including a metallic barrier material such as titanium, a titanium-tungsten alloy, or titanium nitride may be deposited on the physically exposed surfaces of the metal pads 188 and over the passivation layer stack 190. The thickness of the metallic adhesion material layer may be in a range from 50 nm to 500 nm, although lesser and greater thicknesses may also be used. A copper seed layer having a thickness in a range from 300 nm to 1,000 nm may be deposited over the metallic adhesion material layer.

A photoresist layer (not shown) may be applied over the copper seed layer, and may be lithographically patterned to form a two-dimensional array of pillar cavities therein. Each pillar cavity may be formed entirely within the area of an interface between the metallic adhesion material layer and a metal pad 188. An electroplating process may be performed to electroplate copper within the volumes of the pillar cavities on the physically exposed surfaces of the copper seed layer. The thickness of electroplated copper may be in a range from 20 microns to 100 microns, although lesser and greater thicknesses may also be used. The photoresist layer may be subsequently removed, for example, by ashing. Horizontally-extending portions of the copper seed layer and the metallic adhesion material layer that do not underlie electroplated portions of copper may be subsequently removed by performing at least one etch process, which may comprise at least one isotropic etch process and/or at least one anisotropic etch process.

Each remaining portion of the copper seed layer and the electroplated copper material constitutes a die bump structure 198, which may be a copper pillar structure. Each die bump structure 198 may have a lateral dimension in a range from 5 microns to 50 microns, such as from 10 microns to 30 microns, although lesser and greater dimensions may also be used. The height of each die bump structure 198 may be in a range from 20 microns to 100 microns, although lesser and greater heights may also be used. Each patterned portion of the metallic adhesion material layer constitutes a metallic adhesion plate 196.

Solder material portions 199 may be applied to each of the die bump structures 198. Thus, a two-dimensional array of solder material portions 199 may be formed on the two-dimensional array of die bump structures 198, which may be a two-dimensional array of microbump structures.

Referring to FIG. 2H, the semiconductor substrate 101 of the wafer 1000 may be thinned from the backside. The thinning of the semiconductor substrate 101 may be effected by grinding, polishing, an isotropic etch process, and/or an anisotropic etch process. The thickness of the semiconductor substrate 101 after the thinning process may be in a range from 10 microns to 60 microns, although lesser and greater thicknesses may also be used.

Referring to FIGS. 2I and 2J, the wafer 1000 may be diced along the dicing channels. FIG. 2J is a top-down view of a semiconductor die 100 of FIG. 2J. The materials in the dicing channel regions 900 may be removed during the dicing process. Remaining discrete portions of the wafer 1000 after the dicing process comprise materials of the semiconductor die regions 110. Each semiconductor die region 110 that remains after the dicing process constitutes a semiconductor die 100. A semiconductor die 100 having the configuration illustrated in FIGS. 2I and 2J is herein referred to as a first semiconductor die 100.

Generally, a wafer 1000 including a passivation layer stack 190, dielectric material layers 160, metal interconnect structures 180, semiconductor devices 120, and a semiconductor substrate 101 may be diced after formation of die bump structures 198 through the passivation layer stack 190 along dicing channels into a plurality of semiconductor dies 100. Each semiconductor die 100 comprises a diced portion of the semiconductor substrate 101, which is herein referred to as a semiconductor substrate 101 of the semiconductor die 100.

Referring collectively to FIG. 2A-2I and according to an aspect of the present disclosure, at least one material layer selected from the silicate glass layer 192, the second dielectric diffusion barrier layer 193, and the polymer layer 194 is patterned prior to dicing a wafer 1000 into a plurality of semiconductor dies 100. The at least one material layer is completely removed from a respective frame-shaped peripheral region of each of the plurality of semiconductor dies 100 prior to dicing the wafer 1000. The frame-shaped peripheral region is generally proximal to the dicing channel regions 900. In one embodiment, the at least one material layer comprises the polymer layer 194, which may be patterned at the processing steps described with reference to FIG. 2E. In one embodiment, the at least one material layer further comprises the silicate glass layer 192, which may be patterned at the processing steps described with reference to FIG. 2B. In one embodiment, the at least one material layer further comprises the second dielectric diffusion barrier layer 193, which may be patterned at the processing steps described with reference to FIG. 2F.

In one embodiment, the wafer 1000 comprises dicing channel regions 900 that are removed during dicing of the wafer 1000 and semiconductor die regions 110 that become the plurality of semiconductor dies 100 upon dicing. In one embodiment, portions of the silicate glass layer 192 located within a first lateral offset distance lod1 from the dicing channel regions 900 may be removed (as described with reference to FIG. 2B), and portions of the second dielectric diffusion barrier layer 193 located within a second lateral offset distance lod2 from the dicing channel regions 900 may be removed (as described with reference to FIG. 2F). The second lateral offset distance lod2 is less than the first lateral offset distance lod1.

Upon patterning the at least one material layer selected from the silicate glass layer 192, the second dielectric diffusion barrier layer 193, and the polymer layer 194, the at least one material layer is absent from a frame-shaped peripheral region of the semiconductor die 100. In one embodiment, physically exposed surfaces of the portion of the passivation layer stack 190 that is present in the semiconductor die 100 comprise a frame-shaped horizontal surface segment 91H of a portion of the first dielectric diffusion barrier layer 191. In one embodiment, physically exposed surfaces of the portion of the passivation layer stack 190 that is present in the semiconductor die 100 comprise a tapered sidewall surface 94T of the polymer layer 194. In one embodiment, physically exposed surfaces of the portion of the passivation layer stack 190 that is present in the semiconductor die 100 comprise a sidewall surface of the second dielectric diffusion barrier layer 193. In one embodiment, physically exposed surfaces of the portion of the passivation layer stack 190 that is present in the semiconductor die 100 comprise a vertical sidewall of the first dielectric diffusion barrier layer 191.

Generally, the semiconductor die 100 comprises a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; and die bump structures 198 vertically extending through the passivation layer stack 190 and electrically connected to a subset of the metal interconnect structures 180. The passivation layer stack 190 comprises a first frame-shaped horizontal surface located in a peripheral region and vertically offset relative to a distal horizontal surface of the polymer layer 194 that laterally surrounds the die bump structures 198.

FIG. 2K is a vertical cross-sectional view of an alternative configuration of the first semiconductor die 100. The alternative configuration of the first semiconductor die 100 may be derived from the first semiconductor die 100 illustrated in FIGS. 2H and 2I by reducing the second lateral offset distance lod2 to zero.

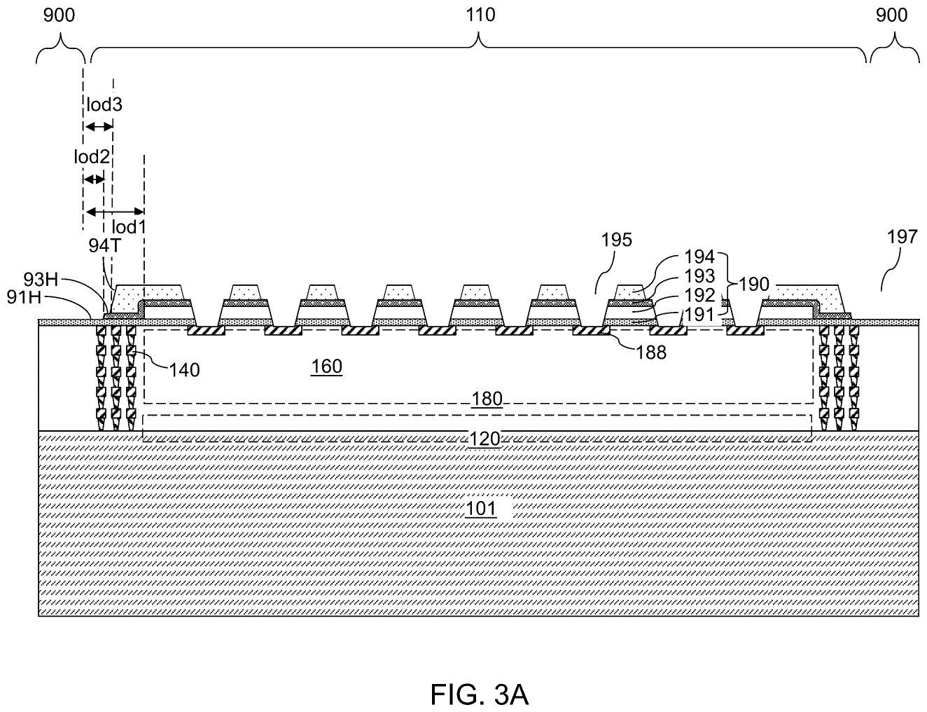

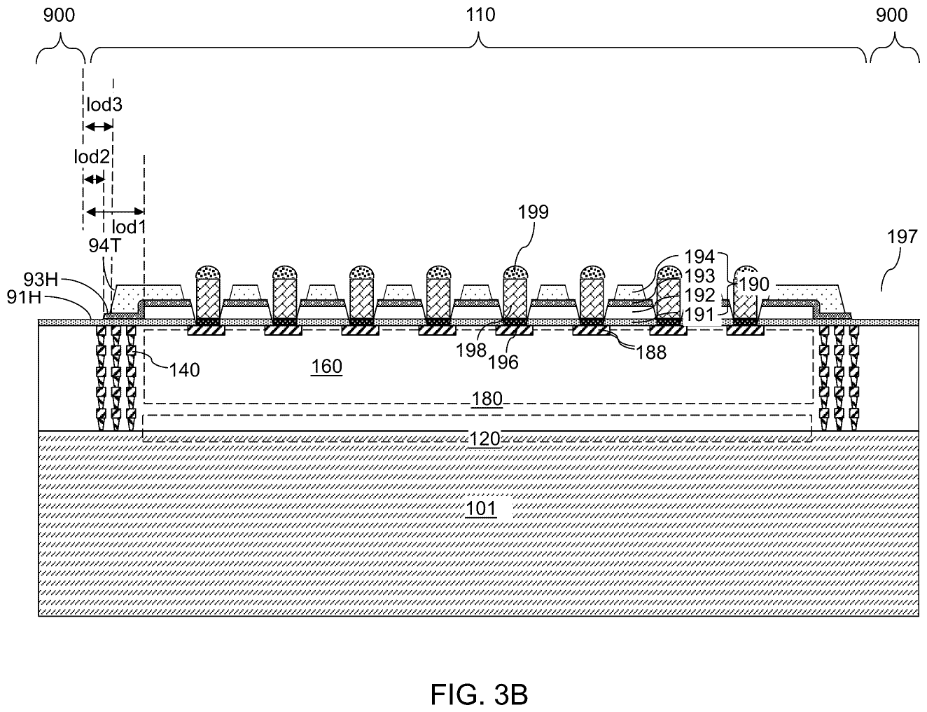

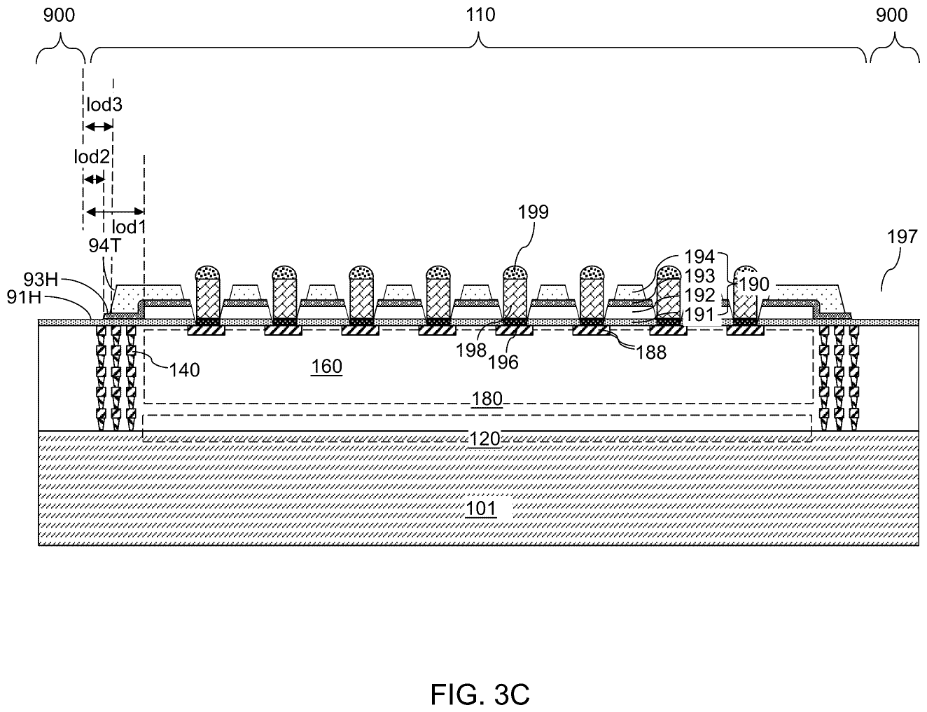

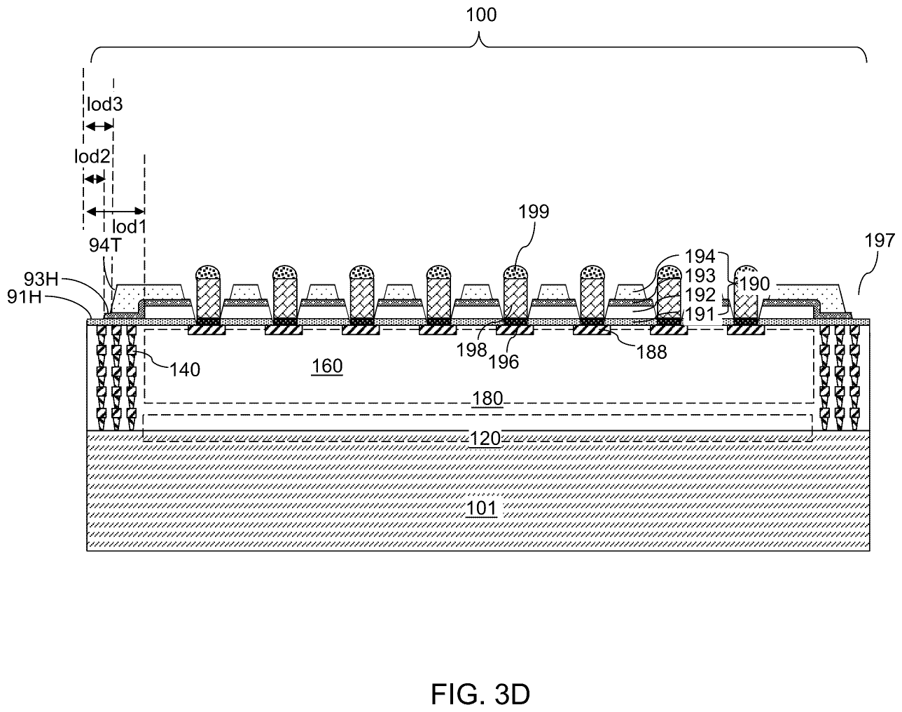

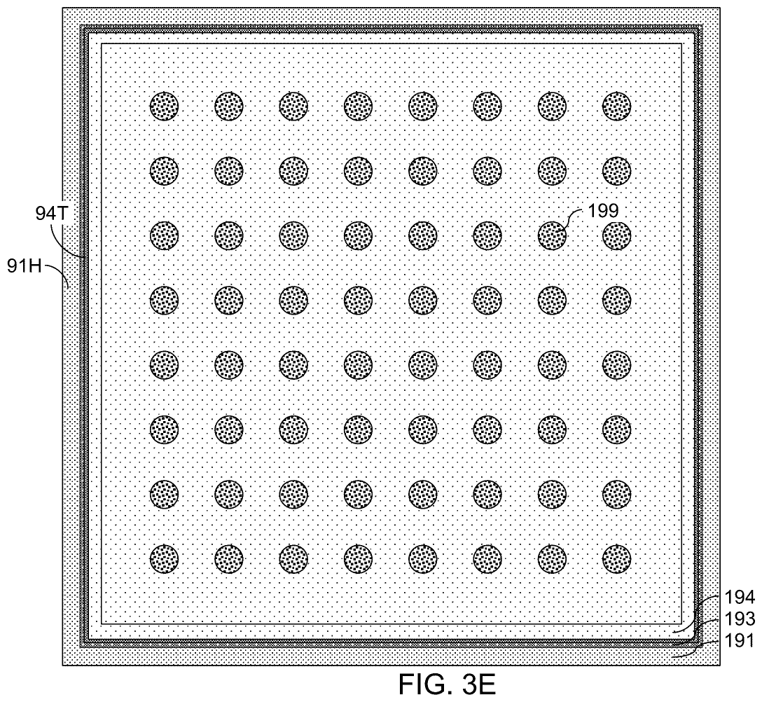

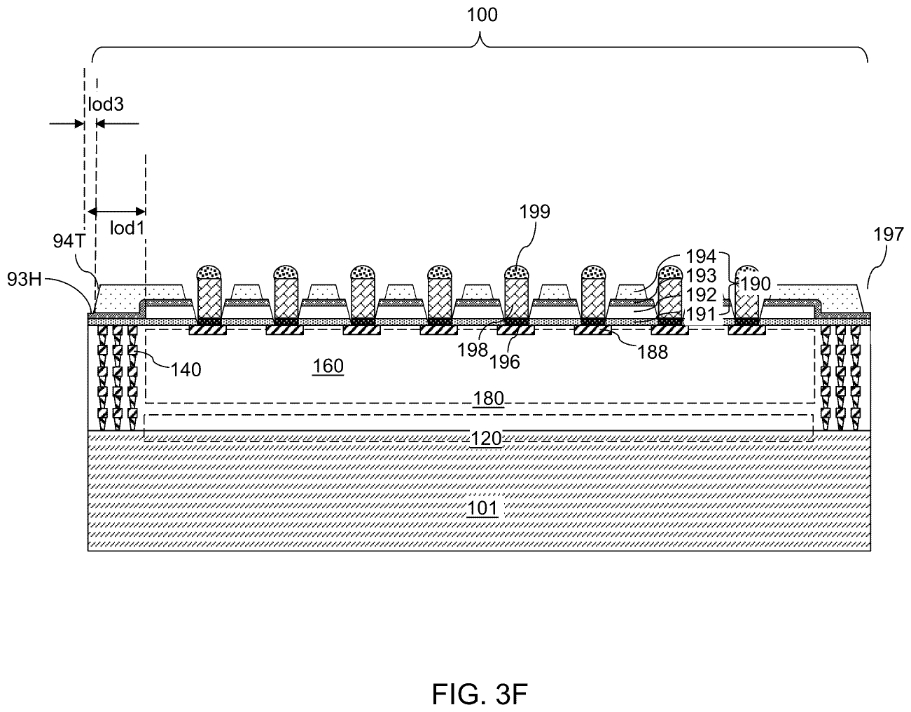

FIG. 3A-3D are sequential vertical cross-sectional views of a second semiconductor die 100 during fabrication and dicing according to an embodiment of the present disclosure.

Referring to FIG. 3A, an alternative configuration of the wafer 1000, of which a semiconductor die region 110 and two dicing channel regions 900 are shown, may be derived from the configuration of the wafer 1000 illustrated in FIG. 2F by trimming the polymer layer 194, for example, by performing an isotropic trimming process. The trimming distance may be in a range from 100 nm to about 50 % of the thickness of the polymer layer 194 at the processing steps of FIG. 2F.

The thickness of the polymer layer 194 around the openings 195 after the trimming process may be in a range from 1 micron to 10 microns, such as from 1.5 microns to 5 microns, although lesser and greater thicknesses may also be used. The trimming of the polymer layer 194 laterally shifts a bottom edge of each outer sidewall of the polymer layer 194 inward by the trimming distance. Thus, the bottom edge of each outer sidewall of the polymer layer 194 may be laterally offset relative to a most proximal dicing channel region 900 by a third lateral offset distance lod3, which is greater than the second lateral offset distance lod2 by the trimming distance. In one embodiment, outer sidewalls of the polymer layer 194 may be formed entirely within the area of the etch-stop region. In one embodiment, the third lateral offset distance lod3 is less than the first lateral offset distance lod1.

Referring to FIG. 3B, the processing steps described with reference to FIG. 2G may be performed to form a two-dimensional array of metallic adhesion plates 196, a two-dimensional array of die bump structures 198, and a two-dimensional array of solder material portions 199.

Referring to FIG. 3C, the processing steps described with reference to FIG. 2H may be performed to thin the semiconductor substrate 101.

Referring to FIGS. 3D and 3E, the processing steps described with reference to FIGS. 2I and 2J may be performed to dice the wafer 1000 into a plurality of semiconductor dies 100. A semiconductor die 100 having the configuration illustrated in FIGS. 3D and 3E is herein referred to as a second semiconductor die 100.

Generally, a wafer 1000 including a passivation layer stack 190, dielectric material layers 160, metal interconnect structures 180, semiconductor devices 120, and a semiconductor substrate 101 may be diced after formation of die bump structures 198 through the passivation layer stack 190 along dicing channels into a plurality of semiconductor dies 100. Each semiconductor die 100 comprises a diced portion of the semiconductor substrate 101, which is herein referred to as a semiconductor substrate 101 of the semiconductor die 100.

Referring collectively to FIG. 2A-2F and 3A-3E and according to an aspect of the present disclosure, at least one material layer selected from the silicate glass layer 192, the second dielectric diffusion barrier layer 193, and the polymer layer 194 is patterned prior to dicing a wafer 1000 into a plurality of semiconductor dies 100. The at least one material layer is completely removed from a respective frame-shaped peripheral region of each of the plurality of semiconductor dies 100 prior to dicing the wafer 1000. The frame-shaped peripheral region is generally proximal to the dicing channel regions 900. In one embodiment, the at least one material layer comprises the polymer layer 194, which may be patterned at the processing steps described with reference to FIG. 2E and with reference to FIG. 3A. In one embodiment, the at least one material layer further comprises the silicate glass layer 192, which may be patterned at the processing steps described with reference to FIG. 2B. In one embodiment, the at least one material layer further comprises the second dielectric diffusion barrier layer 193, which may be patterned at the processing steps described with reference to FIG. 2F.

In one embodiment, the wafer 1000 comprises dicing channel regions 900 that may be removed during dicing of the wafer 1000 and semiconductor die regions 110 that become the plurality of semiconductor dies 100 upon dicing. In one embodiment, portions of the silicate glass layer 192 located within a first lateral offset distance lod1 from the dicing channel regions 900 may be removed (as described with reference to FIG. 2B), and portions of the second dielectric diffusion barrier layer 193 located within a second lateral offset distance lod2 from the dicing channel regions 900 may be removed (as described with reference to FIG. 2F). The second lateral offset distance lod2 is less than the first lateral offset distance lod1. In one embodiment, portions of the polymer layer 194 located within a third lateral offset distance lod3 from the dicing channel regions 900 may be removed (as described with reference to FIG. 3A). The third lateral offset distance lod3 is greater than the second lateral offset distance lod2, and is less than the first lateral offset distance lod1.

Upon patterning the at least one material layer selected from the silicate glass layer 192, the second dielectric diffusion barrier layer 193, and the polymer layer 194, the at least one material layer is absent from a frame-shaped peripheral region of the semiconductor die 100. In one embodiment, physically exposed surfaces of the portion of the passivation layer stack 190 that is present in the semiconductor die 100 comprise a frame-shaped horizontal surface segment 91H of a portion of the first dielectric diffusion barrier layer 191. In one embodiment, physically exposed surfaces of the portion of the passivation layer stack 190 that is present in the semiconductor die 100 comprise a tapered sidewall surface 94T of the polymer layer 194. In one embodiment, physically exposed surfaces of the portion of the passivation layer stack 190 that is present in the semiconductor die 100 comprise a sidewall surface of the second dielectric diffusion barrier layer 193. In one embodiment, physically exposed surfaces of the portion of the passivation layer stack 190 that is present in the semiconductor die 100 comprise a vertical sidewall of the first dielectric diffusion barrier layer 191. In one embodiment, physically exposed surfaces of the portion of the passivation layer stack 190 that is present in the semiconductor die 100 comprise a frame-shaped horizontal surface segment 93H of a portion of the second dielectric diffusion barrier layer 193.

Generally, the semiconductor die 100 comprises a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; and die bump structures 198 vertically extending through the passivation layer stack 190 and electrically connected to a subset of the metal interconnect structures 180. The passivation layer stack 190 comprises a first frame-shaped horizontal surface located in a peripheral region and vertically offset relative to a distal horizontal surface of the polymer layer 194 that laterally surrounds the die bump structures 198.

FIG. 3F is a vertical cross-sectional view of an alternative configuration of the second semiconductor die 100. The alternative configuration of the second semiconductor die 100 may be derived from the second semiconductor die 100 illustrated in FIGS. 3D and 3E by reducing the second lateral offset distance lod2 to zero.

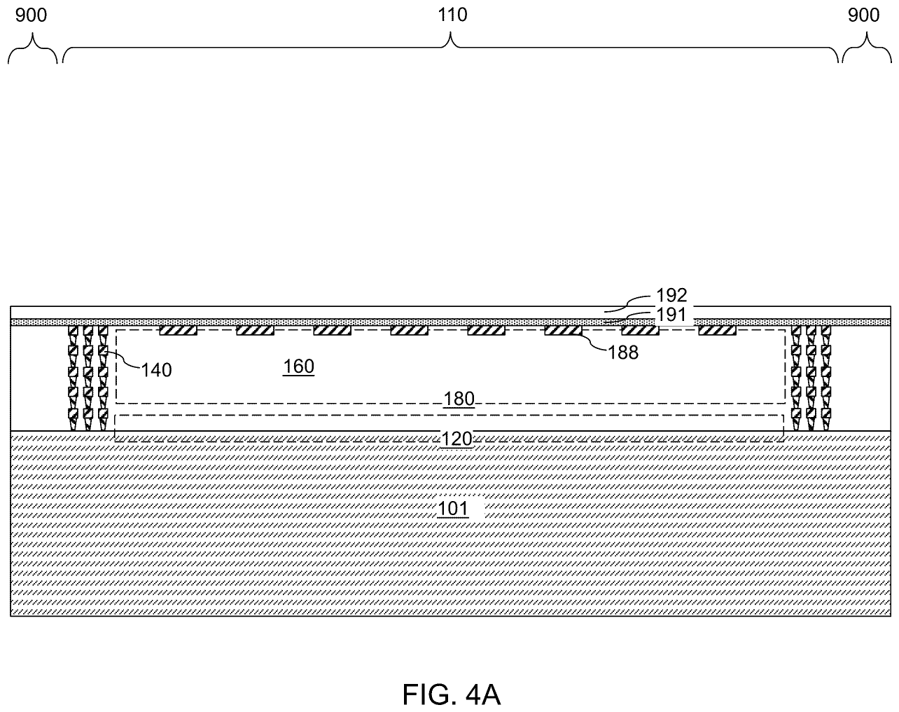

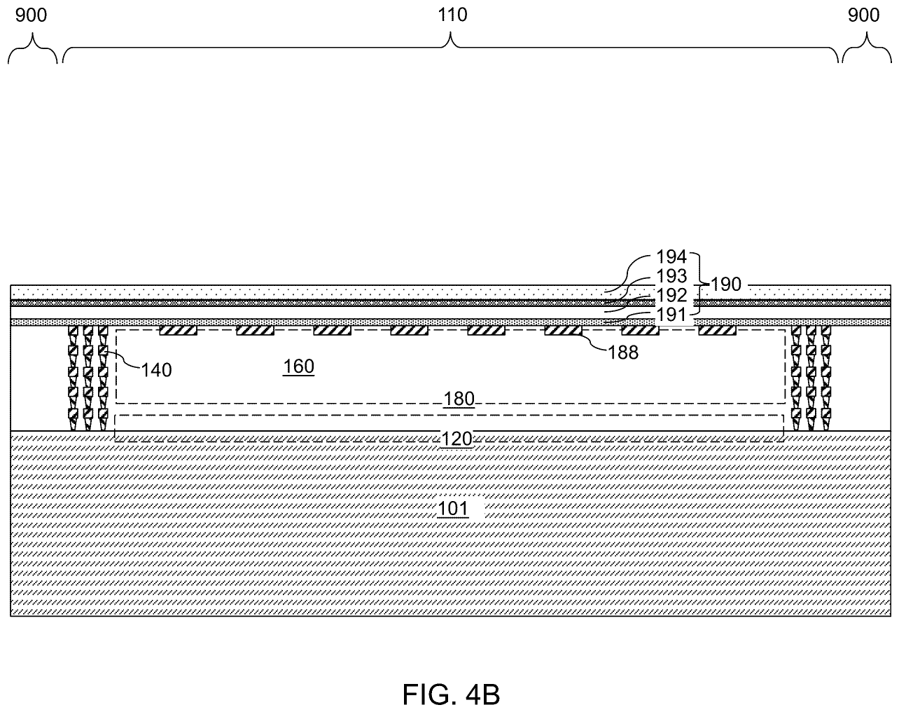

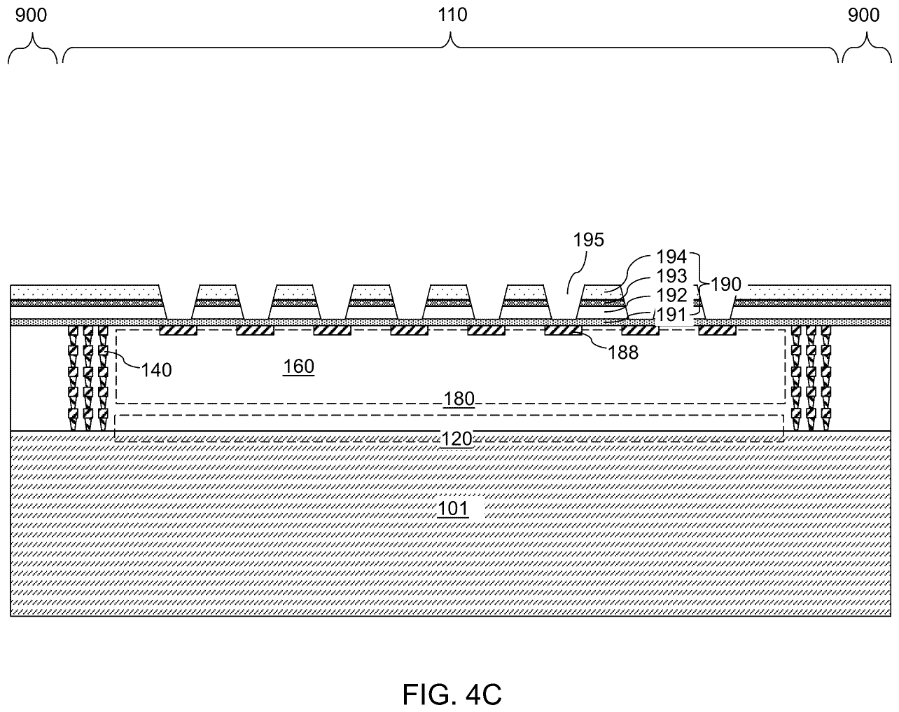

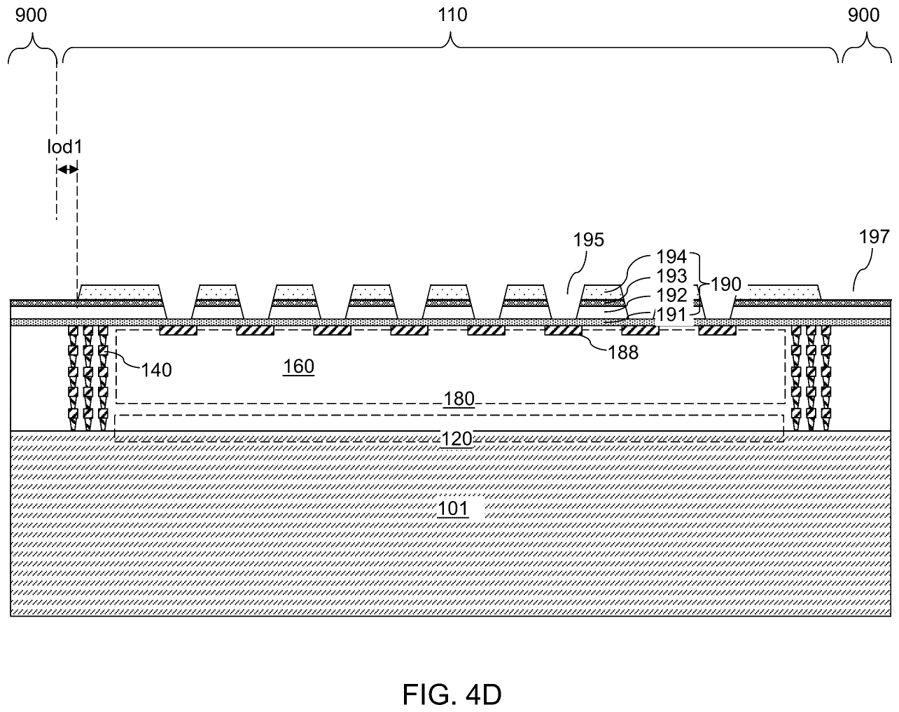

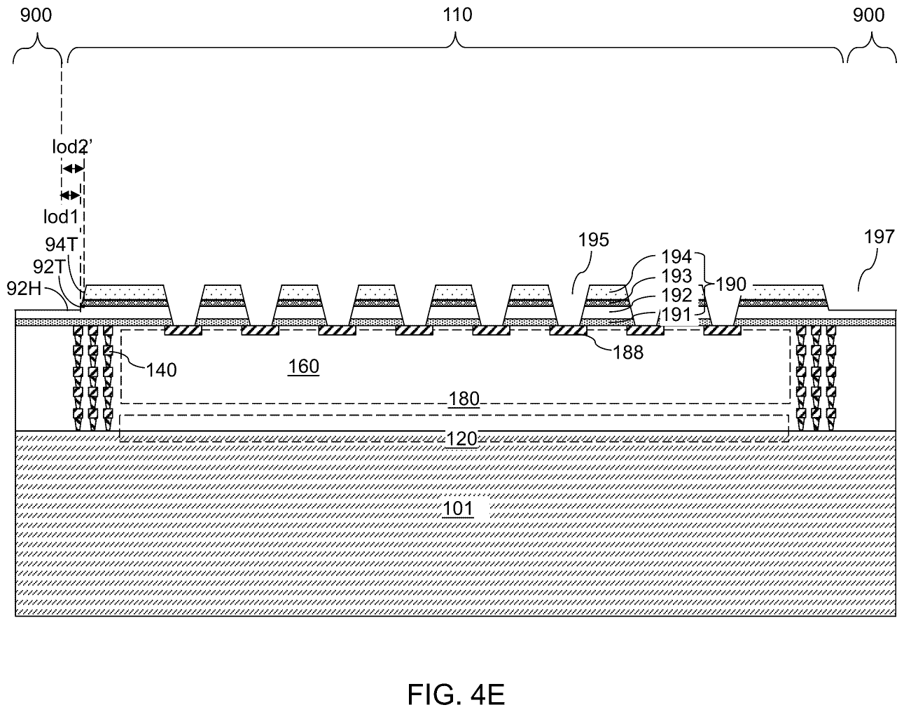

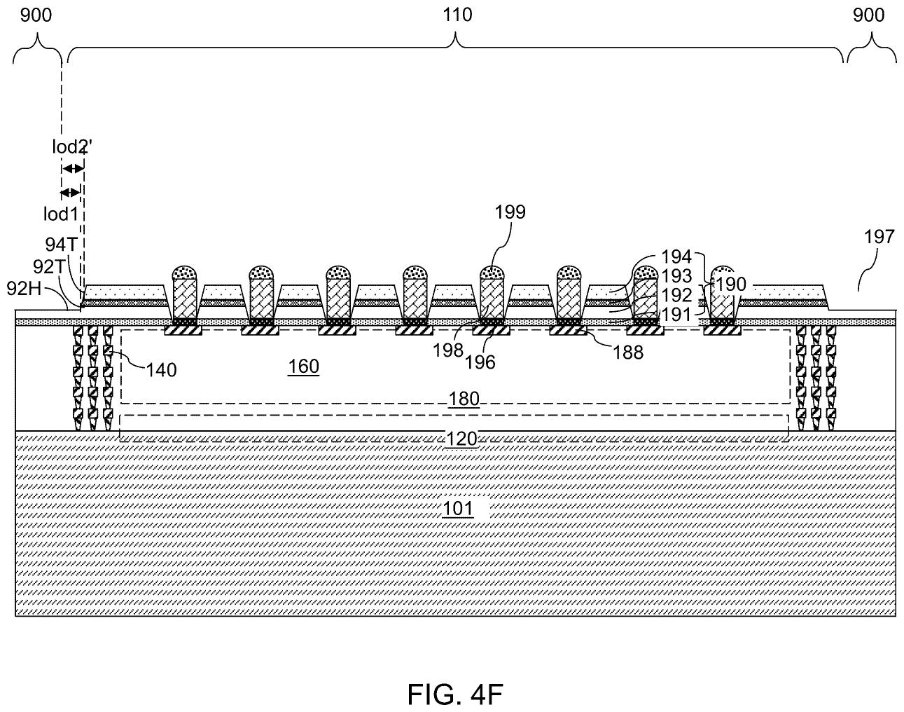

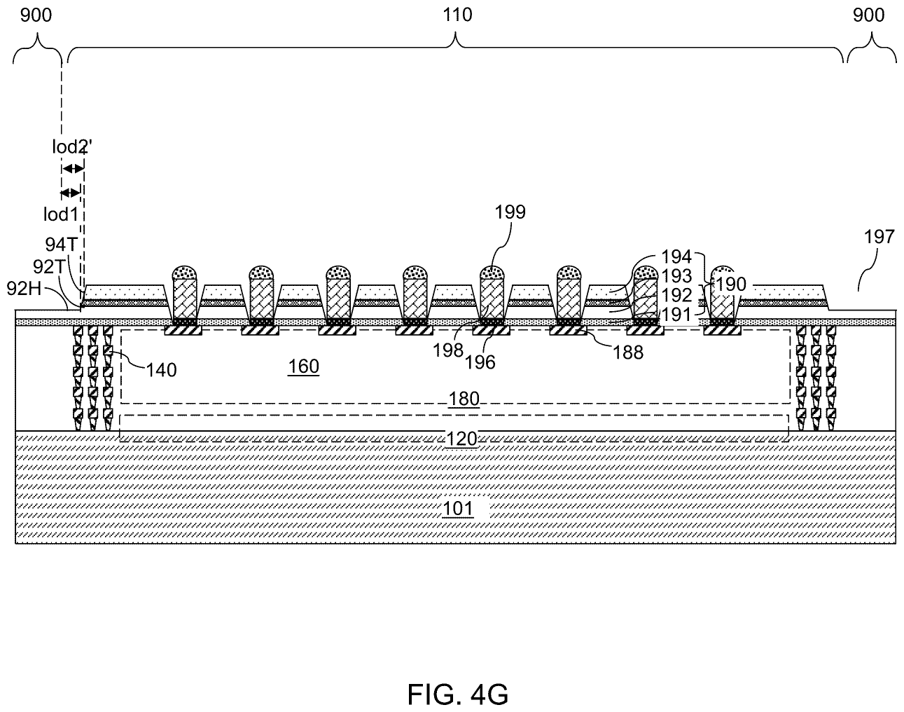

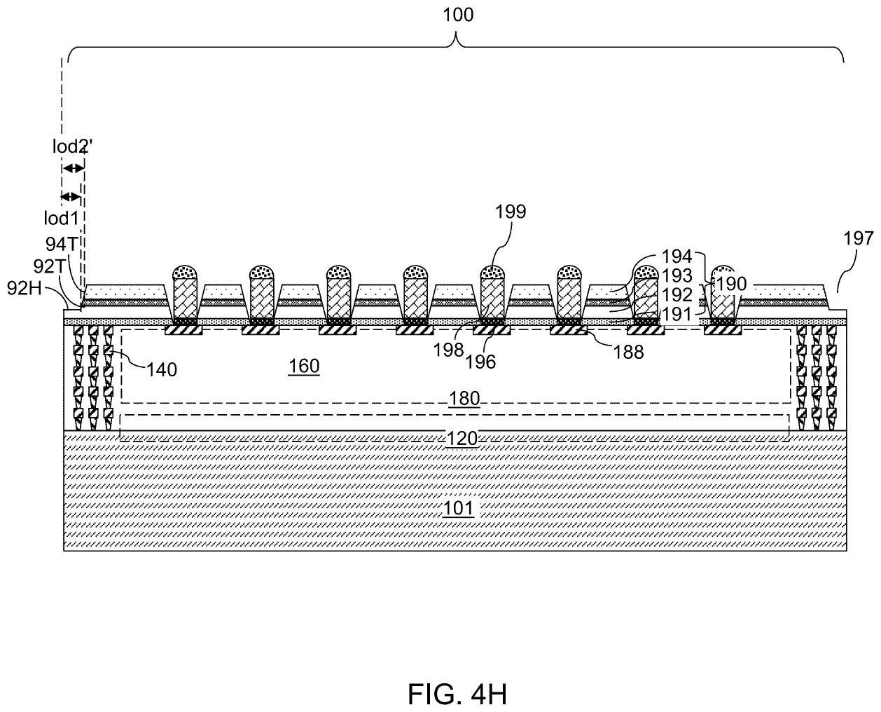

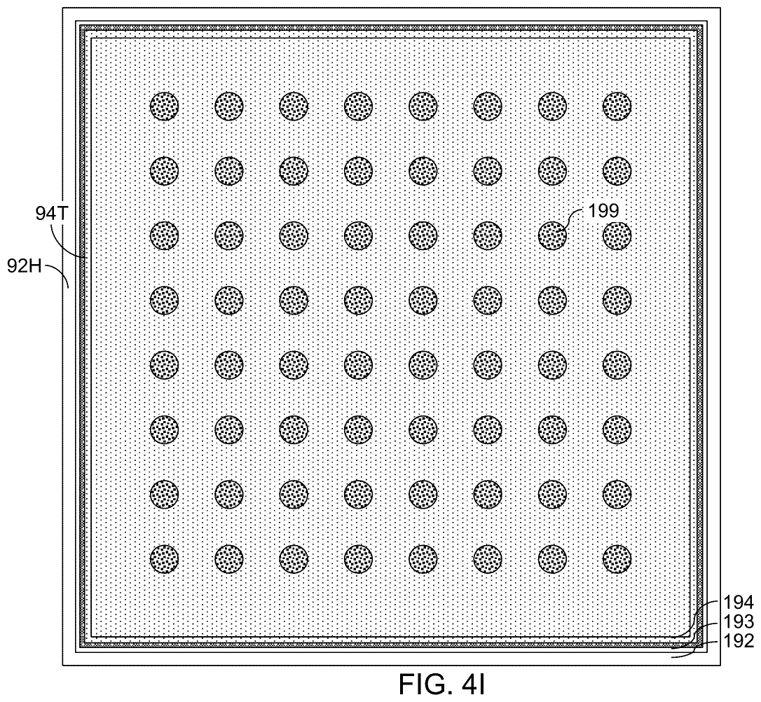

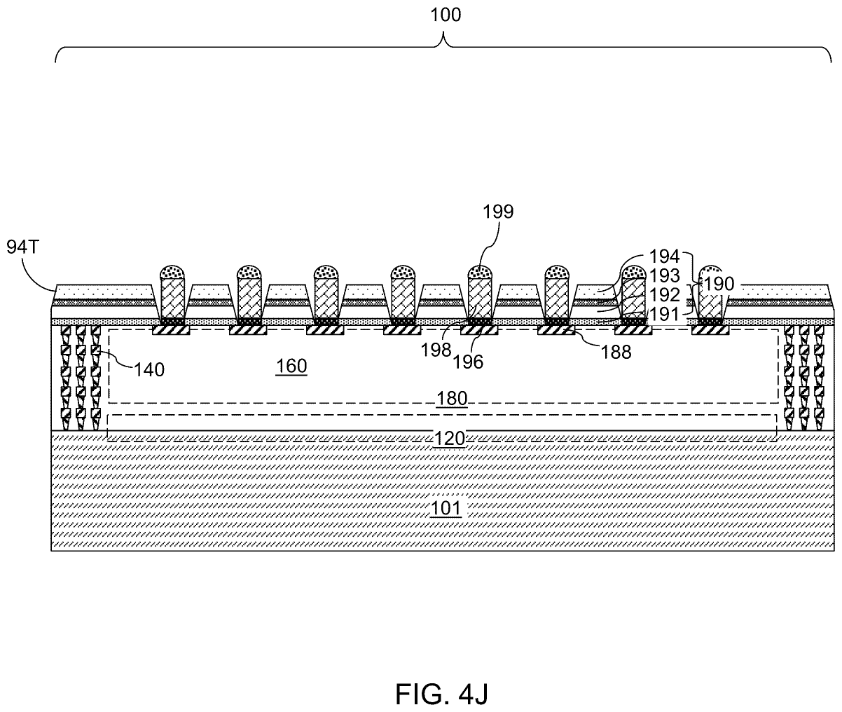

FIG. 4A-4H are sequential vertical cross-sectional views of a third semiconductor die 100 during fabrication and dicing according to an embodiment of the present disclosure.

Referring to FIG. 4A, a portion of the wafer 1000 in FIG. 1A is illustrated after formation of a first dielectric diffusion barrier layer 191 and a silicate glass layer 192 over the dielectric material layers 160 and the metal pads 188. The structure illustrated in FIG. 4A may be the same as the structure described with reference to FIG. 2A.

Referring to FIG. 4B, the processing steps described with reference to FIG. 2C may be performed to form a second dielectric diffusion barrier layer 193 and a polymer layer 194. Thus, the patterning step described with reference to FIG. 2B is omitted in this embodiment.

Referring to FIG. 4C, the processing steps described with reference to FIG. 2D may be performed to form a two-dimensional array of openings 195 through the polymer layer 194, the second dielectric diffusion barrier layer 193, and the silicate glass layer 192.

Referring to FIG. 4D, a photoresist layer (not shown) may be applied over the passivation layer stack 190, and may be lithographically patterned to cover the area of the semiconductor devices 120 and an inner portion of the edge-seal region without covering an outer portion of the edge-seal region or the dicing channel region 900. An etch process (such as an anisotropic etch process) may be performed to remove unmasked portions of the polymer layer 194 selectively to the material of the second dielectric diffusion barrier layer 193. A grid-shaped cavity 197 may be formed along the dicing channel regions 900 such that the area of the grid-shaped cavity 197 includes the entire area of the dicing channel regions 900 and further includes frame-shaped peripheral areas of the semiconductor die regions 110.

A frame-shaped horizontal top surface of the second dielectric diffusion barrier layer 193 may be physically exposed within a peripheral portion of the semiconductor die region 110. The patterned sidewalls of the polymer layer 194 may have a taper angle (as measured relative to the vertical direction) in a range from 1 degree to 20 degrees, such as from 2 degrees to 10 degrees, although lesser and greater taper angles may also be used. The bottom edge of outermost tapered sidewalls of the polymer layer 194 within each semiconductor die region 110 may be laterally offset from a most proximal edge of the dicing channel regions 900 by about a lateral offset distance, which is herein referred to as a first lateral offset distance lod1. The first lateral offset distance lod1 may be in a range from 300 nm to 10,000 nm, such as from 600 nm to 5,000 nm, although lesser and greater values may also be used for the first lateral offset distance lod1.

Referring to FIG. 4E, an anisotropic etch process may be performed to vertically extend the openings 195 and the grid-shaped cavity 197. The anisotropic etch process has an etch chemistry that etches the materials of the first dielectric diffusion barrier layer 191, the silicate glass layer 192, and the second dielectric diffusion barrier layer 193 selectively to the material of the metal pads 188. The openings 195 through the polymer layer 194, the second dielectric diffusion barrier layer 193, and the silicate glass layer 192 are vertically extended through the first dielectric diffusion barrier layer 191 so that top surfaces of the metal pads 188 are physically exposed. The anisotropic etch process may vertically extend the grid-shaped cavity 197 through the second dielectric diffusion barrier layer 193 and into an upper portion of the silicate glass layer 192 so that a recessed horizontal surface of the silicate glass layer 192 is physically exposed at the bottom of the grid-shaped cavity 197.

The lateral dimension (i.e., the maximum lateral dimension) of each physically exposed surface of the metal pads 188 underneath the openings 195 through the passivation layer stack 190 may be selected to provide subsequent formation of die bump structures (such as copper pillar structures) thereupon. For example, the lateral dimension of each physically exposed surface of the metal pad 188 may be in a range from 5 microns to 50 microns, such as from 10 microns to 30 microns, although lesser and greater dimensions may also be used. The shape of each physically exposed surface of the metal pads 188 (as seen in a top-down view) may be a circle, a rectangle, a rounded rectangle, or any other suitable two-dimensional curvilinear shape having a closed boundary.

A frame-shaped horizontal top surface of the silicate glass layer 192 may be physically exposed within a peripheral portion of the semiconductor die region 110. The bottom edge of each physically exposed tapered sidewalls of the silicate glass layer 192 within each semiconductor die region 110 may be laterally offset from a most proximal edge of the dicing channel regions 900 by the first lateral offset distance lod1, which may be in a range from 300 nm to 10,000 nm, such as from 600 nm to 5,000 nm, although lesser and greater values may also be used for the first lateral offset distance lod1. A bottom edge of each tapered outer sidewall of the polymer layer 194 may be laterally spaced from a most proximal edge of the dicing channel regions 900 by a lateral offset distance (which may be referred to as a second lateral offset distance lod2′) that is greater than the first lateral offset distance lod1.

Generally, portions of the silicate glass layer 192 that are not masked by the second dielectric diffusion barrier layer 193 to a thickness that is greater than zero and is less than an original thickness of the silicate glass layer 192 after patterning the second dielectric diffusion barrier layer 193. In one embodiment, the wafer 1000 comprises dicing channel regions 900 that are removed during dicing of the wafer 1000 and semiconductor die regions 110 that become the plurality of semiconductor dies 100 upon dicing. Portions of the second dielectric diffusion barrier layer 193 located within a first lateral offset distance lod1 from the dicing channel regions 900 may be removed by the anisotropic etch process.

Physically exposed surfaces of the portion of the passivation layer stack 190 that is present in the semiconductor die 100 comprise a frame-shaped horizontal surface segment 92H of a portion of the silicate glass layer 192. Physically exposed surfaces of the portion of the passivation layer stack 190 that is present in the semiconductor die 100 comprise a tapered sidewall surface 94T of the polymer layer 194. In one embodiment, physically exposed surfaces of the portion of the passivation layer stack 190 that is present in the semiconductor die 100 comprise a tapered sidewall surface 92T of the silicate glass layer 192.

Referring to FIG. 4F, the processing steps described with reference to FIG. 2G may be performed to form a two-dimensional array of metallic adhesion plates 196, a two-dimensional array of die bump structures 198, and a two-dimensional array of solder material portions 199.

Referring to FIG. 4G the processing steps described with reference to FIG. 2H may be performed to thin the semiconductor substrate 101.

Referring to FIGS. 4H and 4I, the processing steps described with reference to FIGS. 2I and 2J may be performed to dice the wafer 1000 into a plurality of semiconductor dies 100. A semiconductor die 100 having the configuration illustrated in FIGS. 4H and 4I is herein referred to as a third semiconductor die 100.

Generally, a wafer 1000 including a passivation layer stack 190, dielectric material layers 160, metal interconnect structures 180, semiconductor devices 120, and a semiconductor substrate 101 may be diced after formation of die bump structures 198 through the passivation layer stack 190 along dicing channels into a plurality of semiconductor dies 100. Each semiconductor die 100 comprises a diced portion of the semiconductor substrate 101, which is herein referred to as a semiconductor substrate 101 of the semiconductor die 100.

Referring collectively to FIG. 4A-4I and according to an aspect of the present disclosure, at least one material layer selected from the silicate glass layer 192, the second dielectric diffusion barrier layer 193, and the polymer layer 194 is patterned prior to dicing a wafer 1000 into a plurality of semiconductor dies 100. The at least one material layer is completely removed from a respective frame-shaped peripheral region of each of the plurality of semiconductor dies 100 prior to dicing the wafer 1000. The frame-shaped peripheral region is generally proximal to the dicing channel regions 900. In one embodiment, the at least one material layer comprises the polymer layer 194, which may be patterned at the processing steps described with reference to FIG. 4D. In one embodiment, the at least one material layer further comprises the second dielectric diffusion barrier layer 193, which may be patterned at the processing steps described with reference to FIG. 4E. In one embodiment, the silicate glass layer 192 may be partially removed from a frame-shaped peripheral region of each of the plurality of semiconductor dies 100 prior to dicing the wafer 1000, for example, at the processing steps described with reference to FIG. 4E.

In one embodiment, the wafer 1000 comprises dicing channel regions 900 that are removed during dicing of the wafer 1000 and semiconductor die regions 110 that become the plurality of semiconductor dies 100 upon dicing. In one embodiment, portions of the silicate glass layer 192 located within a first lateral offset distance lod1 from the dicing channel regions 900 may be removed (as described with reference to FIG. 4D). Subsequently, portions of the second dielectric diffusion barrier layer 193 located within the first offset distance lod1 from the dicing channel regions 900 may be removed (as described with reference to FIG. 4E), and portions of the silicate glass layer 192 located within a second lateral offset distance lod2′ from the dicing channel regions 900 may be removed (as described with reference to FIG. 4E). The second lateral offset distance lod2′ is greater than the first lateral offset distance lod1.

Upon patterning the at least one material layer selected from the silicate glass layer 192, the second dielectric diffusion barrier layer 193, and the polymer layer 194, the at least one material layer is absent from a frame-shaped peripheral region of the semiconductor die 100. In one embodiment, physically exposed surfaces of the portion of the passivation layer stack 190 that is present in the semiconductor die 100 comprise a frame-shaped horizontal surface segment 92H of a portion of the silicate glass layer 192. In one embodiment, physically exposed surfaces of the portion of the passivation layer stack 190 that is present in the semiconductor die 100 comprise a tapered sidewall surface 94T of the polymer layer 194. In one embodiment, physically exposed surfaces of the portion of the passivation layer stack 190 that is present in the semiconductor die 100 comprise a tapered sidewall surface 92T of the silicate glass layer 192. In one embodiment, physically exposed surfaces of the portion of the passivation layer stack 190 that is present in the semiconductor die 100 comprise a sidewall surface of the second dielectric diffusion barrier layer 193. In one embodiment, physically exposed surfaces of the portion of the passivation layer stack 190 that is present in the semiconductor die 100 comprise a vertical sidewall of the first dielectric diffusion barrier layer 191.

Generally, the semiconductor die 100 comprises a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; and die bump structures 198 vertically extending through the passivation layer stack 190 and electrically connected to a subset of the metal interconnect structures 180. The passivation layer stack 190 comprises a first frame-shaped horizontal surface located in a peripheral region and vertically offset relative to a distal horizontal surface of the polymer layer 194 that laterally surrounds the die bump structures 198.

FIG. 4J is a vertical cross-sectional view of an alternative configuration of the third semiconductor die 100. The alternative configuration of the second semiconductor die 100 may be derived from the third semiconductor die 100 illustrated in FIGS. 4H and 4I by reducing the first lateral offset distance lod1 to zero.

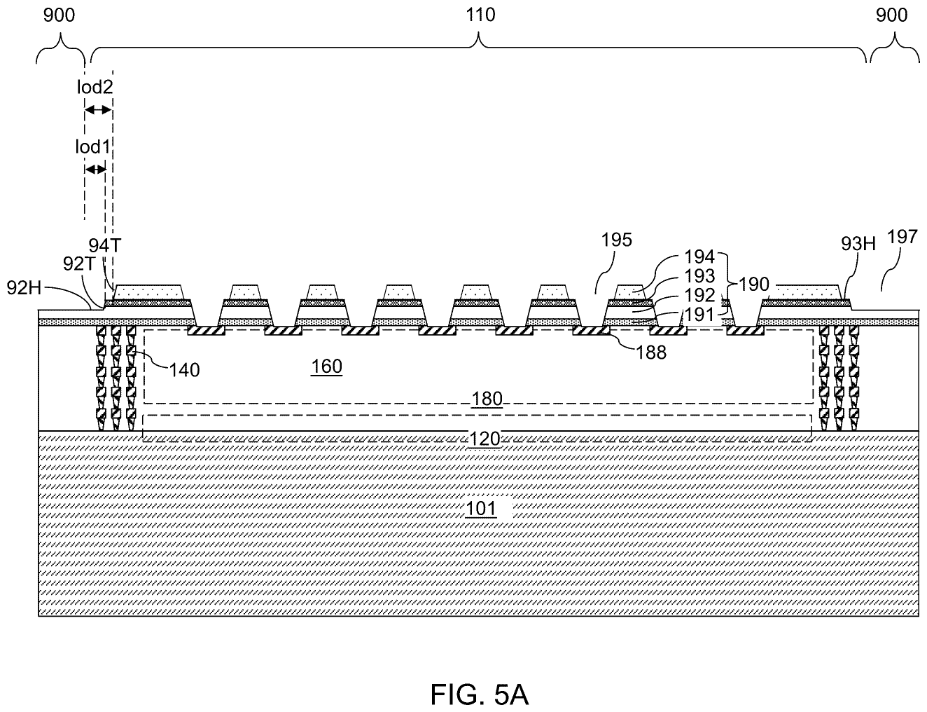

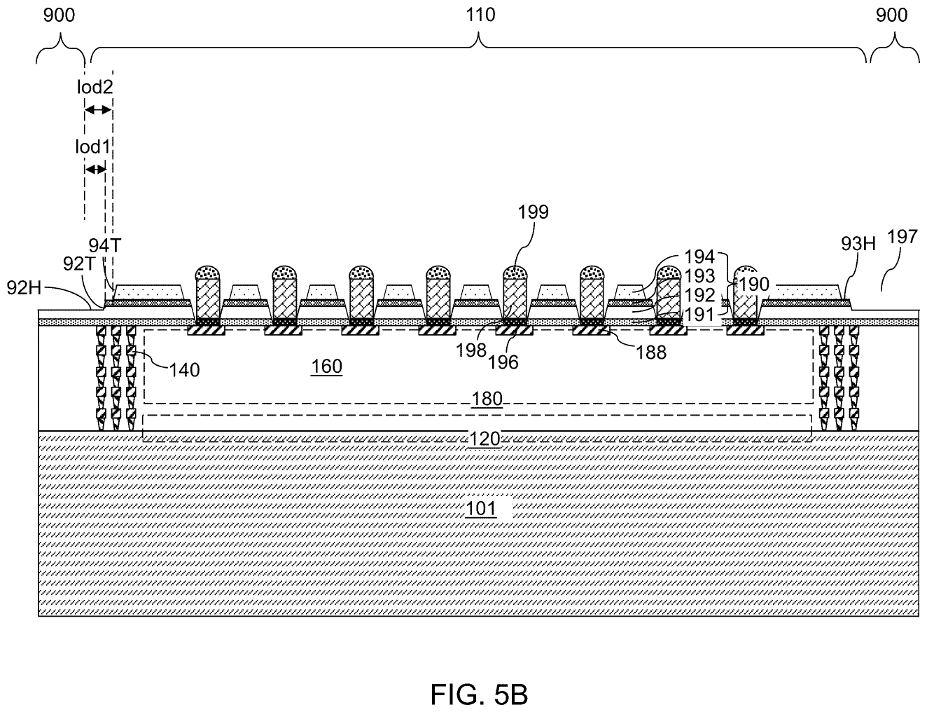

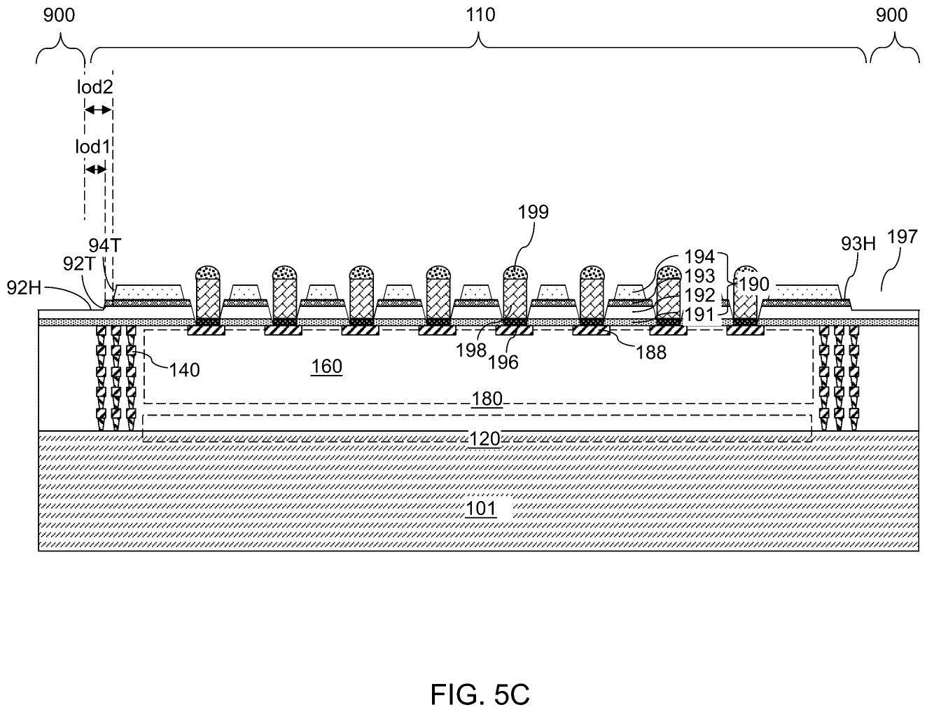

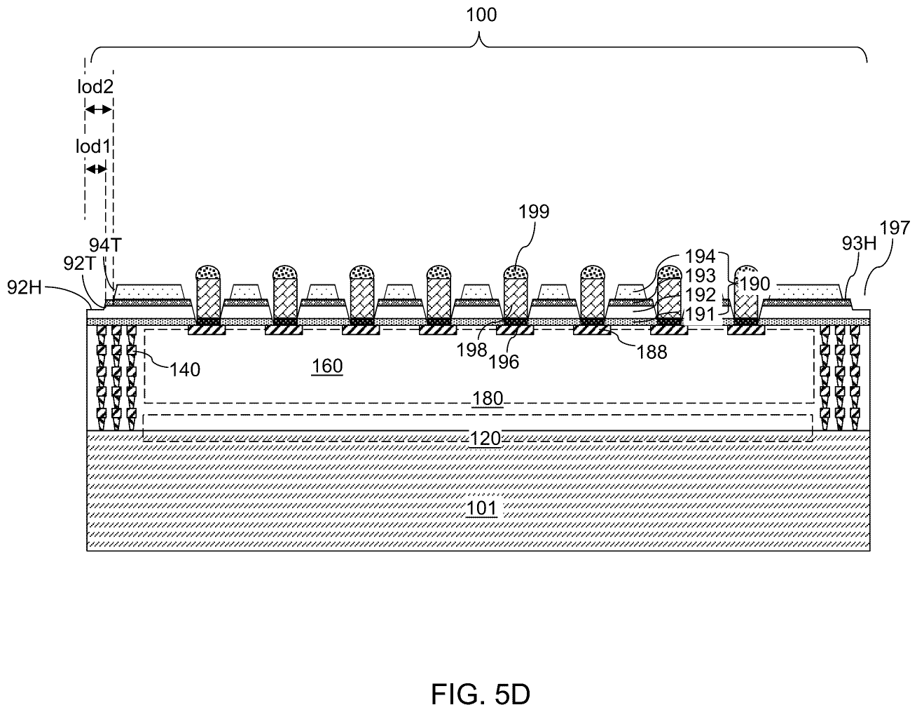

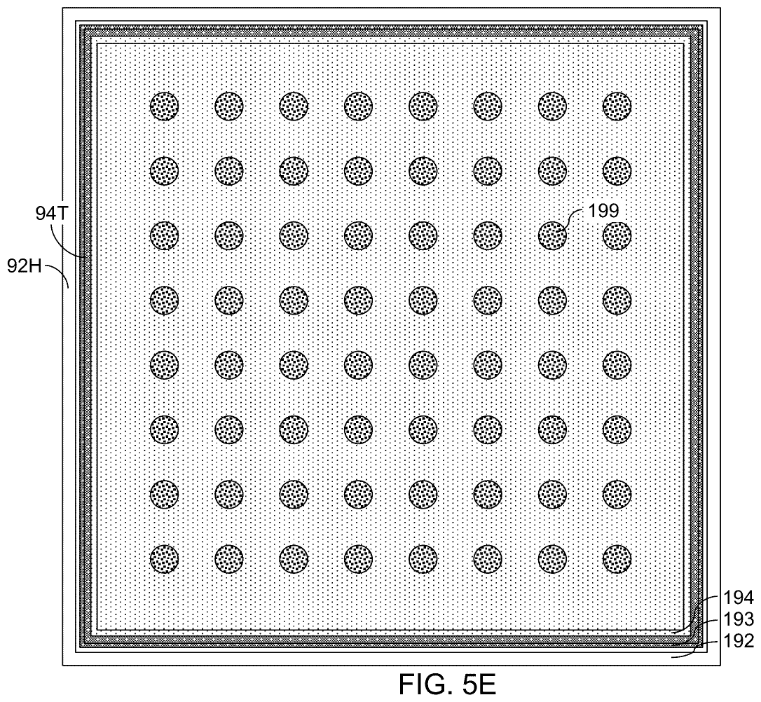

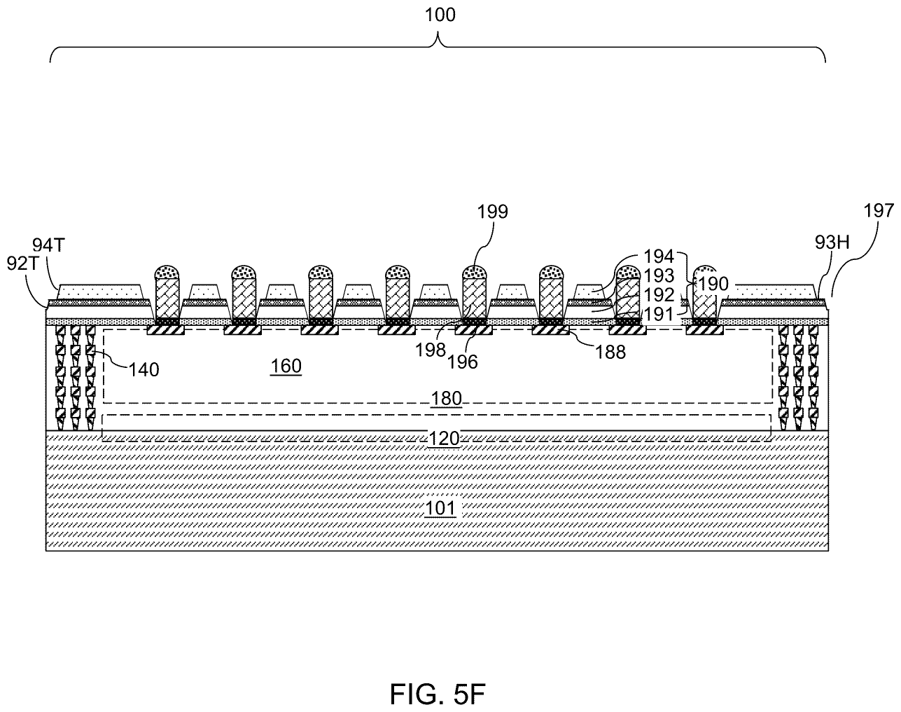

FIG. 5A-5D are sequential vertical cross-sectional views of a fourth semiconductor die 100 during fabrication and dicing according to an embodiment of the present disclosure.

Referring to FIG. 5A, an alternative configuration of the wafer 1000, of which a semiconductor die region 110 and two dicing channel regions 900 are shown, may be derived from the configuration of the wafer 1000 illustrated in FIG. 4E by trimming the polymer layer 194, for example, by performing an isotropic trimming process. The trimming distance may be in a range from 100 nm to about 50% of the thickness of the polymer layer 194 at the processing steps of FIG. 4E.

The thickness of the polymer layer 194 around the openings 195 after the trimming process may be in a range from 1 micron to 10 microns, such as from 1.5 microns to 5 microns, although lesser and greater thicknesses may also be used. The trimming of the polymer layer 194 laterally shifts a bottom edge of each outer sidewall of the polymer layer 194 inward by the trimming distance. Thus, the bottom edge of each outer sidewall of the polymer layer 194 may be laterally offset relative to a most proximal dicing channel region 900 by a second lateral offset distance lod2, which is greater than the first lateral offset distance lod1 by more than the trimming distance. In one embodiment, outer sidewalls of the polymer layer 194 may be formed entirely within the area of the etch-stop region.

Physically exposed surfaces of the portion of the passivation layer stack 190 that is present in the semiconductor die 100 comprise a frame-shaped horizontal surface segment 92H of a portion of the silicate glass layer 192. Physically exposed surfaces of the portion of the passivation layer stack 190 that is present in the semiconductor die 100 comprise a tapered sidewall surface 94T of the polymer layer 194. In one embodiment, physically exposed surfaces of the portion of the passivation layer stack 190 that is present in the semiconductor die 100 comprise a tapered sidewall surface 92T of the silicate glass layer 192. In one embodiment, physically exposed surfaces of the portion of the passivation layer stack 190 that is present in the semiconductor die 100 comprise a frame-shaped horizontal surface segment 93H of the second dielectric diffusion barrier layer 193.

Referring to FIG. 5B, the processing steps described with reference to FIG. 2G may be performed to form a two-dimensional array of metallic adhesion plates 196, a two-dimensional array of die bump structures 198, and a two-dimensional array of solder material portions 199.

Referring to FIG. 5C, the processing steps described with reference to FIG. 2H may be performed to thin the semiconductor substrate 101.

Referring to FIGS. 5D and 5E, the processing steps described with reference to FIGS. 2I and 2J may be performed to dice the wafer 1000 into a plurality of semiconductor dies 100. A semiconductor die 100 having the configuration illustrated in FIGS. 5D and 5E is herein referred to as a fourth semiconductor die 100.

Generally, a wafer 1000 including a passivation layer stack 190, dielectric material layers 160, metal interconnect structures 180, semiconductor devices 120, and a semiconductor substrate 101 may be diced after formation of die bump structures 198 through the passivation layer stack 190 along dicing channels into a plurality of semiconductor dies 100. Each semiconductor die 100 comprises a diced portion of the semiconductor substrate 101, which is herein referred to as a semiconductor substrate 101 of the semiconductor die 100.

Referring collectively to FIG. 4A-4E and 5A-5E and according to an aspect of the present disclosure, at least one material layer selected from the silicate glass layer 192, the second dielectric diffusion barrier layer 193, and the polymer layer 194 is patterned prior to dicing a wafer 1000 into a plurality of semiconductor dies 100. The at least one material layer is completely removed from a respective frame-shaped peripheral region of each of the plurality of semiconductor dies 100 prior to dicing the wafer 1000. The frame-shaped peripheral region is generally proximal to the dicing channel regions 900. In one embodiment, the at least one material layer comprises the polymer layer 194, which may be patterned at the processing steps described with reference to FIG. 4D. In one embodiment, the at least one material layer further comprises the second dielectric diffusion barrier layer 193, which may be patterned at the processing steps described with reference to FIG. 4E. In one embodiment, the silicate glass layer 192 may be partially removed from a frame-shaped peripheral region of each of the plurality of semiconductor dies 100 prior to dicing the wafer 1000, for example, at the processing steps described with reference to FIG. 4E.

In one embodiment, the wafer 1000 comprises dicing channel regions 900 that are removed during dicing of the wafer 1000 and semiconductor die regions 110 that become the plurality of semiconductor dies 100 upon dicing. In one embodiment, portions of the silicate glass layer 192 located within a first lateral offset distance lod1 from the dicing channel regions 900 may be removed (as described with reference to FIG. 4D). Subsequently, portions of the second dielectric diffusion barrier layer 193 located within the first offset distance lod1 from the dicing channel regions 900 may be removed (as described with reference to FIG. 4E), and portions of the silicate glass layer 192 located at least within the first lateral offset distance lod1 from the dicing channel regions 900 may be removed (as described with reference to FIG. 4E). Subsequently, portions of the polymer layer 194 located within a second offset distance lod2 from the dicing channel regions 900 may be removed (as described with reference to FIG. 5A),

Upon patterning the at least one material layer selected from the silicate glass layer 192, the second dielectric diffusion barrier layer 193, and the polymer layer 194, the at least one material layer is absent from a frame-shaped peripheral region of the semiconductor die 100. In one embodiment, physically exposed surfaces of the portion of the passivation layer stack 190 that is present in the semiconductor die 100 comprise a frame-shaped horizontal surface segment 92H of a portion of the silicate glass layer 192. In one embodiment, physically exposed surfaces of the portion of the passivation layer stack 190 that is present in the semiconductor die 100 comprise a tapered sidewall surface 94T of the polymer layer 194. In one embodiment, physically exposed surfaces of the portion of the passivation layer stack 190 that is present in the semiconductor die 100 comprise a tapered sidewall surface 92T of the silicate glass layer 192. In one embodiment, physically exposed surfaces of the portion of the passivation layer stack 190 that is present in the semiconductor die 100 comprise a sidewall surface of the second dielectric diffusion barrier layer 193. In one embodiment, physically exposed surfaces of the portion of the passivation layer stack 190 that is present in the semiconductor die 100 comprise a frame-shaped horizontal surface segment 93H of the second dielectric diffusion barrier layer 193. In one embodiment, physically exposed surfaces of the portion of the passivation layer stack 190 that is present in the semiconductor die 100 comprise a vertical sidewall of the first dielectric diffusion barrier layer 191.

Generally, the semiconductor die 100 comprises a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; and die bump structures 198 vertically extending through the passivation layer stack 190 and electrically connected to a subset of the metal interconnect structures 180. The passivation layer stack 190 comprises a first frame-shaped horizontal surface located in a peripheral region and vertically offset relative to a distal horizontal surface of the polymer layer 194 that laterally surrounds the die bump structures 198.

FIG. 5F is a vertical cross-sectional view of an alternative configuration of the fourth semiconductor die 100. The alternative configuration of the fourth semiconductor die 100 may be derived from the fourth semiconductor die 100 illustrated in FIGS. 5D and 5E by reducing the first lateral offset distance lod1 to zero.

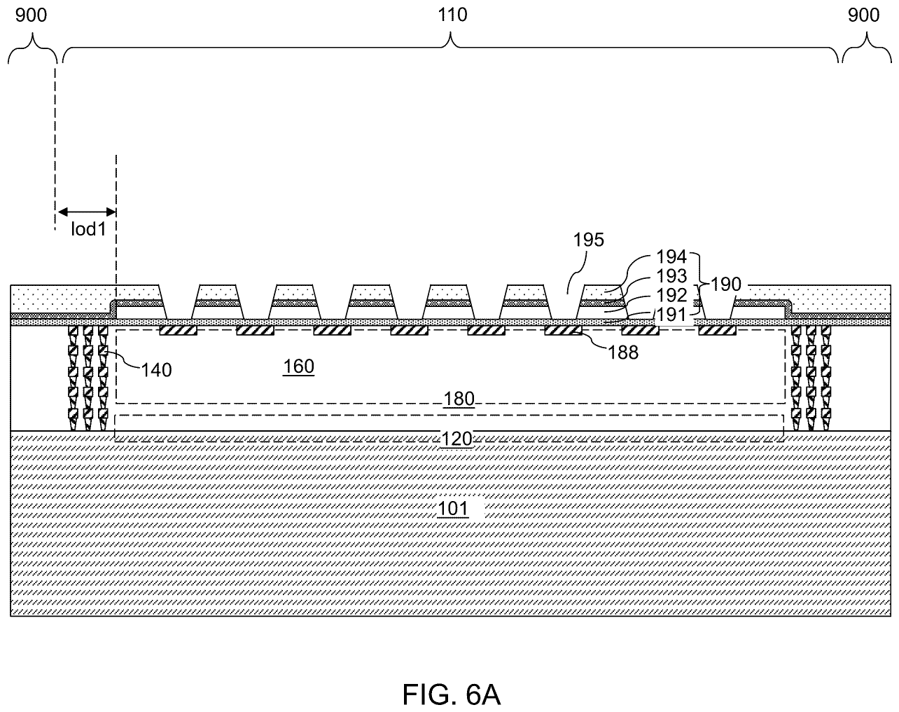

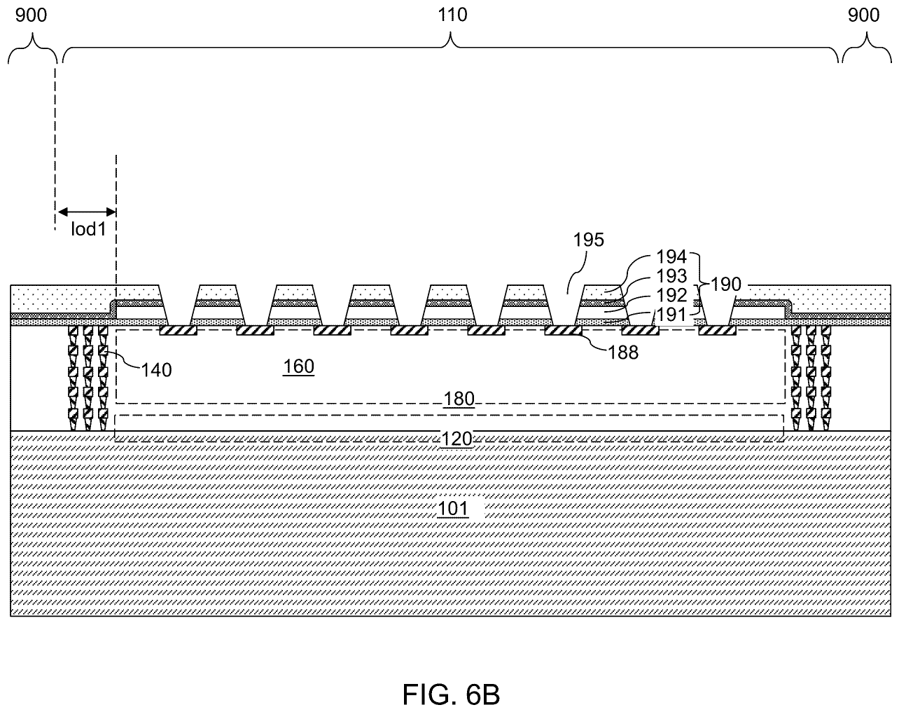

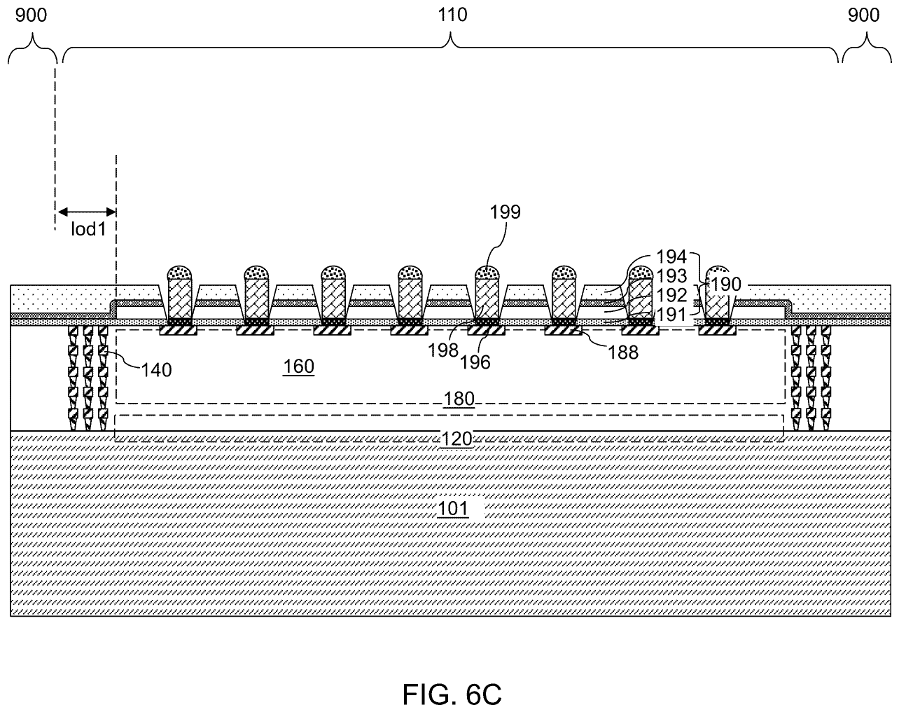

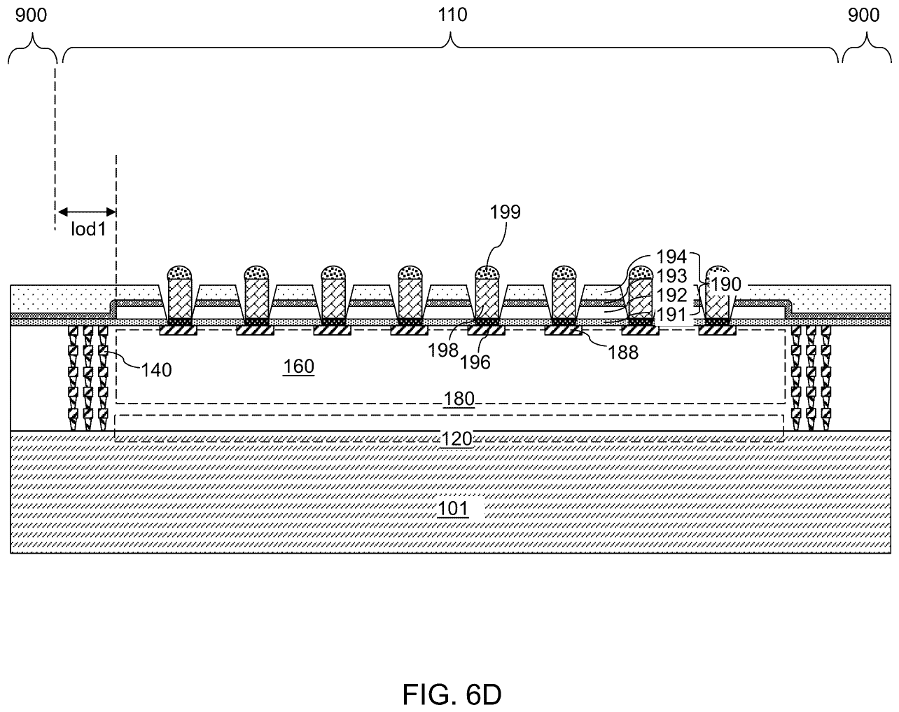

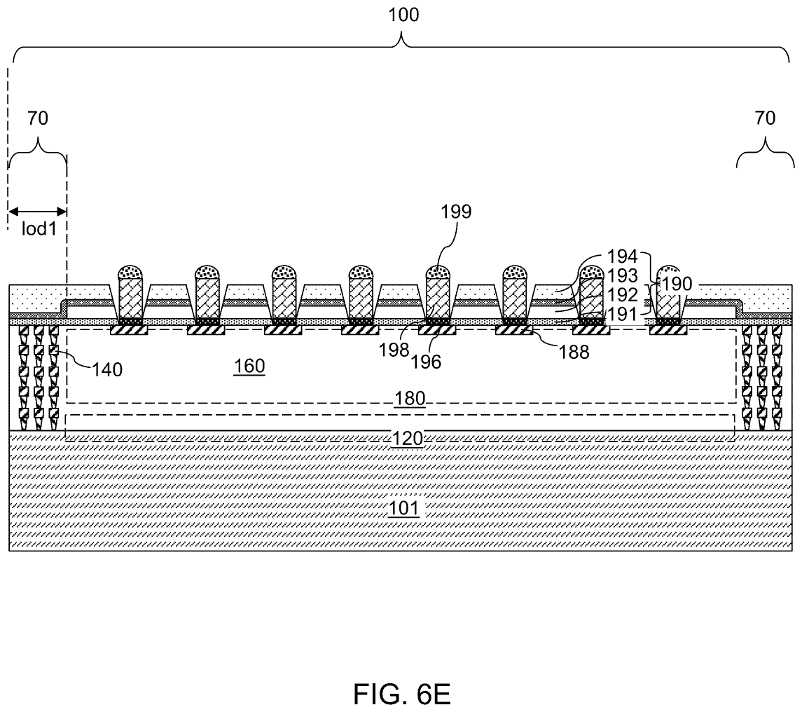

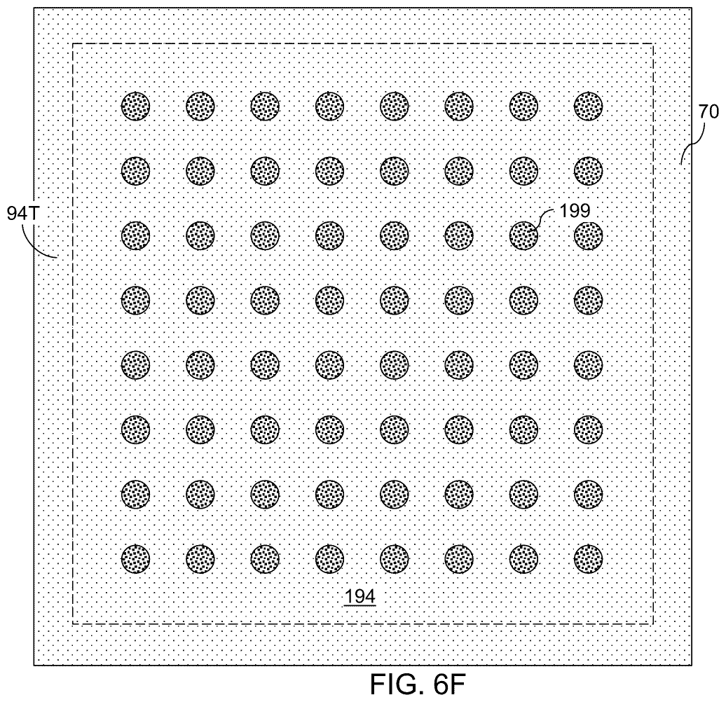

FIG. 6A-6E are sequential vertical cross-sectional views of a fifth semiconductor die 100 during fabrication and dicing according to an embodiment of the present disclosure.

Referring to FIG. 6A, a portion of the wafer 1000 described with reference to FIG. 2D is illustrated. The structure for forming the fifth semiconductor dies 100 may be the same as the structure described with reference to FIG. 2D.

Referring to FIG. 6B, the processing steps described with reference to FIG. 2F may be performed. Specifically, an anisotropic etch process may be performed to vertically extend the openings 195. The anisotropic etch process has an etch chemistry that etches the materials of the first dielectric diffusion barrier layer 191 selectively to the material of the metal pads 188. The openings 195 through the polymer layer 194, the second dielectric diffusion barrier layer 193, and the silicate glass layer 192 are vertically extended through the first dielectric diffusion barrier layer 191 so that top surfaces of the metal pads 188 are physically exposed.

The lateral dimension (i.e., the maximum lateral dimension) of each physically exposed surface of the metal pads 188 underneath the openings 195 through the passivation layer stack 190 may be selected to provide subsequent formation of die bump structures (such as copper pillar structures) thereupon. For example, the lateral dimension of each physically exposed surface of the metal pad 188 may be in a range from 5 microns to 50 microns, such as from 10 microns to 30 microns, although lesser and greater dimensions may also be used. The shape of each physically exposed surface of the metal pads 188 (as seen in a top-down view) may be a circle, a rectangle, a rounded rectangle, or any other suitable two-dimensional curvilinear shape having a closed boundary.

Referring to FIG. 6C, the processing steps described with reference to FIG. 2G may be performed to form a two-dimensional array of metallic adhesion plates 196, a two-dimensional array of die bump structures 198, and a two-dimensional array of solder material portions 199.

Referring to FIG. 6D, the processing steps described with reference to FIG. 2H may be performed to thin the semiconductor substrate 101.

Referring to FIGS. 6E and 6F, the processing steps described with reference to FIGS. 2I and 2J may be performed to dice the wafer 1000 into a plurality of semiconductor dies 100. A semiconductor die 100 having the configuration illustrated in FIGS. 6E and 6F is herein referred to as a fifth semiconductor die 100.

Generally, a wafer 1000 including a passivation layer stack 190, dielectric material layers 160, metal interconnect structures 180, semiconductor devices 120, and a semiconductor substrate 101 may be diced after formation of die bump structures 198 through the passivation layer stack 190 along dicing channels into a plurality of semiconductor dies 100. Each semiconductor die 100 comprises a diced portion of the semiconductor substrate 101, which is herein referred to as a semiconductor substrate 101 of the semiconductor die 100.

Referring collectively to FIG. 2A-2D and 6A-6F and according to an aspect of the present disclosure, at least one material layer selected from the silicate glass layer 192, the second dielectric diffusion barrier layer 193, and the polymer layer 194 is patterned prior to dicing a wafer 1000 into a plurality of semiconductor dies 100. The at least one material layer is completely removed from a respective frame-shaped peripheral region of each of the plurality of semiconductor dies 100 prior to dicing the wafer 1000. The frame-shaped peripheral region is generally proximal to the dicing channel regions 900. In one embodiment, the at least one material layer comprises the silicate glass layer 192, which may be patterned at the processing steps described with reference to FIG. 2B.

In one embodiment, the wafer 1000 comprises dicing channel regions 900 that are removed during dicing of the wafer 1000 and semiconductor die regions 110 that become the plurality of semiconductor dies 100 upon dicing. In one embodiment, portions of the silicate glass layer 192 located within a first lateral offset distance lod1 from the dicing channel regions 900 may be removed (as described with reference to FIG. 2B). The entirety of the polymer layer 194 may be formed within a horizontal plane. Upon patterning the at least one material layer selected from the silicate glass layer 192, the second dielectric diffusion barrier layer 193, and the polymer layer 194, the at least one material layer is absent from a frame-shaped peripheral region 70 of the semiconductor die 100. Specifically, upon patterning the silicate glass layer 192, silicate glass layer 192 is absent from a frame-shaped peripheral region 70 of the semiconductor die 100.

Generally, the semiconductor die 100 comprises a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; and die bump structures 198 vertically extending through the passivation layer stack 190 and electrically connected to a subset of the metal interconnect structures 180.

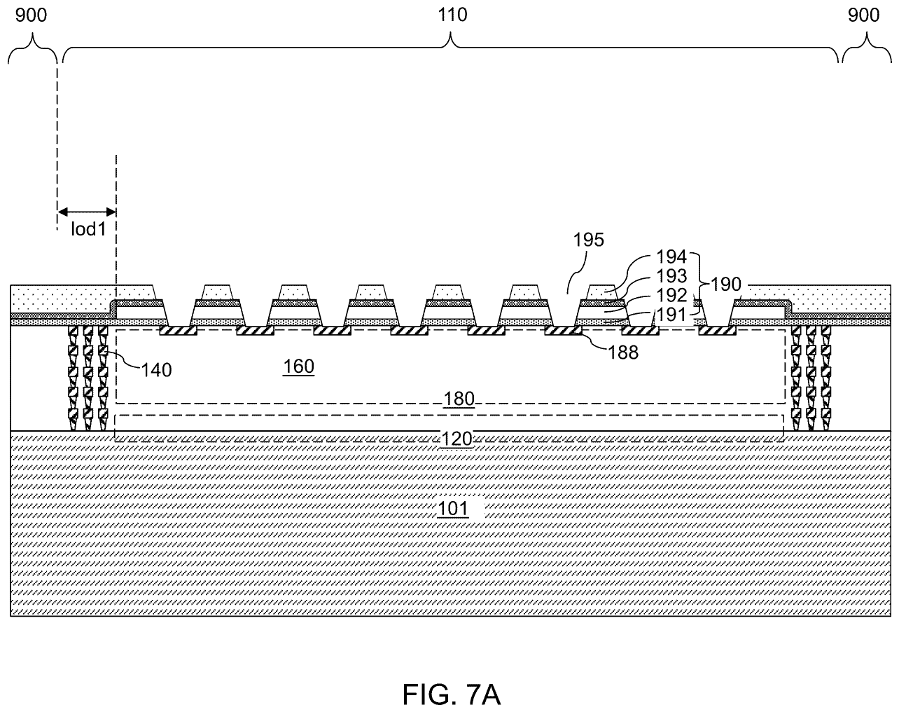

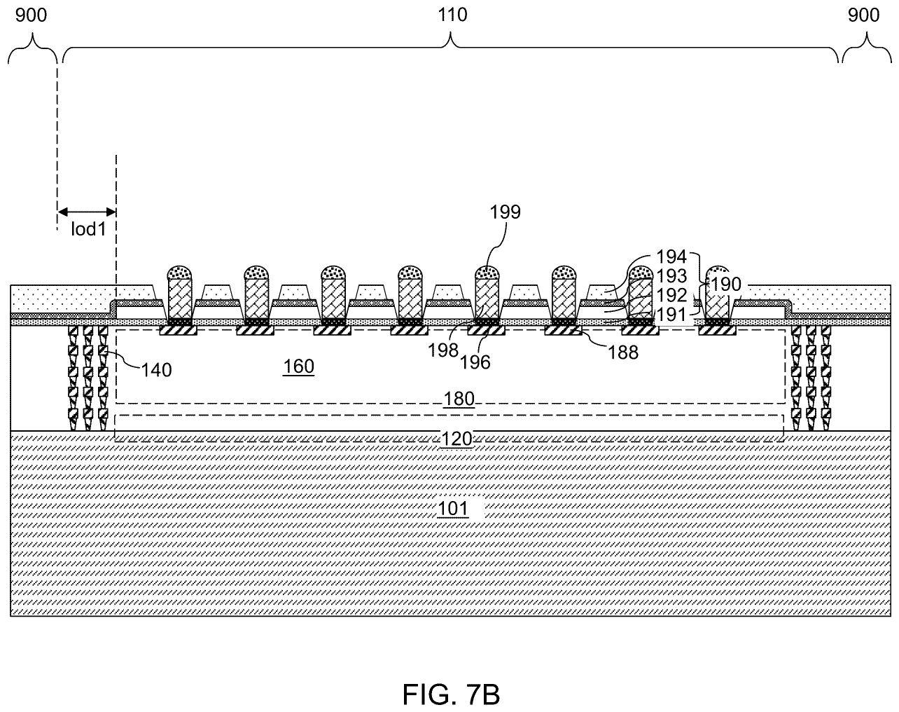

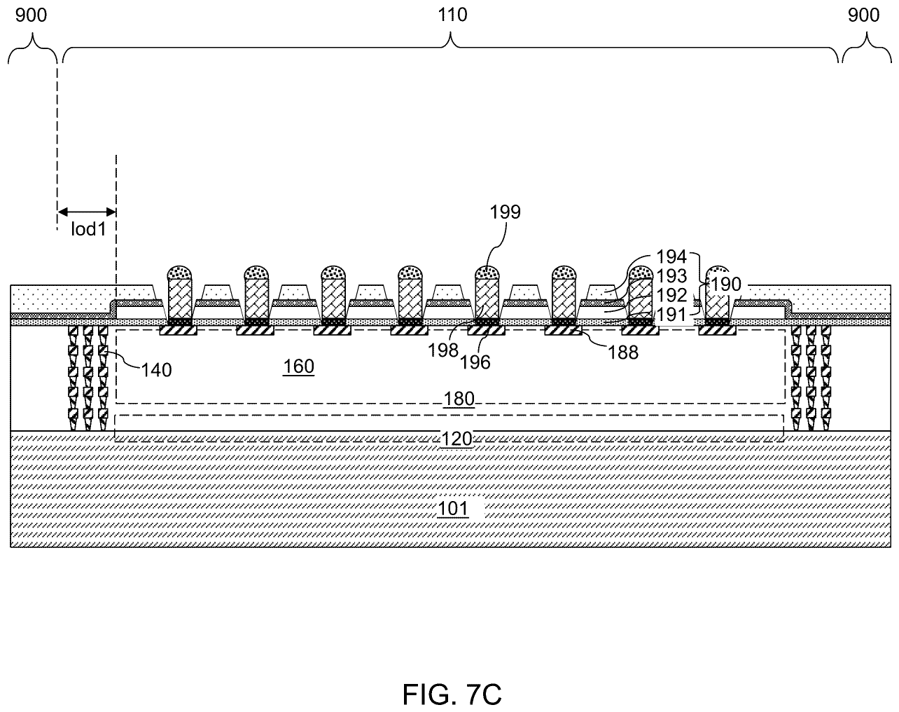

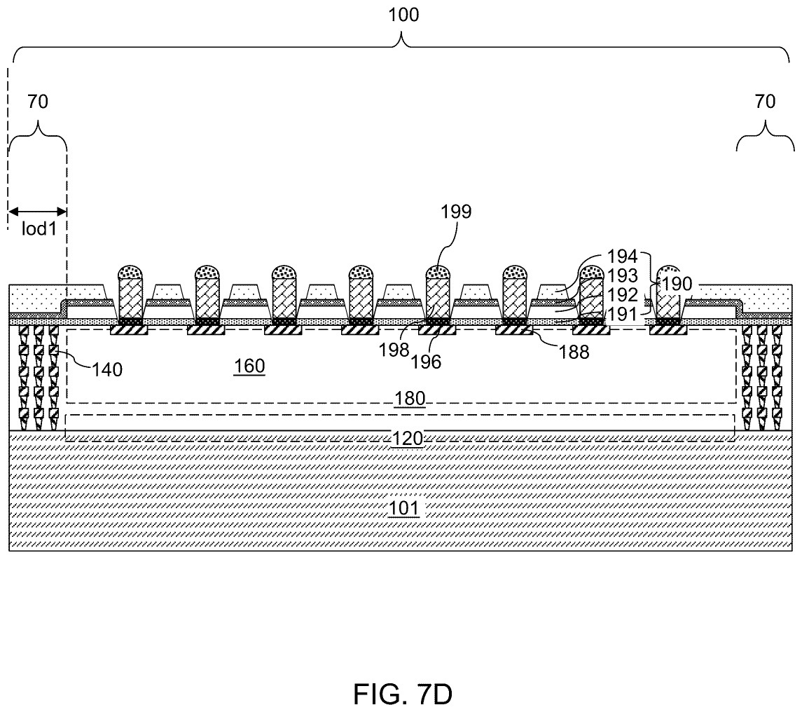

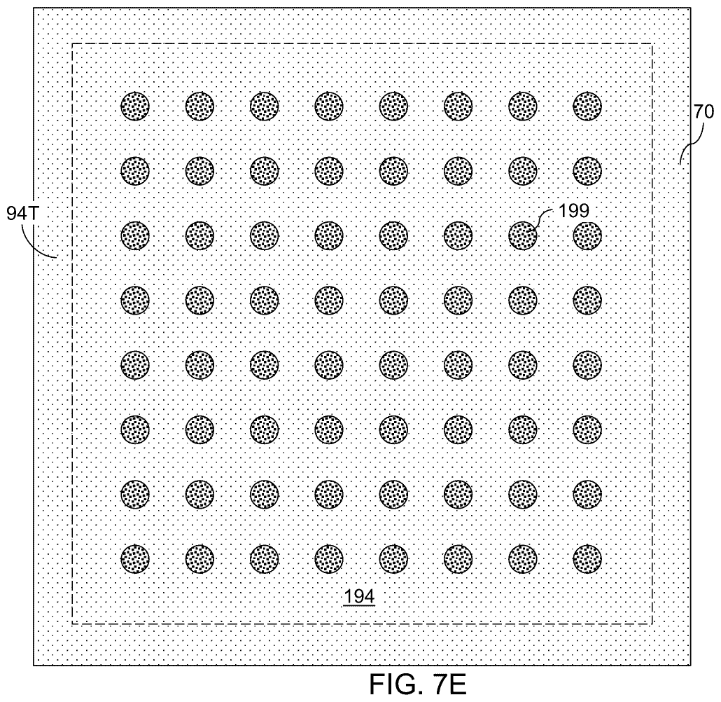

FIG. 7A-7D are sequential vertical cross-sectional views of a sixth semiconductor die 100 during fabrication and dicing according to an embodiment of the present disclosure.

Referring to FIG. 7A, an alternative configuration of the wafer 1000, of which a semiconductor die region 110 and two dicing channel regions 900 are shown, may be derived from the configuration of the wafer 1000 illustrated in FIG. 6A by trimming the polymer layer 194, for example, by performing an isotropic trimming process. The trimming distance may be in a range from 100 nm to about 50 % of the thickness of the polymer layer 194 at the processing steps of FIG. 6A. The thickness of the polymer layer 194 around the openings 195 after the trimming process may be in a range from 1 micron to 10 microns, such as from 1.5 microns to 5 microns, although lesser and greater thicknesses may also be used.

Referring to FIG. 7B, the processing steps described with reference to FIG. 2G may be performed to form a two-dimensional array of metallic adhesion plates 196, a two-dimensional array of die bump structures 198, and a two-dimensional array of solder material portions 199.

Referring to FIG. 7C, the processing steps described with reference to FIG. 2H may be performed to thin the semiconductor substrate 101.

Referring to FIGS. 7D and 7E, the processing steps described with reference to FIGS. 2I and 2J may be performed to dice the wafer 1000 into a plurality of semiconductor dies 100. A semiconductor die 100 having the configuration illustrated in FIGS. 7D and 7E is herein referred to as a sixth semiconductor die 100.

Generally, a wafer 1000 including a passivation layer stack 190, dielectric material layers 160, metal interconnect structures 180, semiconductor devices 120, and a semiconductor substrate 101 may be diced after formation of die bump structures 198 through the passivation layer stack 190 along dicing channels into a plurality of semiconductor dies 100. Each semiconductor die 100 comprises a diced portion of the semiconductor substrate 101, which is herein referred to as a semiconductor substrate 101 of the semiconductor die 100.

Referring collectively to FIGS. 2A-2D, 6A, and 7A-7E and according to an aspect of the present disclosure, at least one material layer selected from the silicate glass layer 192, the second dielectric diffusion barrier layer 193, and the polymer layer 194 is patterned prior to dicing a wafer 1000 into a plurality of semiconductor dies 100. The at least one material layer is completely removed from a respective frame-shaped peripheral region of each of the plurality of semiconductor dies 100 prior to dicing the wafer 1000. The frame-shaped peripheral region is generally proximal to the dicing channel regions 900. In one embodiment, the at least one material layer comprises the silicate glass layer 192, which may be patterned at the processing steps described with reference to FIG. 2B.

In one embodiment, the wafer 1000 comprises dicing channel regions 900 that are removed during dicing of the wafer 1000 and semiconductor die regions 110 that become the plurality of semiconductor dies 100 upon dicing. In one embodiment, portions of the silicate glass layer 192 located within a first lateral offset distance lod1 from the dicing channel regions 900 may be removed (as described with reference to FIG. 2B). The entirety of the polymer layer 194 may be formed within a horizontal plane. Upon patterning the at least one material layer selected from the silicate glass layer 192, the second dielectric diffusion barrier layer 193, and the polymer layer 194, the at least one material layer is absent from a frame-shaped peripheral region 70 of the semiconductor die 100. Specifically, upon patterning the silicate glass layer 192, silicate glass layer 192 is absent from a frame-shaped peripheral region 70 of the semiconductor die 100.

Generally, the semiconductor die 100 comprises a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; and die bump structures 198 vertically extending through the passivation layer stack 190 and electrically connected to a subset of the metal interconnect structures 180.

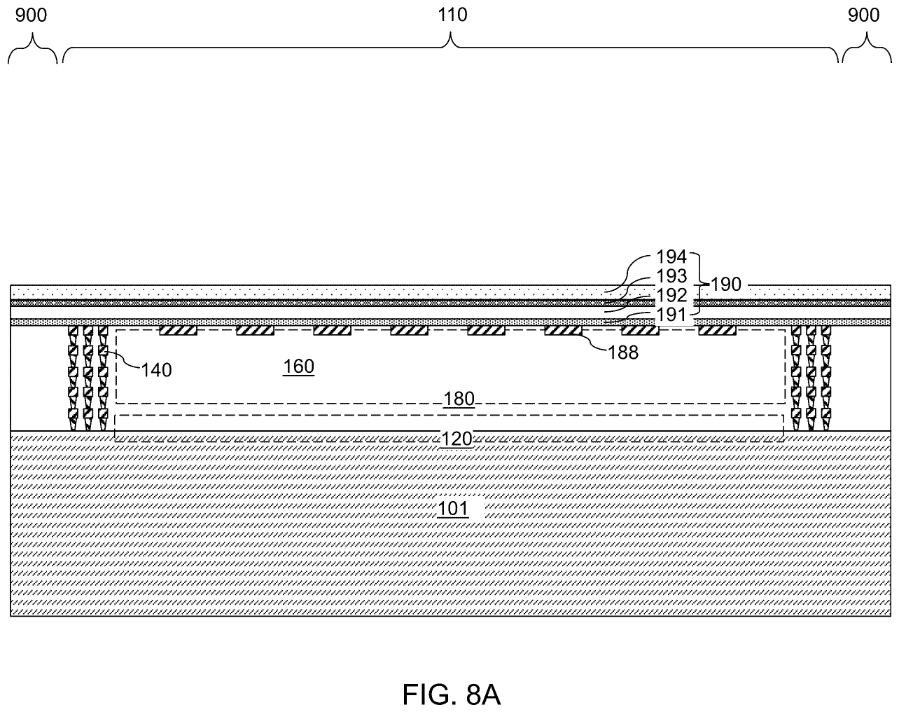

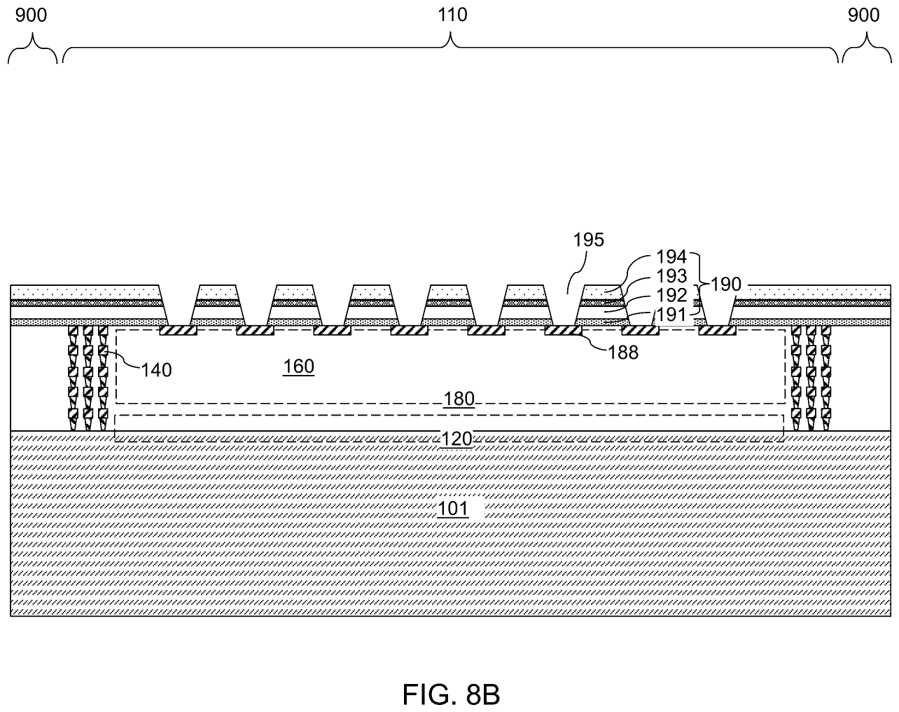

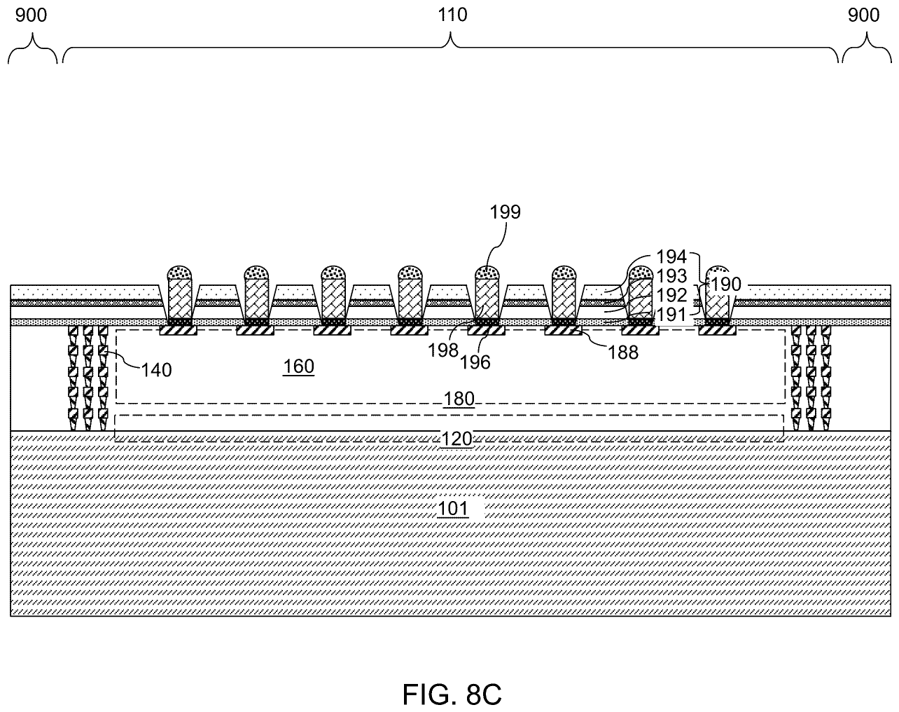

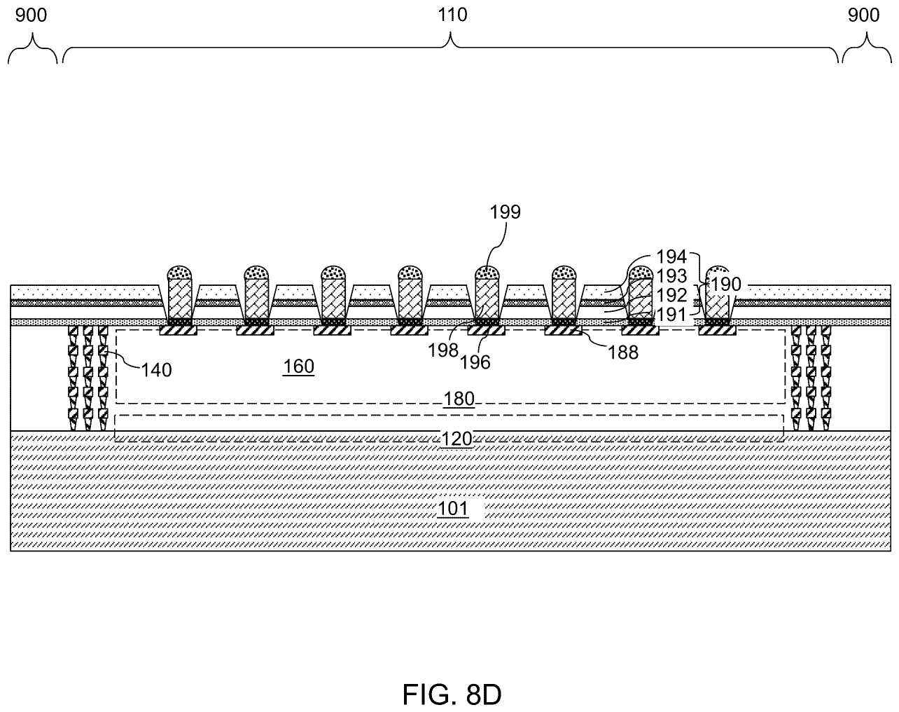

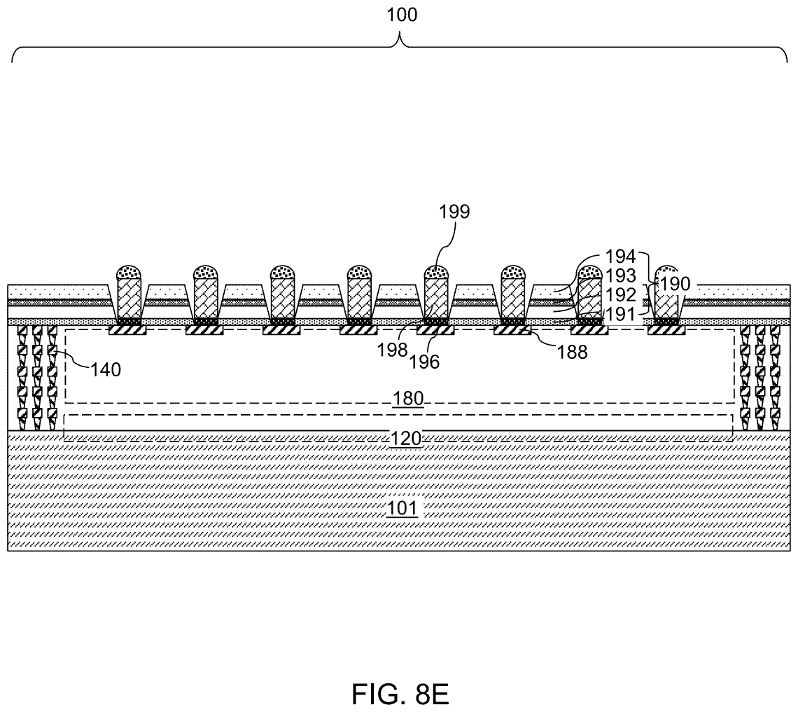

FIG. 8A-8F are sequential vertical cross-sectional views of a seventh semiconductor die 100 during fabrication and dicing according to an embodiment of the present disclosure.

Referring to FIG. 8A, a portion of the wafer 1000 described with reference to FIG. 4B is illustrated. The structure for forming the seventh semiconductor dies 100 may be the same as the structure described with reference to FIG. 4B.

Referring to FIG. 8B, the processing steps described with reference to FIGS. 4C and 4E may be performed. For example, the polymer layer 194 may be patterned by lithographic exposure and development. A pattern of a two-dimensional array of openings may be formed in the polymer layer 194 such that each opening is formed entirely within the area of an underlying metal pad 188. An anisotropic etch process may be performed to transfer the pattern of the openings in the polymer layer 194 through the second dielectric diffusion barrier layer 193, the silicate glass layer 192, and the first dielectric diffusion barrier layer 191. The etch chemistry of a terminal step of the anisotropic etch process may be selective to the material of the metal pads 188.

Openings 195 are formed through the passivation layer stack 190. The taper angle of the sidewalls of the openings 195 (as measured relative to the vertical direction) may be in a range from 1 degree to 20 degrees, such as from 2 degrees to 10 degrees, although lesser and greater taper angles may also be used.

The lateral dimension (i.e., the maximum lateral dimension) of each physically exposed surface of the metal pads 188 underneath the openings 195 through the passivation layer stack 190 may be selected to provide subsequent formation of die bump structures (such as copper pillar structures) thereupon. For example, the lateral dimension of each physically exposed surface of the metal pad 188 may be in a range from 5 microns to 50 microns, such as from 10 microns to 30 microns, although lesser and greater dimensions may also be used. The shape of each physically exposed surface of the metal pads 188 (as seen in a top-down view) may be a circle, a rectangle, a rounded rectangle, or any other suitable two-dimensional curvilinear shape having a closed boundary.

Referring to FIG. 8C, the processing steps described with reference to FIG. 2G may be performed to form a two-dimensional array of metallic adhesion plates 196, a two-dimensional array of die bump structures 198, and a two-dimensional array of solder material portions 199.

Referring to FIG. 8D, the processing steps described with reference to FIG. 2H may be performed to thin the semiconductor substrate 101.

Referring to FIG. 8E, the processing steps described with reference to FIGS. 2I and 2J may be performed to dice the wafer 1000 into a plurality of semiconductor dies 100. A semiconductor die 100 having the configuration illustrated in FIG. 8E is herein referred to as a seventh semiconductor die 100.

Generally, a wafer 1000 including a passivation layer stack 190, dielectric material layers 160, metal interconnect structures 180, semiconductor devices 120, and a semiconductor substrate 101 may be diced after formation of die bump structures 198 through the passivation layer stack 190 along dicing channels into a plurality of semiconductor dies 100. Each semiconductor die 100 comprises a diced portion of the semiconductor substrate 101, which is herein referred to as a semiconductor substrate 101 of the semiconductor die 100. The semiconductor die 100 comprises a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; and die bump structures 198 vertically extending through the passivation layer stack 190 and electrically connected to a subset of the metal interconnect structures 180.

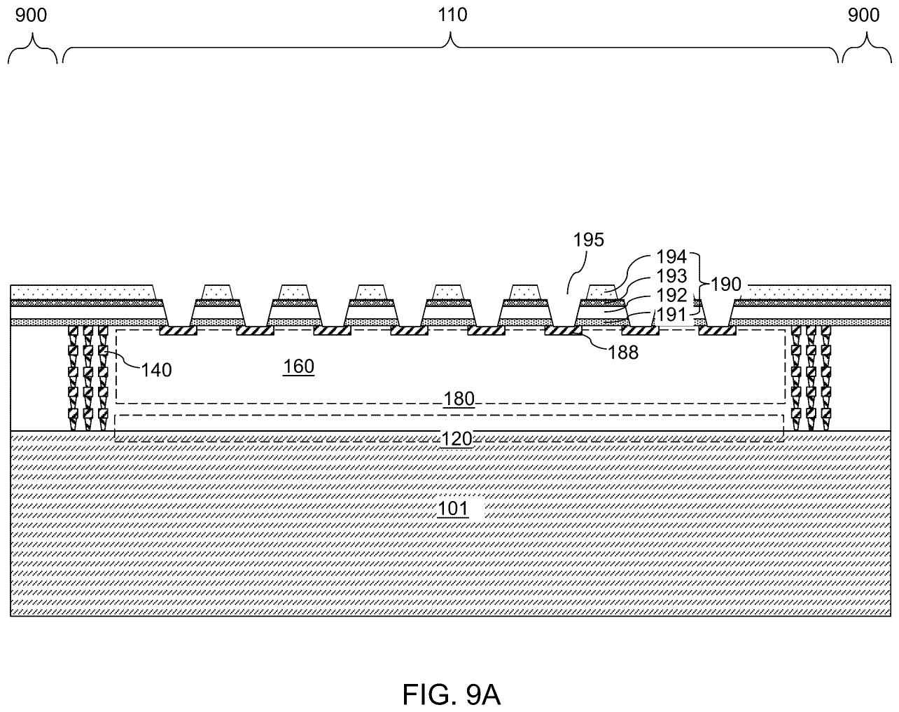

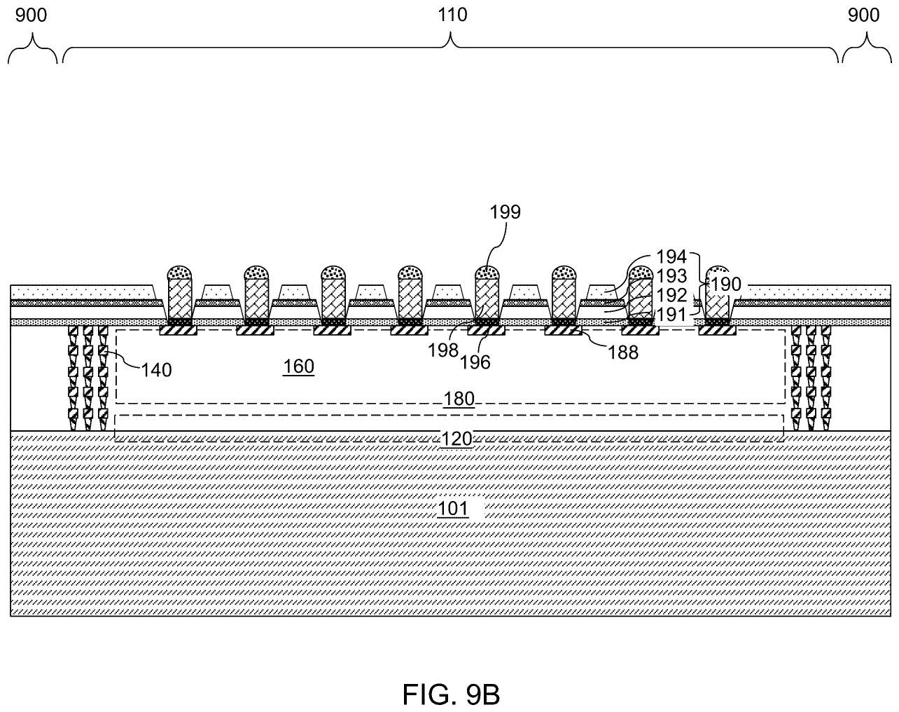

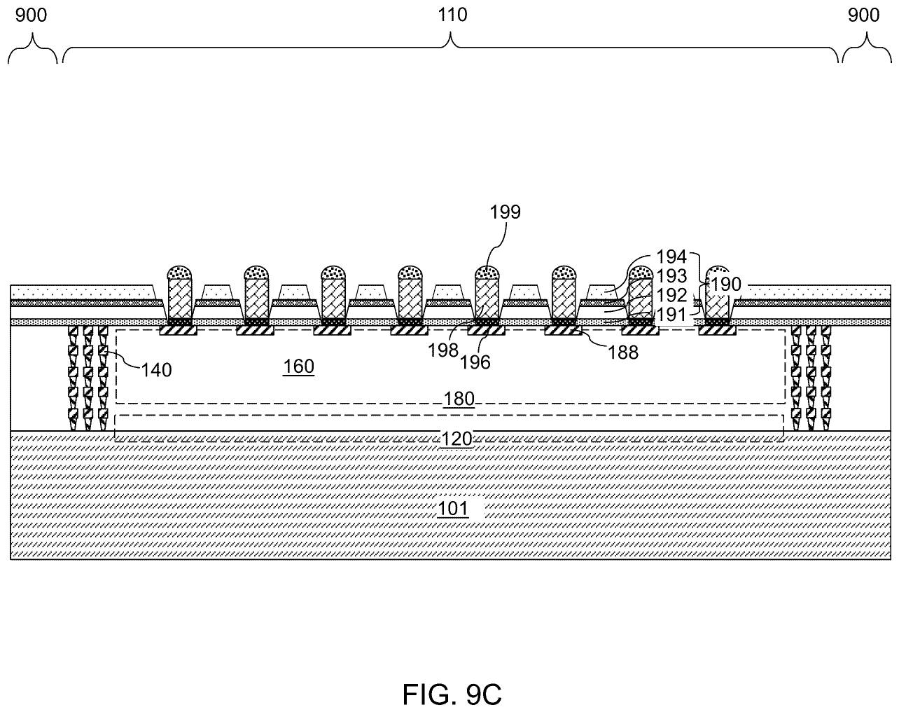

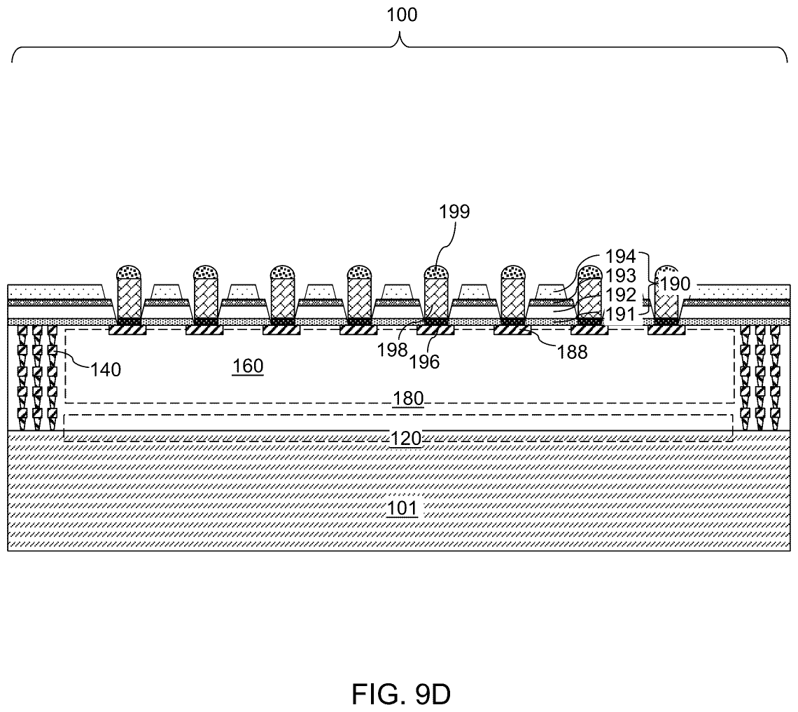

FIG. 9A-9D are sequential vertical cross-sectional views of an eighth semiconductor die 100 during fabrication and dicing according to an embodiment of the present disclosure.

Referring to FIG. 9A, an alternative configuration of the wafer 1000, of which a semiconductor die region 110 and two dicing channel regions 900 are shown, may be derived from the configuration of the wafer 1000 illustrated in FIG. 8B by trimming the polymer layer 194, for example, by performing an isotropic trimming process. The trimming distance may be in a range from 100 nm to about 50 % of the thickness of the polymer layer 194 at the processing steps of FIG. 8B. The thickness of the polymer layer 194 around the openings 195 after the trimming process may be in a range from 1 micron to 10 microns, such as from 1.5 microns to 5 microns, although lesser and greater thicknesses may also be used.

Referring to FIG. 9B, the processing steps described with reference to FIG. 2G may be performed to form a two-dimensional array of metallic adhesion plates 196, a two-dimensional array of die bump structures 198, and a two-dimensional array of solder material portions 199.

Referring to FIG. 9C, the processing steps described with reference to FIG. 2H may be performed to thin the semiconductor substrate 101.

Referring to FIG. 9D, the processing steps described with reference to FIGS. 2I and 2J may be performed to dice the wafer 1000 into a plurality of semiconductor dies 100. A semiconductor die 100 having the configuration illustrated in FIG. 9D is herein referred to as an eighth semiconductor die 100.

Generally, a wafer 1000 including a passivation layer stack 190, dielectric material layers 160, metal interconnect structures 180, semiconductor devices 120, and a semiconductor substrate 101 may be diced after formation of die bump structures 198 through the passivation layer stack 190 along dicing channels into a plurality of semiconductor dies 100. Each semiconductor die 100 comprises a diced portion of the semiconductor substrate 101, which is herein referred to as a semiconductor substrate 101 of the semiconductor die 100. The semiconductor die 100 comprises a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; and die bump structures 198 vertically extending through the passivation layer stack 190 and electrically connected to a subset of the metal interconnect structures 180.

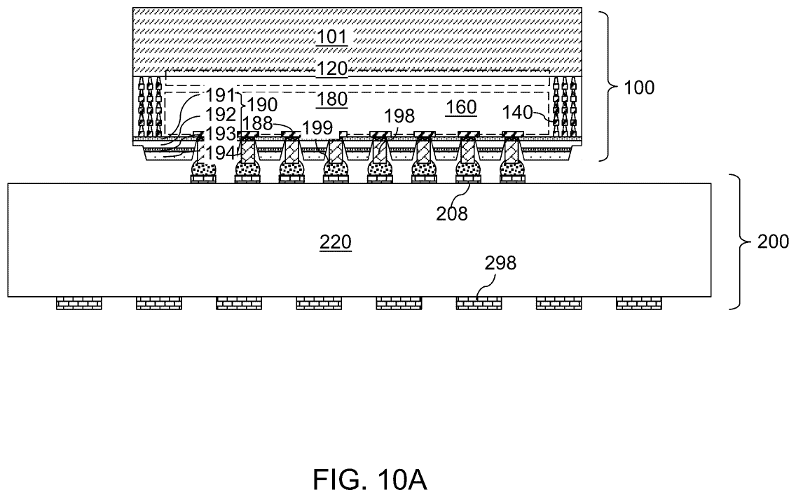

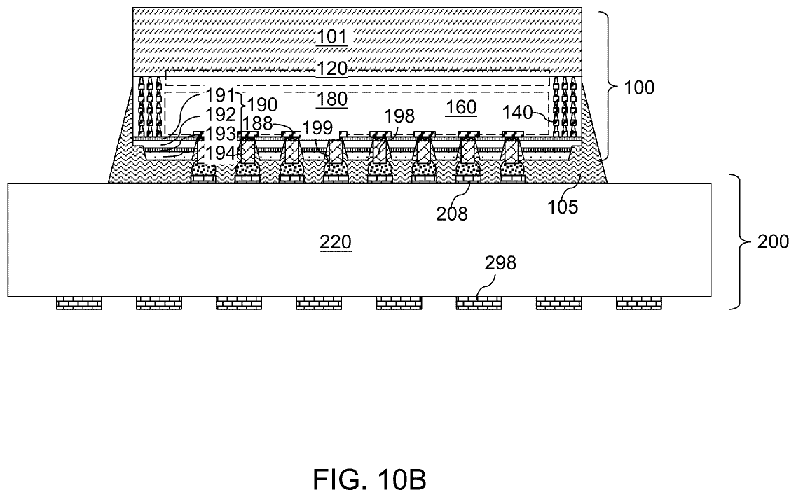

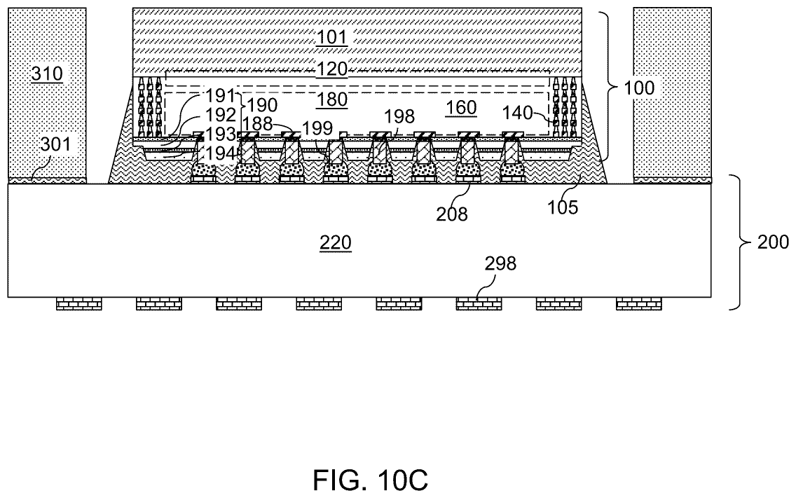

FIG. 10A-10C are sequential vertical cross-sectional views of an exemplary structure during assembly of a semiconductor die 100 and a packaging structure such as a packaging substrate 200 according to an embodiment of the present disclosure.

In the illustrated example, the packaging structure is a packaging substrate 200, which may be any type of packaging substrate known in the art. For example, the packaging substrate 200 may be a cored packaging substrate, a coreless packaging substrate, or a ceramic packaging substrate. Alternatively, the packaging substrate 200 may comprise a system-on-integrated packaging substrate (SoIS) including redistribution layers and/or dielectric interlayers, at least one embedded interposer (such as a silicon interposer). The packaging substrate 200 comprises a substrate body 220, a two-dimensional array of substrate bump structures 208 on a proximal side of the substrate body 220, and a two-dimensional array of bonding pads 298 (such as C4 bonding pads) on a distal side of the substrate body 220. The two-dimensional array of substrate bump structures 208 may have the same pitch as the two-dimensional array of die bump structures 198.

A semiconductor die 100 may be bonded to the packaging substrate 200 by positioning the array of solder material portions 199 on the two-dimensional array of substrate bump structures 208, and by inducing reflow of the solder material portions 199. The semiconductor die 100 may be any of the semiconductor dies 100 described above. A bonded assembly of the semiconductor die 100 and the packaging substrate 200 is provided.

Referring to FIG. 10B, an underfill material may be applied around the array of solder material portions 199 to form an underfill material portion 105. The mechanical stress generated during application of the underfill material and applied to the semiconductor die 100 is partially absorbed by deformation of the polymer layer 194. Further, in embodiments in which corner regions of the semiconductor die 100 comprises at least one frame-shaped horizontal surface segment and/or at least one tapered sidewall of the passivation layer stack 190, mechanical stress generated during application of the underfill material and applied to corner regions of the semiconductor die 100 may be absorbed through the at least one frame-shaped horizontal surface segment and/or at least one tapered sidewall of the passivation layer stack 190. Thus, the at least one frame-shaped horizontal surface segment and/or at least one tapered sidewall of the passivation layer stack 190 reduces the effect of mechanical stress on the structural integrity of the semiconductor die 100. Specifically, the gradual thinning of the passivation layer stack 190 around the edge regions of the passivation layer stack 190 has the effect of suppressing delamination of the passivation layer stack 190 during application of the underfill material, and increasing enhanced structural integrity to the bonded assembly of the semiconductor die 100 and the packaging substrate 200.

Generally, the underfill material portion 105 is applied between the semiconductor die 100 and a packaging structure (such as a packaging substrate 200) around an array of solder material portions 199 directly on a portion of the passivation layer stack 190 that is present in the semiconductor die 100. The underfill material portion 105 laterally surrounds the array of solder material portions 199, and contacts a first frame-shaped horizontal surface and the distal horizontal surface of the polymer layer 194.

In some embodiments, the first frame-shaped horizontal surface comprises a surface of the second dielectric diffusion barrier layer 193. In some embodiments, the passivation layer stack 190 comprises a second frame-shaped horizontal surface located in a peripheral region, vertically offset relative to the first frame-shaped horizontal surface, laterally offset outward relative to the first frame-shaped horizontal surface, and contacting the underfill material portion 105. In one embodiment, the second frame-shaped horizontal surface comprises a surface of the first dielectric diffusion barrier layer 191.

In some embodiments, the silicate glass layer 192 has a first thickness within a first region having an areal overlap with the second dielectric diffusion barrier layer 193, and has a second thickness within a second region that does not have an areal overlap with the second dielectric diffusion barrier layer 193, the second thickness being less than the first thickness. In some embodiments, the second frame-shaped horizontal surface comprises a surface of the second region of the silicate glass layer 192.

In some embodiments, physically exposed surfaces of the portion of the passivation layer stack 190 that is present in the semiconductor die 100 prior to application of the underfill material portion 105 comprise a frame-shaped horizontal surface segment of a portion of the second dielectric diffusion barrier layer 193. In this embodiment, the underfill material portion 105 is applied directly on the frame-shaped horizontal surface segment of the portion of the second dielectric diffusion barrier layer 193.

In some embodiments, physically exposed surfaces of the portion of the passivation layer stack 190 that is present in the semiconductor die 100 prior to application of the underfill material portion 105 comprise a frame-shaped horizontal surface segment of a portion of the first dielectric diffusion barrier layer 191. In this embodiment, the underfill material portion 105 is applied directly on the frame-shaped horizontal surface segment of the portion of the first dielectric diffusion barrier layer 191.

Referring to FIG. 10C, a first adhesive layer 301 may be applied to a proximal horizontal surface of the packaging substrate 200. A stiffener ring 310 may be attached to the first adhesive layer 301.

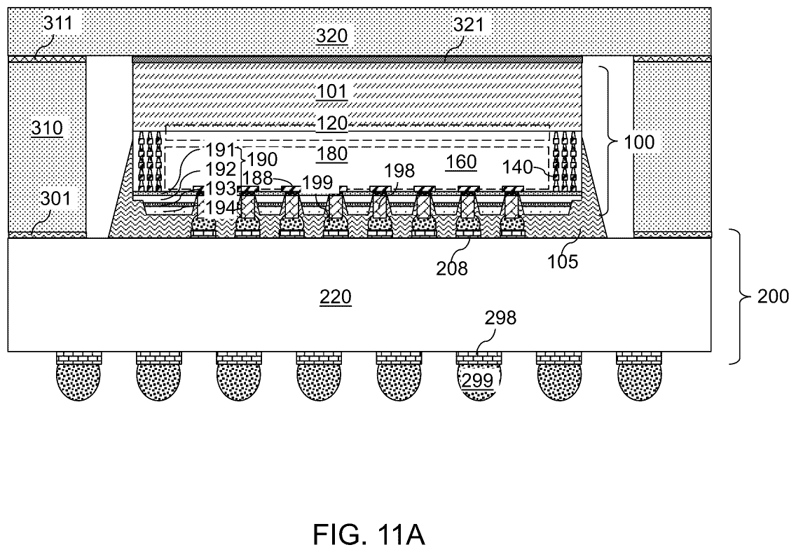

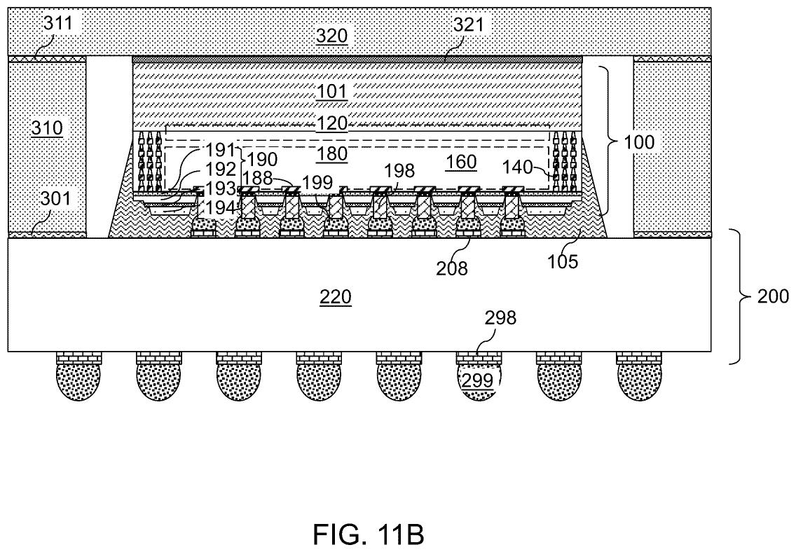

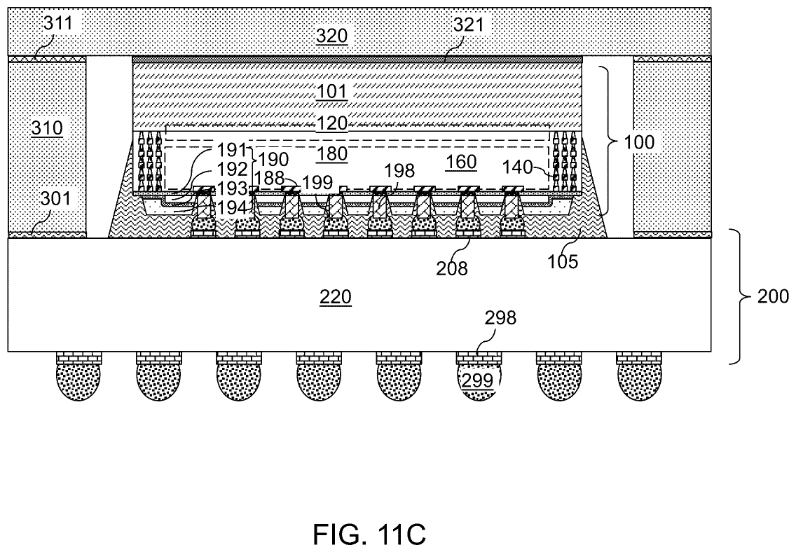

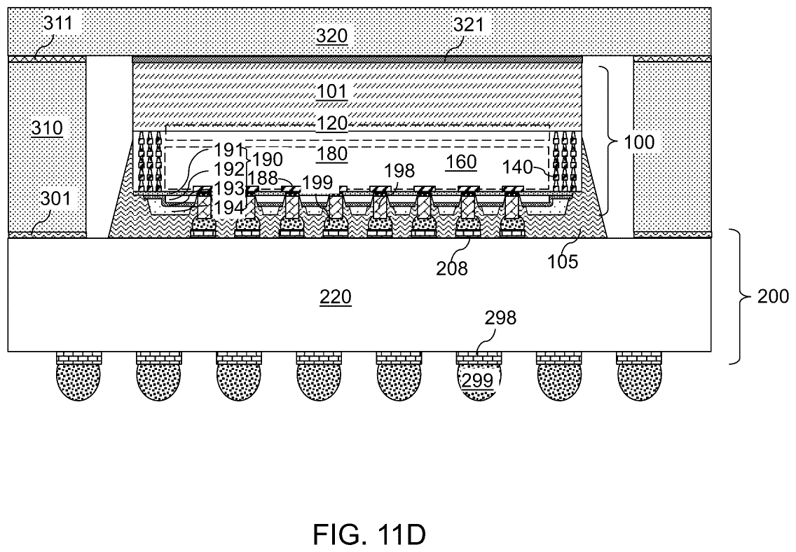

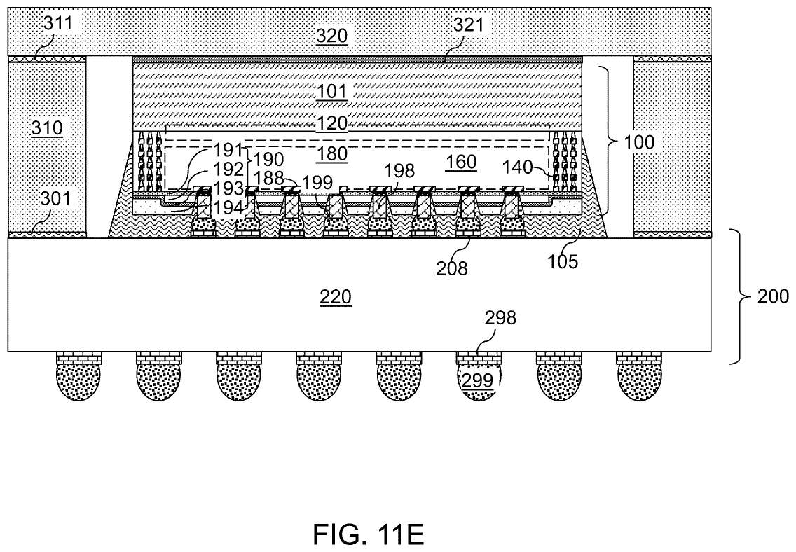

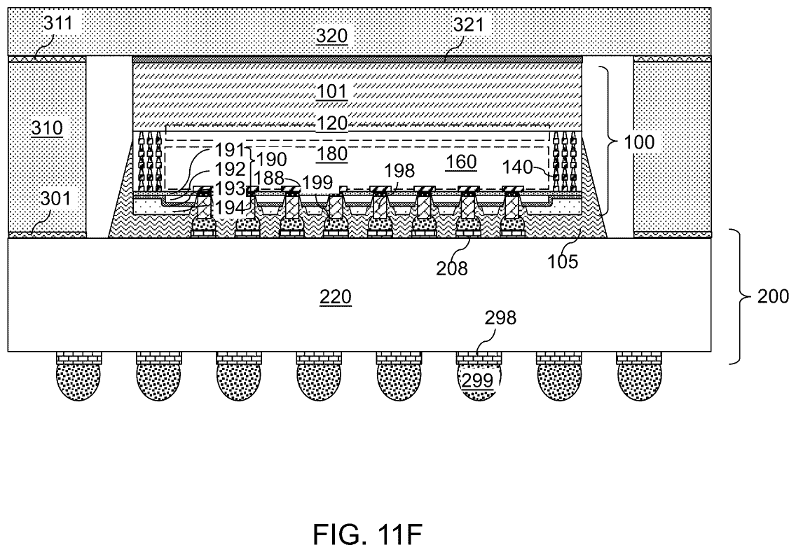

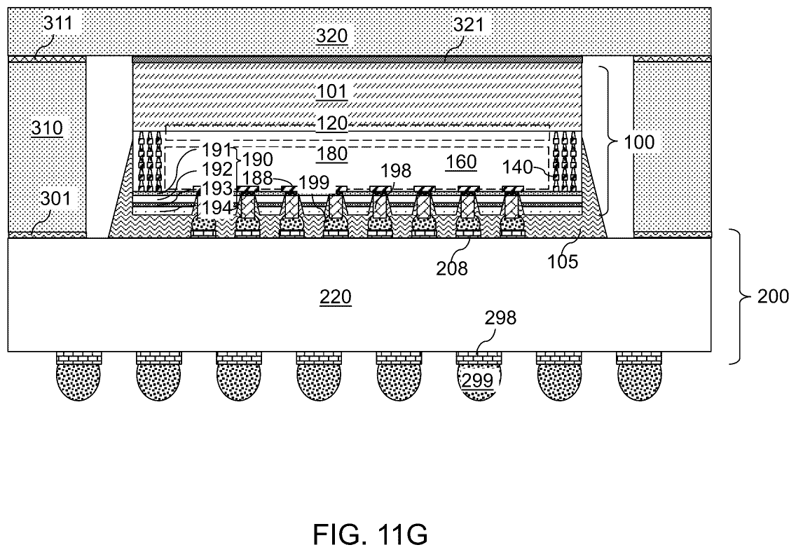

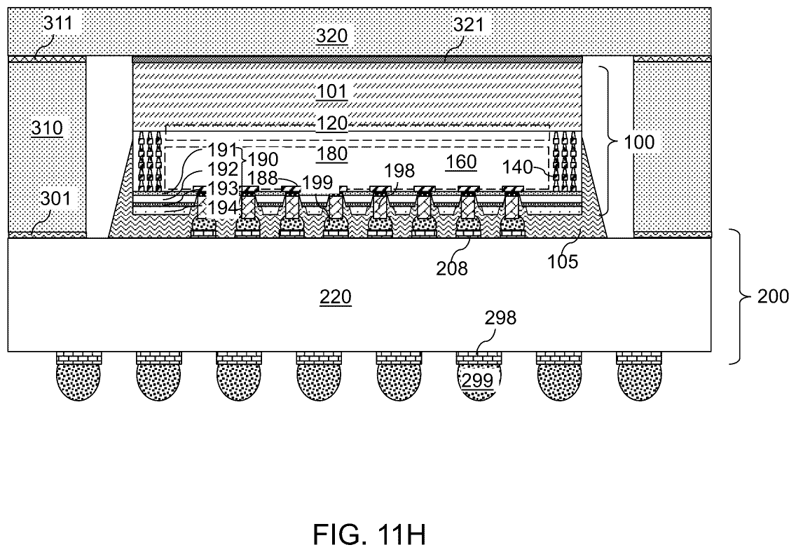

FIG. 11A-11H are vertical cross-sectional views of various configurations of a first exemplary bonded assembly according to an embodiment of the present disclosure.

Referring to FIG. 11A, a second adhesive layer 311 may be applied to the top surface of the stiffener ring 310. A thermal interface material (TIM) layer 321 may be applied to the backside of the semiconductor substrate 101. A lid structure 320 may be attached to the second adhesive layer 311 and the TIM layer 321. Solder balls 299 may be attached to bonding pads 298.

FIG. 11A represents a bonded assembly of a packaging substrate 200, structural stabilization structures (310, 320), and a first semiconductor die 100, i.e., a semiconductor die 100 having the configuration described with reference to FIGS. 2I and 2J. Generally, any of the semiconductor dies 100 described above may be used to form such a bonded assembly. FIGS. 11B, 11C, 11D, 11E, 11F, 11G, and 11H illustrate, in order, bonded assemblies of a respective packaging substrate 200, respective structural stabilization structures (310, 320), and a respective one of the second, third, fourth, fifth, sixth, seventh, or eighth semiconductor dies 100 described above.

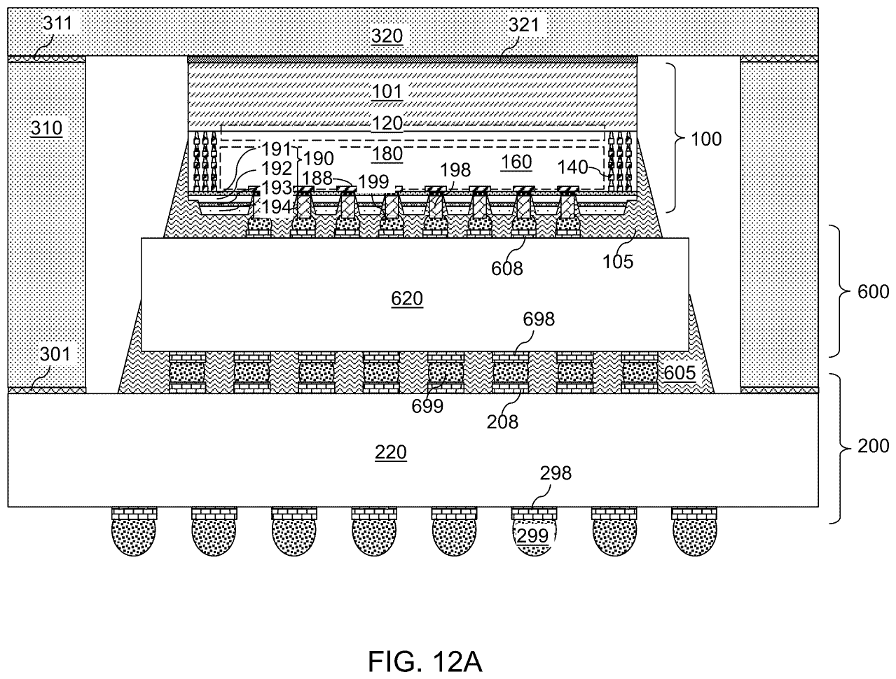

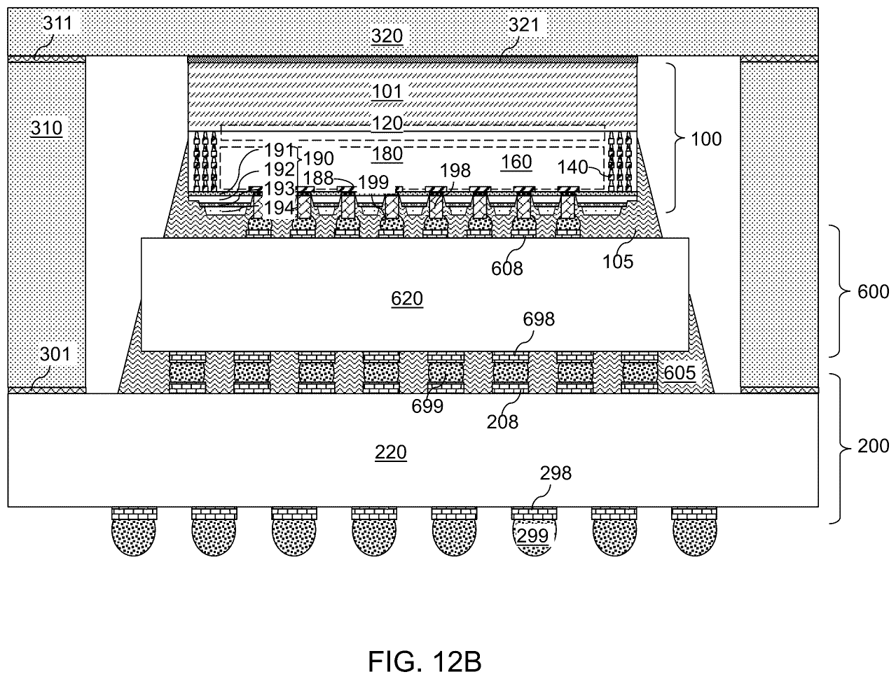

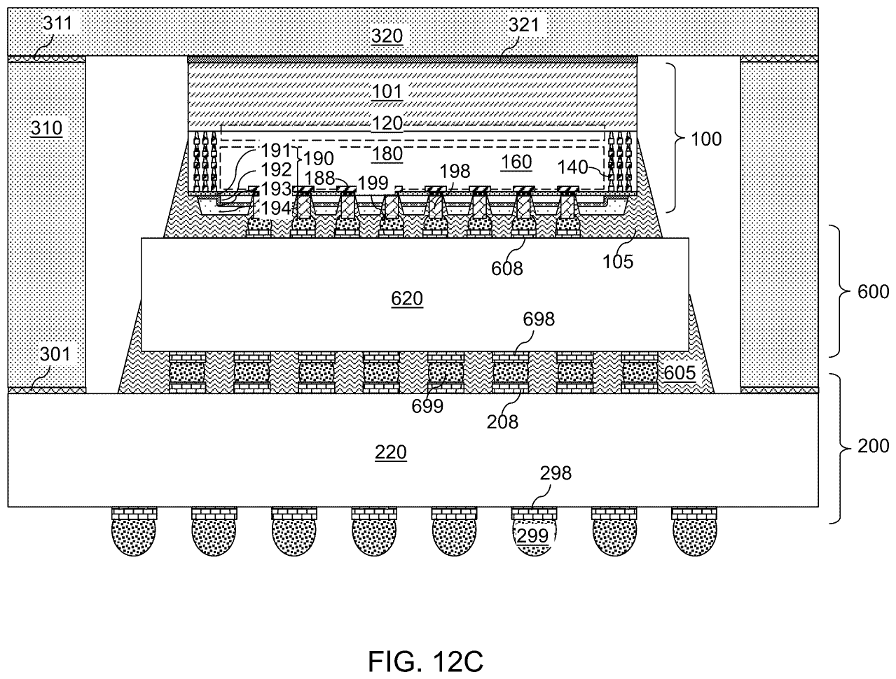

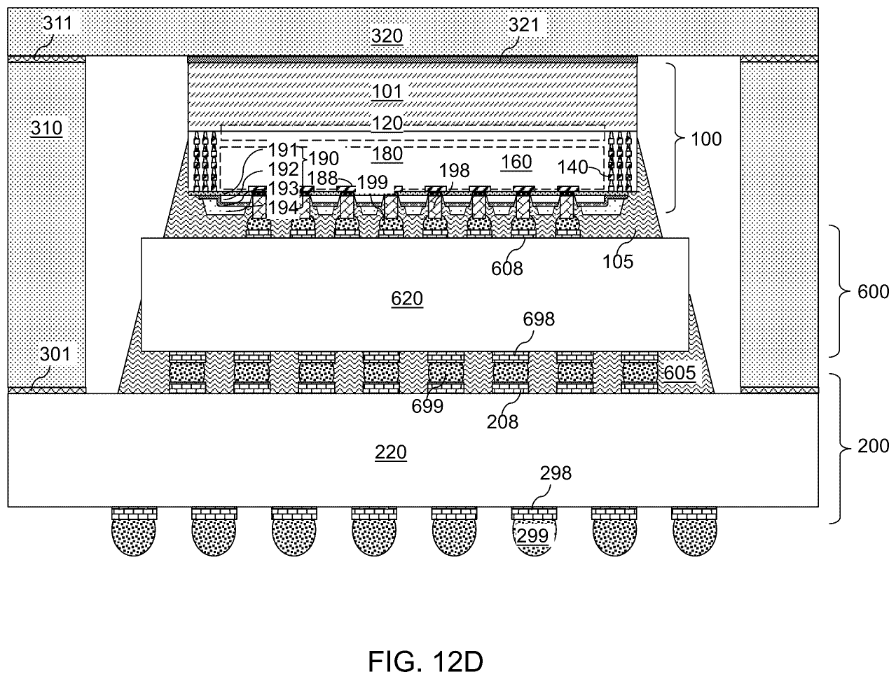

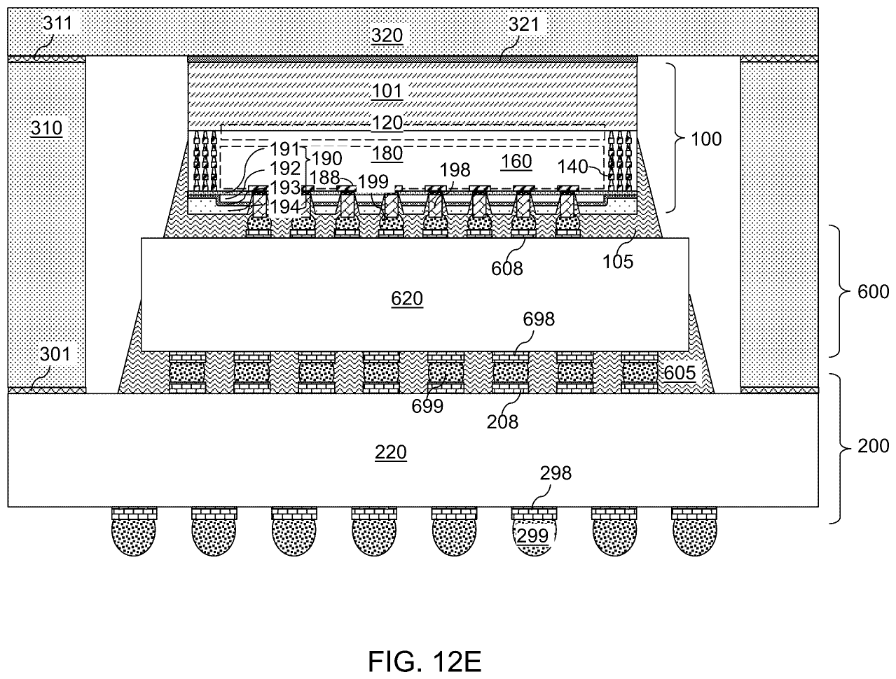

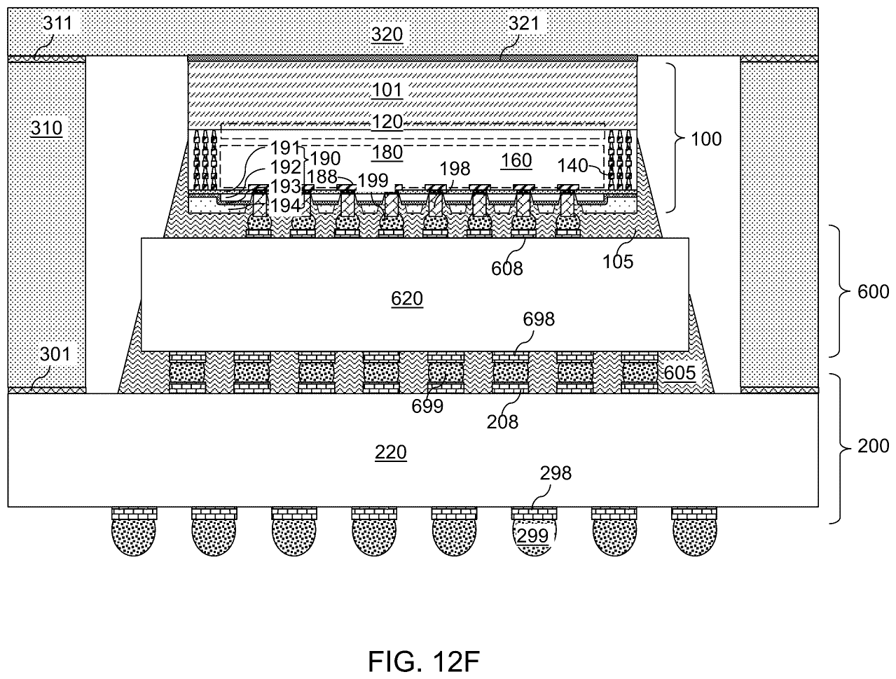

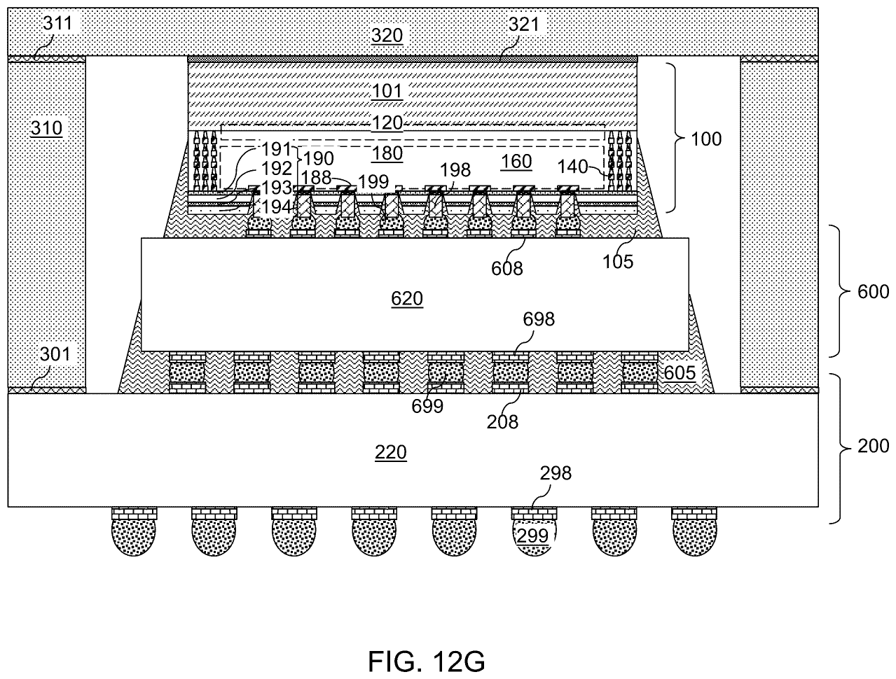

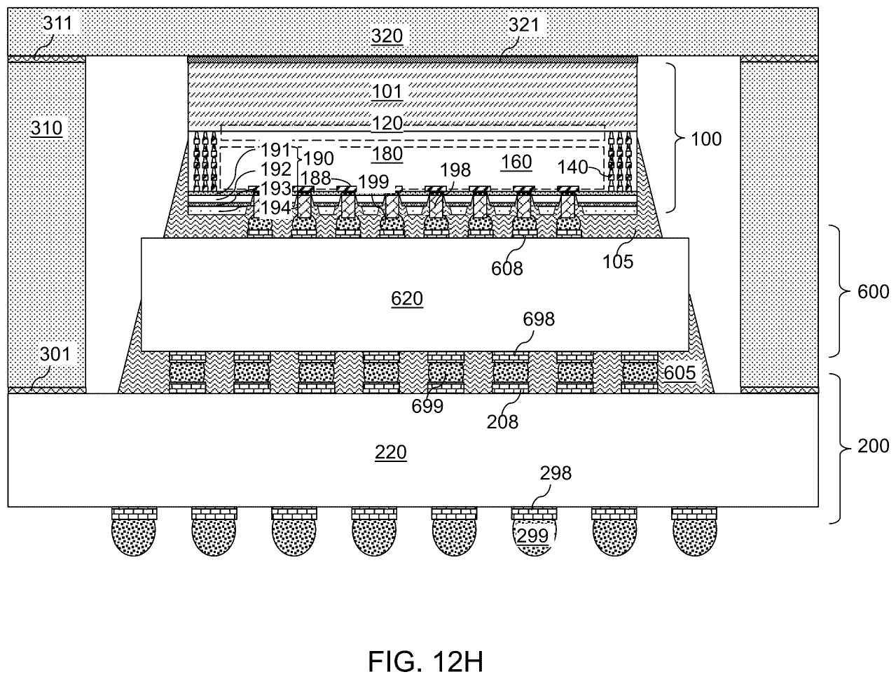

Generally, any other packaging structure may be used in lieu of a packaging substrate 200 to provide bonded assemblies including a semiconductor die 100 and the packaging structure. FIG. 12A-12H are vertical cross-sectional views of various configurations of a second exemplary bonded assembly according to an embodiment of the present disclosure. Specifically, FIG. 12A-12H illustrate embodiments in which an interposer 600 is used as a packaging structure. The interposer 600 may comprise an organic interposer, a semiconductor interposer, a ceramic interposer, or any other type of interposer known in the art. The interposer 600 comprises an interposer body 620, an array of interposer bump structures 608 located on a proximal side of the interposer body 620 and having a same pitch as the array of die bump structures 198, and a two-dimensional array of interposer bonding structures 698 located on a distal side of the interposer body 620 and having a same pitch as the two-dimensional array of substrate bump structures 208.

In this embodiment, the semiconductor die 100 may be attached to the interposer 600 through the array of solder material portions 199 (which provide bonding through reflow and re-solidification), and an underfill material portion 105 may be applied around the array of solder material portions 199. As discussed above, the various features of the passivation layer stack 190 of the present disclosure may reduce the mechanical stress on the passivation layer stack 190 and the rest of the semiconductor die 100. Subsequently, the assembly of the semiconductor die 100 and the interposer 600 may be attached to a packaging substrate 200 through an additional array of solder material portions 699. An additional underfill material portion 605 may be formed around the additional array of solder material portions 699. Subsequently, structural stabilization structures (310, 320) may be attached to the packaging substrate 200 and the semiconductor die 100.

FIGS. 12A, 12B, 12C, 12D, 12E, 12F, 12G, and 12H illustrate, in order, bonded assemblies of a respective packaging substrate 200, a respective interposer 600, respective structural stabilization structures (310, 320), and a respective one of the first, second, third, fourth, fifth, sixth, seventh, or eighth semiconductor dies 100 described above.

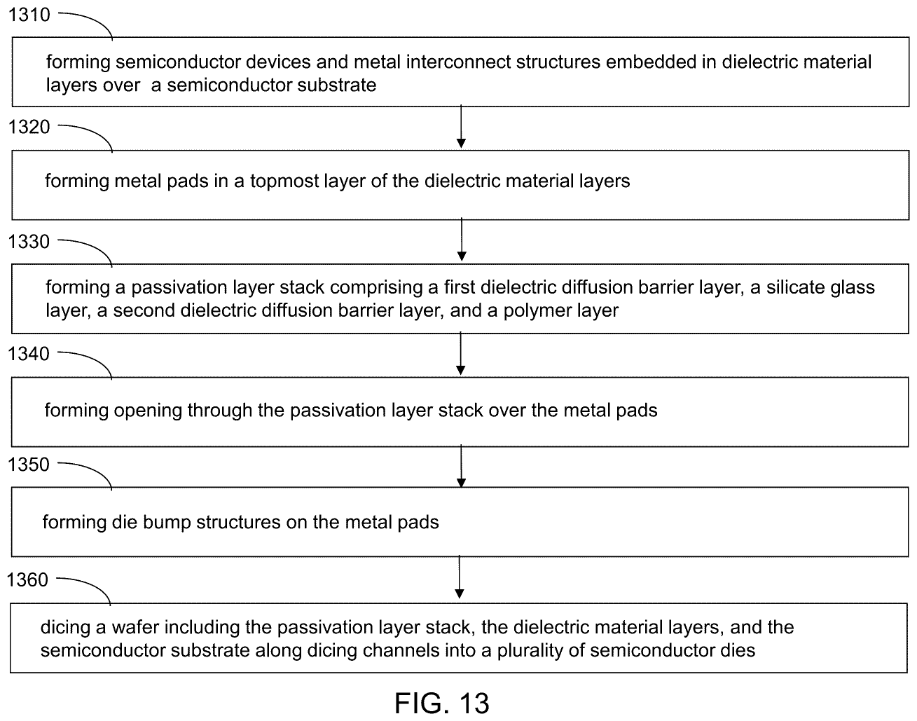

FIG. 13 is a first flowchart illustrating steps for a manufacturing process for forming a device structure according to an embodiment of the present disclosure.

Referring to step 1310 and FIG. 1A-1C, semiconductor devices 120 and metal interconnect structures 180 formed within dielectric material layers 160 may be formed over a semiconductor substrate 101.

Referring to step 1320 and FIG. 1A-1C, metal pads 188 may be formed in a topmost layer of the dielectric material layers 160.

Referring to step 1330 and FIG. 2A-2C, 4A, and 8A, a passivation layer stack 190 comprising a first dielectric diffusion barrier layer 191, a silicate glass layer 192, a second dielectric diffusion barrier layer 193, and a polymer layer 194 may be formed.

Referring to step 1340 and FIG. 2D-2F, 3A, 4B-4E, 5A, 6A and 6B, 7A, 8B, 9A, openings 195 may be formed through the passivation layer stack 190 over the metal pads 188.

Referring to step 1350 and FIGS. 2G, 3B, 4F, 5B, 6C, 7B, 8C, 9B, die bump structures 198 may be formed on the metal pads 188.

Referring to step 1360 and FIG. 2H-2K, 3C-3F, 4G-4J, 5C-5F, 6D-6F, 7C-7E, 8D and 8E, and 9C and 9D, a wafer 1000 including the passivation layer stack 190, the dielectric material layers 160, and the semiconductor substrate 101 may be diced along dicing channels into a plurality of semiconductor dies 100.

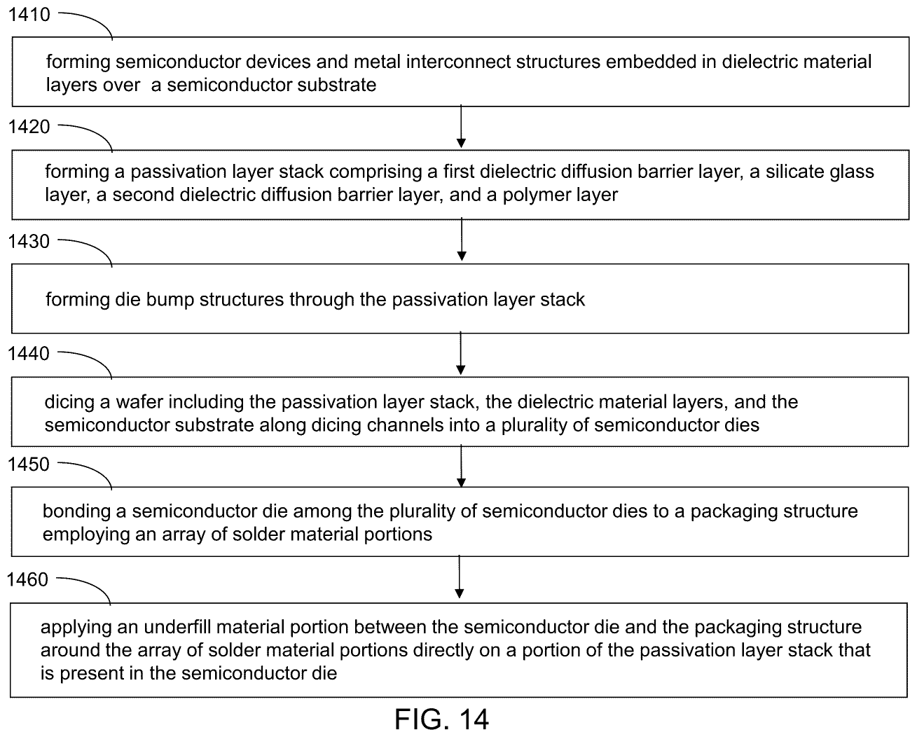

FIG. 14 is a second flowchart illustrating steps for the manufacturing process according to an embodiment of the present disclosure.

Referring to step 1410 and FIG. 1A-1C, semiconductor devices 120 and metal interconnect structures 180 formed within dielectric material layers 160 may be formed over a semiconductor substrate 101.

Referring to step 1420 and FIG. 2A-2C, 4A, and 8A, a passivation layer stack 190 comprising a first dielectric diffusion barrier layer 191, a silicate glass layer 192, a second dielectric diffusion barrier layer 193, and a polymer layer 194 may be formed.

Referring to step 1430 and FIGS. 2D-2G, 3A and 3B, 4B-4F, 5A and 5B, 6A-6C, 7A and 7B, 8B and 8C, and 9A and 9B, die bump structures 198 may be formed through the passivation layer stack 190.

Referring to step 1440 and FIG. 2H-2K, 3C-3F, 4G-4J, 5C-5F, 6D-6F, 7C-7E, 8D and 8E, and 9C and 9D, a wafer 1000 including the passivation layer stack 190, the dielectric material layers 160, and the semiconductor substrate 101 may be diced along dicing channels into a plurality of semiconductor dies 100.

Referring to step 1450 and FIGS. 10A, 10B, 11B-11H, and 12A-12H, a semiconductor die 100 selected from the plurality of semiconductor dies 100 may be bonded to a packaging structure (200 or 600) using an array of solder material portions 199.

Referring to step 1460 and FIGS. 10C, 11A-11H, and 12A-12H, an underfill material portion 105 may be applied between the semiconductor die 100 and the packaging structure (200 or 600) around the array of solder material portions 199 directly on a portion of the passivation layer stack 190 that is present in the semiconductor die 100.

Referring to all drawings and according to various embodiments of the present disclosure, a device structure is provided, which comprises: a semiconductor die 100 comprising a semiconductor substrate 101, semiconductor devices 120 located on the semiconductor substrate 101, metal interconnect structures 180 formed within dielectric material layers 160, and a passivation layer stack 190 comprising a first dielectric diffusion barrier layer 191, a silicate glass layer 192, a second dielectric diffusion barrier layer 193, and a polymer layer 194; die bump structures 198 vertically extending through the passivation layer stack 190 and electrically connected to a subset of the metal interconnect structures 180, wherein the passivation layer stack 190 comprises a first frame-shaped horizontal surface located in a peripheral region and vertically offset relative to a distal horizontal surface of the polymer layer 194 that laterally surrounds the die bump structures 198; a packaging structure (200 or 600) comprising package bump structures (208 or 608) that are bonded to the die bump structures 198 through an array of solder material portions 199; and an underfill material portion 105 laterally surrounding the array of solder material portions 199 and contacting the first frame-shaped horizontal surface and the distal horizontal surface.

In one embodiment, the first frame-shaped horizontal surface comprises a surface of the second dielectric diffusion barrier layer 193. In one embodiment, the passivation layer stack 190 comprises a second frame-shaped horizontal surface located in the peripheral region, vertically offset relative to the first frame-shaped horizontal surface, laterally offset outward relative to the first frame-shaped horizontal surface, and contacting the underfill material portion 105. In one embodiment, the second frame-shaped horizontal surface comprises a surface of the first dielectric diffusion barrier layer 191. In one embodiment, the silicate glass layer 192 has a first thickness within a first region having an areal overlap with the second dielectric diffusion barrier layer 193, and has a second thickness within a second region that does not have an areal overlap with the second dielectric diffusion barrier layer 193, the second thickness being less than the first thickness; and the second frame-shaped horizontal surface comprises a surface of the second region of the silicate glass layer 192.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming semiconductor devices and metal interconnect structures formed within dielectric material layers over a semiconductor substrate;
forming metal pads in a topmost layer of the dielectric material layers;
forming a passivation layer stack comprising a first dielectric diffusion barrier layer, a silicate glass layer, and a polymer layer;
forming openings through the passivation layer stack over the metal pads;
forming die bump structures on the metal pads; and
dicing a wafer including the passivation layer stack, the dielectric material layers, and the semiconductor substrate along dicing channels into a plurality of semiconductor dies.

2. The method of claim 1, wherein the passivation layer stack comprises a second dielectric diffusion barrier layer formed between the silicate glass layer and the polymer layer.

3. The method of claim 2, further comprising patterning at least one material layer selected from the silicate glass layer, the second dielectric diffusion barrier layer, and the polymer layer such that said at least one material layer is completely removed from a respective frame-shaped peripheral region of each of the plurality of semiconductor dies prior to dicing the wafer.

4. The method of claim 3, wherein the at least one material layer comprises the polymer layer.

5. The method of claim 4, wherein the at least one material layer further comprises the silicate glass layer.

6. The method of claim 5, wherein the at least one material layer further comprises the second dielectric diffusion barrier layer.

7. The method of claim 6, wherein:
the wafer comprises dicing channel regions that are removed during dicing of the wafer and semiconductor die regions that become the plurality of semiconductor dies upon dicing;
the method comprises removing portions of the silicate glass layer located within a first lateral offset distance from the dicing channel regions, and removing portions of the second dielectric diffusion barrier layer located within a second lateral offset distance from the dicing channel regions; and
the second lateral offset distance is less than the first lateral offset distance.

8. The method of claim 7, wherein:
the method comprises removing portions of the polymer layer located within a third lateral offset distance from the dicing channel regions; and
the third lateral offset distance is greater than the second lateral offset distance, and is less than the first lateral offset distance.

9. The method of claim 5, further comprising thinning portions of the silicate glass layer that are not masked by the second dielectric diffusion barrier layer to a thickness that is greater than zero and is less than an original thickness of the silicate glass layer after patterning the second dielectric diffusion barrier layer.

10. The method of claim 9, wherein:
the wafer comprises dicing channel regions that are removed during dicing of the wafer and semiconductor die regions that become the plurality of semiconductor dies upon dicing;
the method comprises removing portions of the second dielectric diffusion barrier layer located within a first lateral offset distance from the dicing channel regions, and removing portions of the polymer layer located within a second lateral offset distance from the dicing channel regions; and
the second lateral offset distance is less than the first lateral offset distance.

11. The method of claim 3, wherein:
the at least one material layer comprises the silicate glass layer;
the wafer comprises dicing channel regions that are removed during dicing of the wafer and semiconductor die regions that become the plurality of semiconductor dies upon dicing; and
the polymer layer comprises a self-planarizing polymer material and forms a top surface located entirely within a horizontal plane prior to formation of the openings.

12. A method of forming a device structure, comprising:
forming semiconductor devices and metal interconnect structures formed within dielectric material layers over a semiconductor substrate;
forming a passivation layer stack comprising a first dielectric diffusion barrier layer, a silicate glass layer, a second dielectric diffusion barrier layer, and a polymer layer;
forming die bump structures through the passivation layer stack;
dicing a wafer including the passivation layer stack, the dielectric material layers, and the semiconductor substrate along dicing channels into a plurality of semiconductor dies;
bonding a semiconductor die selected from the plurality of semiconductor dies to a packaging structure using an array of solder material portions; and
applying an underfill material portion between the semiconductor die and the packaging structure around the array of solder material portions directly on a portion of the passivation layer stack that is present in the semiconductor die.

13. The method of claim 12, further comprising patterning at least one material layer selected from the silicate glass layer, the second dielectric diffusion barrier layer, and the polymer layer, wherein said at least one material layer is absent from a frame-shaped peripheral region of the semiconductor die upon patterning.

14. The method of claim 12, wherein:
physically exposed surfaces of the portion of the passivation layer stack that is present in the semiconductor die prior to application of the underfill material portion comprise a frame-shaped horizontal surface segment of a portion of the second dielectric diffusion barrier layer; and
the underfill material portion is applied directly on the frame-shaped horizontal surface segment of the portion of the second dielectric diffusion barrier layer.

15. The method of claim 12, wherein:
physically exposed surfaces of the portion of the passivation layer stack that is present in the semiconductor die prior to application of the underfill material portion comprise a frame-shaped horizontal surface segment of a portion of the first dielectric diffusion barrier layer; and
the underfill material portion is applied directly on the frame-shaped horizontal surface segment of the portion of the first dielectric diffusion barrier layer.

16. A device structure comprising:
a semiconductor die comprising a semiconductor substrate, semiconductor devices located on the semiconductor substrate, metal interconnect structures formed within dielectric material layers, and a passivation layer stack comprising a first dielectric diffusion barrier layer, a silicate glass layer, a second dielectric diffusion barrier layer, and a polymer layer;
die bump structures vertically extending through the passivation layer stack and electrically connected to a subset of the metal interconnect structures, wherein the passivation layer stack comprises a first frame-shaped horizontal surface located in a peripheral region and vertically offset relative to a distal horizontal surface of the polymer layer that laterally surrounds the die bump structures;
a packaging structure comprising package bump structures that are bonded to the die bump structures through an array of solder material portions; and
an underfill material portion laterally surrounding the array of solder material portions and contacting the first frame-shaped horizontal surface and the distal horizontal surface.

17. The device structure of claim 16, wherein the first frame-shaped horizontal surface comprises a surface of the second dielectric diffusion barrier layer.

18. The device structure of claim 16, wherein the passivation layer stack comprises a second frame-shaped horizontal surface located in the peripheral region, vertically offset relative to the first frame-shaped horizontal surface, laterally offset outward relative to the first frame-shaped horizontal surface, and contacting the underfill material portion.

19. The device structure of claim 18, wherein the second frame-shaped horizontal surface comprises a surface of the first dielectric diffusion barrier layer.

20. The device structure of claim 18, wherein:
the silicate glass layer has a first thickness within a first region having an areal overlap with the second dielectric diffusion barrier layer, and has a second thickness within a second region that does not have an areal overlap with the second dielectric diffusion barrier layer, the second thickness being less than the first thickness; and
the second frame-shaped horizontal surface comprises a surface of the second region of the silicate glass layer.
